(19) United States
(12) Patent Application Publication
(10) Pub. No.: US 2026/0020289 A1
(43) Pub. Date: Jan. 15, 2026

(54) SEMICONDUCTOR DEVICE AND METHOD FOR MANUFACTURING SEMICONDUCTOR DEVICE

(71) Applicant: SEMICONDUCTOR ENERGY LABORATORY CO., LTD., Atsugi-shi (JP)

(72) Inventors: Hidekazu MIYAIRI, Hadano (JP); Yasuhiro JINBO, Isehara (JP); Tsutomu MURAKAWA, Isehara (JP); Fumito ISAKA, Zama (JP); Motomu KURATA, Isehara (JP); Shunpei YAMAZAKI, Tokyo (JP)

(21) Appl. No.: 19/251,955

(22) Filed: Jun. 27, 2025

(30) Foreign Application Priority Data
Jul. 10, 2024 (JP) 2024-111316

(51) Int. Cl. H10D 30/67; H10B 12/00; H10D 1/68; H10D 30/01

(52) U.S. Cl. CPC H10D 30/6755; H10B 12/312; H10D 1/696; H10D 1/716; H10D 30/031

(57) ABSTRACT

A semiconductor device that can be easily miniaturized is provided. The semiconductor device includes a first insulating layer, a second insulating layer, and a transistor. The transistor includes a first conductive layer, a second conductive layer, a first semiconductor layer, a third insulating layer, and a third conductive layer. The first insulating layer is over the first conductive layer and includes a slit reaching the first conductive layer. The second conductive layer is over the first insulating layer. The first semiconductor layer includes a first portion in contact with the second conductive layer, a second portion along a side surface of the slit, and a third portion in contact with a top surface of the first conductive layer in the slit. The third conductive layer includes a portion facing a second portion of the first semiconductor layer with the third insulating layer therebetween. The second insulating layer includes a portion facing the second portion of the first semiconductor layer with the third insulating layer and the third conductive layer of the first semiconductor layer therebetween and a portion overlapping with the top surface with the third portion of the first conductive layer therebetween.

### BACKGROUND OF THE INVENTION

### 1. Field of the Invention

One embodiment of the present invention relates to a semiconductor device. One embodiment of the present invention relates to a transistor. One embodiment of the present invention relates to a memory device.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof. A semiconductor device generally means a device that can function by utilizing semiconductor characteristics.

### 2. Description of the Related Art

In recent years, semiconductor devices have been developed, and CPUs (Central Processing Units), memories, and other LSI are mainly used in the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor integrated circuit of a CPU, a memory, or other LSI is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit and an image display device (also simply referred to as a display device). A silicon-based semiconductor material is widely known as a material of a semiconductor thin film that can be used in a transistor. As another material, an oxide semiconductor has been attracting attention.

It is known that a transistor including an oxide semiconductor has an extremely low leakage current in a non-conducting state. For example, Patent Document 1 discloses a low-power CPU utilizing the characteristic of a low leakage current. Furthermore, for example, Patent Document 2 discloses a memory device that can retain stored data for a long time.

In recent years, demand for an integrated circuit with higher density has risen with reductions in size and weight of electronic devices. In addition, the productivity of a semiconductor device including an integrated circuit is desired to be improved. For example, Patent Document 3 discloses a technique to achieve an integrated circuit with higher density by making a plurality of memory cells overlap with each other by stacking a first transistor including an oxide semiconductor film and a second transistor including an oxide semiconductor film. For example, Patent Document 4 discloses a vertical transistor in which a side surface of an oxide semiconductor is covered with a gate electrode with a gate insulator therebetween.

### REFERENCES

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537
[Non-Patent Document 1] Takashi Koida, “High-mobility transparent conductive film”, National Institute of Advanced Industrial Science and Technology, AIST Photovoltaic Technology Research Symposium 2019, Internet URL: https://unit.aist.go.jp/rpd-envene/PV/ja/results/2019/oral/T13.pdf

### SUMMARY OF THE INVENTION

An object of one embodiment of the present invention is to provide a semiconductor device that can be miniaturized or highly integrated. Another object of one embodiment of the present invention is to provide a highly reliable semiconductor device. Another object of one embodiment of the present invention is to provide a semiconductor device with low power consumption. Another object of one embodiment of the present invention is to provide a semiconductor device with a high operation speed. Another object of one embodiment of the present invention is to provide a semiconductor device including a transistor with favorable electrical characteristics. Another object of one embodiment of the present invention is to provide a semiconductor device including a transistor with a high on-state current. Another object of one embodiment of the present invention is to provide a semiconductor device including a transistor with small parasitic capacitance. Another object of one embodiment of the present invention is to provide a novel semiconductor device. Another object of one embodiment of the present invention is to provide a method for manufacturing a semiconductor device having any of these features.

Another object of one embodiment of the present invention is to manufacture a semiconductor device with high yield. Another object of one embodiment of the present invention is to reduce the number of manufacturing steps of a semiconductor device. Another object of one embodiment of the present invention is to reduce the manufacturing cost of a semiconductor device.

Note that the description of these objects does not preclude the presence of other objects. One embodiment of the present invention does not need to achieve all these objects. Objects other than these can be derived from the description of the specification, the drawings, the claims, and the like.

One embodiment of the present invention is a semiconductor device includes a first transistor, a first insulating layer, and a second insulating layer. The first transistor includes a first conductive layer, a second conductive layer, a first semiconductor layer, a third insulating layer, and a third conductive layer. The first insulating layer is over the first conductive layer and includes a slit reaching the first conductive layer. The second conductive layer is over the first insulating layer. The first insulating layer includes a first side surface and a second side surface facing the first side surface in the slit. The first semiconductor layer includes a first portion in contact with the second conductive layer, a second portion along the first side surface, and a third portion in contact with a first top surface of the first conductive layer. The first top surface overlaps with the slit in a plan view. The third conductive layer includes a portion facing a second portion with the third insulating layer therebetween. The second insulating layer includes a portion facing the second portion with the third insulating layer and the third conductive layer therebetween and a portion overlapping with the first top surface with the third portion therebetween.

In the above embodiment, a second transistor and a fourth insulating layer are preferably included. The second transistor preferably includes a fourth conductive layer, a fifth conductive layer, a second semiconductor layer, a fifth insulating layer, and a sixth conductive layer. The first insulating layer is preferably over the fourth conductive layer so that the second side surface overlaps with a first region of a second top surface of the fourth conductive layer. The fifth conductive layer is preferably over the first insulating layer. The second semiconductor layer preferably includes a fourth portion in contact with the fifth conductive layer, a fifth portion along the second side surface, and a sixth portion in contact with a second region of the second top surface of the fourth conductive layer. The second region of the second top surface preferably overlaps with the slit in the plan view. The sixth conductive layer preferably includes a portion facing the fifth portion with the fifth insulating layer therebetween. The fourth insulating layer preferably includes a portion facing the fifth portion with the fifth insulating layer and the sixth conductive layer therebetween and a portion overlapping with the second region of the second top surface with the second semiconductor layer therebetween.

In the above embodiment, the third conductive layer and the second insulating layer extend in a first direction in the plan view.

In the above structure, the first semiconductor layer preferably includes indium oxide.

In the above embodiment, a capacitor, a sixth insulating layer, and a seventh conductive layer are preferably included. The capacitor preferably includes an eighth conductive layer, a ninth conductive layer, and a seventh insulating layer. The sixth insulating layer is preferably over the seventh conductive layer and includes an opening portion reaching the seventh conductive layer. The eighth conductive layer is preferably in contact with a side surface of the sixth insulating layer and a top surface of the seventh conductive layer in the opening portion. The seventh insulating layer is preferably over the eighth conductive layer. The ninth conductive layer is preferably over the seventh insulating layer. The first conductive layer is preferably in contact with a top surface of the ninth conductive layer.

In the above embodiment, the slit preferably extends in a first direction in the plan view. The first side surface and the second side surface are preferably along the first direction. The third conductive layer, the sixth conductive layer, the second insulating layer, and the fourth insulating layer preferably extend in the first direction.

In the above embodiment, an eighth insulating layer and a ninth insulating layer are preferably included. A third side surface of the first conductive layer preferably faces a fourth side surface of the fourth conductive layer. The eighth insulating layer preferably includes a seventh portion covering the third side surface, an eighth portion covering the fourth side surface, a ninth portion covering a side surface of the second insulating layer, and a tenth portion covering a side surface of the fourth insulating layer. The ninth insulating layer preferably includes a portion between the seventh portion and the eighth portion and a portion between the ninth portion and the tenth portion.

In the above embodiment, the second insulating layer and the fourth insulating layer each preferably include one or more of silicon nitride and silicon nitride oxide. The eighth insulating layer preferably includes one or more of silicon nitride, silicon nitride oxide, silicon oxynitride, aluminum oxide, aluminum oxynitride, aluminum nitride, hafnium oxide, and hafnium aluminate. The ninth insulating layer preferably includes one or more of silicon oxide, silicon oxynitride, silicon oxide including fluorine, silicon oxide including carbon, and silicon oxide including carbon and nitrogen.

Another embodiment of the present invention is a method for manufacturing a semiconductor device. The method includes: forming a first conductive layer; forming a first insulating layer including a first side surface and a second side surface over the first conductive layer; forming a second conductive layer over the first insulating layer; by removing part of the second conductive layer and part of the first insulating layer with use of a first mask, forming a slit reaching the first conductive layer in the first insulating layer, thereby forming a first side surface and a second side surface of the first insulating layer that face each other within the slit in a cross-sectional view and dividing the second conductive layer with the slit therebetween in a plan view; forming a first semiconductor layer covering a top surface of the first conductive layer, the first side surface in the slit, and the second side surface in the slit; forming a second insulating layer over the first semiconductor layer; forming a third conductive layer over the second insulating layer; by removing part of the third conductive layer by anisotropic etching, forming a fourth conductive layer along the first side surface and forming a fifth conductive layer along the second side surface; forming a third insulating layer covering the first conductive layer, the second insulating layer, the fourth conductive layer, and the fifth conductive layer; by removing part of the third insulating layer by anisotropic etching, forming a fourth insulating layer along the first side surface with the fourth conductive layer therebetween and forming a fifth insulating layer along the second side surface with the fifth conductive layer therebetween; forming an eighth insulating layer and a ninth insulating layer by dividing the second insulating layer in the slit; forming a second semiconductor layer and a third semiconductor layer by dividing the first semiconductor layer in the slit; and forming a sixth conductive layer and a tenth conductive layer by dividing the first conductive layer in the slit. The slit extends in a first direction in the plan view. The first side surface and the second side surface extend in the first direction. The second semiconductor layer includes a portion covering the first side surface and a portion covering a top surface of the sixth conductive layer. The third semiconductor layer includes a portion covering the second side surface and a portion covering a top surface of the tenth conductive layer.

In the above embodiment, the second insulating layer, the first semiconductor layer, and dividing the first conductive layer are each preferably divided using the fourth insulating layer and the fifth insulating layer as masks.

In the above structure, the first semiconductor layer preferably includes indium oxide.

In the above embodiment, the third insulating layer preferably includes one or more of silicon nitride and silicon nitride oxide.

One embodiment of the present invention can provide a semiconductor device that can be miniaturized or highly integrated. Another embodiment of the present invention can provide a highly reliable semiconductor device. Another embodiment of the present invention can provide a semiconductor device with low power consumption. Another embodiment of the present invention can provide a semiconductor device with a high operation speed. Another embodiment of the present invention can provide a semiconductor device including a transistor with favorable electrical characteristics. Another embodiment of the present invention can provide a semiconductor device including a transistor with a high on-state current. Another embodiment of the present invention can provide a semiconductor device including a transistor with small parasitic capacitance. Another embodiment of the present invention can provide a novel semiconductor device. Another embodiment of the present invention can provide a method for manufacturing a semiconductor device having any of these features.

According to one embodiment of the present invention, a semiconductor device can be manufactured with high yield. Another embodiment of the present invention can reduce the number of manufacturing steps of a semiconductor device. Another embodiment of the present invention can reduce the manufacturing cost of a semiconductor device.

Note that the description of these effects does not preclude the existence of other effects. One embodiment of the present invention does not necessarily have all these effects. Effects other than these can be derived from the description of the specification, the drawings, the claims, and the like.

### BRIEF DESCRIPTION OF THE DRAWINGS

FIG. 1 illustrates a structure example of a semiconductor device.

FIG. 2A illustrates a structure example of a semiconductor device. FIG. 2B illustrates a circuit configuration example of the semiconductor device.

FIGS. 3A to 3C illustrate a structure example of a semiconductor device.

FIGS. 4A and 4B each illustrate a structure example of a semiconductor device.

FIGS. 5A and 5B illustrate a structure example of a semiconductor device.

FIGS. 6A and 6B illustrate a structure example of a semiconductor device.

FIGS. 7A to 7C illustrate a structure example of a semiconductor device.

FIGS. 8A and 8B illustrate a structure example of a semiconductor device.

FIGS. 9A and 9B illustrate a structure example of a semiconductor device.

FIGS. 10A and 10B illustrate a structure example of a semiconductor device.

FIG. 11 illustrates a structure example of a semiconductor device.

FIGS. 12A to 12C illustrate a structure example of a semiconductor device.

FIG. 13 illustrates a structure example of a semiconductor device.

FIGS. 14A to 14C illustrate a structure example of a semiconductor device.

FIG. 15 illustrates a structure example of a semiconductor device.

FIGS. 16A to 16D illustrate a method for manufacturing a semiconductor device.

FIGS. 17A to 17D illustrate a method for manufacturing a semiconductor device.

FIGS. 18A to 18D illustrate a method for manufacturing a semiconductor device.

FIGS. 19A to 19D illustrate a method for manufacturing a semiconductor device.

FIGS. 20A to 20D illustrate a method for manufacturing a semiconductor device.

FIGS. 21A to 21D illustrate a method for manufacturing a semiconductor device.

FIGS. 22A to 22D illustrate a method for manufacturing a semiconductor device.

FIGS. 23A to 23D illustrate a method for manufacturing a semiconductor device.

FIGS. 24A to 24D illustrate a method for manufacturing a semiconductor device.

FIGS. 25A to 25D illustrate a method for manufacturing a semiconductor device.

FIGS. 26A to 26D illustrate a method for manufacturing a semiconductor device.

FIGS. 27A to 27D illustrate a method for manufacturing a semiconductor device.

FIGS. 28A to 28D illustrate the manufacturing method example of a semiconductor device.

FIGS. 29A to 29D illustrate a method for manufacturing a semiconductor device.

FIGS. 30A to 30D illustrate a method for manufacturing a semiconductor device.

FIGS. 31A to 31C illustrate a method for manufacturing a semiconductor device.

FIGS. 32A and 32B illustrate a method for manufacturing a semiconductor device.

FIG. 33 is a block diagram illustrating a configuration example of a semiconductor device.

FIG. 34 illustrates a circuit configuration example of a memory cell array and memory cells.

FIG. 35A is a graph showing an example of hysteresis characteristics, and FIG. 35B is a timing chart showing an example of a method for driving a memory cell.

FIGS. 36A to 36H illustrate circuit configuration examples of memory cells.

FIGS. 37A and 37B are perspective views illustrating structure examples of a semiconductor device.

FIG. 38 is a block diagram illustrating a CPU.

FIGS. 39A and 39B are perspective views of a semiconductor device.

FIGS. 40A and 40B are perspective views of semiconductor devices.

FIGS. 41A and 41B illustrate structure examples of electronic components.

FIGS. 42A to 42C illustrate a structure example of a large computer.

FIG. 43A illustrates a structure example of space equipment. FIG. 43B illustrates a structure example of a storage system.

FIGS. 44A and 44B show carrier concentration dependence of Hall mobility. FIG. 44C is a cross-sectional view illustrating an indium oxide film.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number of components.

A transistor is a kind of semiconductor element and enables amplification of a current or a voltage, switching operation for controlling conduction or non-conduction, and the like. A transistor in this specification includes an insulated-gate field effect transistor (IGFET) and a thin film transistor (TFT).

The functions of a “source” and a “drain” are sometimes replaced with each other when a transistor of different polarity is used or when the direction of current flow is changed in circuit operation, for example. Thus, the terms “source” and “drain” can be used interchangeably in this specification.

The expression “connection” in this specification includes “electrical connection”, for example. Note that the expression “electrical connection” is used in some cases to specify the connection relation of a circuit element as an object. The term “electrical connection” includes “direct connection” and “indirect connection”. The expression “A and B are directly connected” means that A and B are connected to each other without a circuit element (e.g., a transistor or a switch; a wiring is not a circuit element) therebetween. By contrast, the expression “A and B are indirectly connected” means that A and B are connected to each other with at least one circuit element therebetween. Note that A and B each denote an object such as an element, a circuit, a wiring, an electrode, a terminal, a semiconductor layer, or a conductive layer.

For example, assuming that a circuit including A and B is in operation, the circuit can be specified as “A and B are indirectly connected” as an object when electric signal transmission and reception or electric potential interaction between A and B occurs at some point during the operation period of the circuit. Note that even when neither electric signal transmission and reception nor electric potential interaction between A and B occurs at some point during the operation of the circuit, the circuit can be specified as “A and B are indirectly connected” as long as electric signal transmission and reception or electric potential interaction between A and B occurs at another point during the operation period of the circuit.

Examples of the case where the expression “A and B are indirectly connected” can be used include the case where A and B are connected to each other through a source and a drain of at least one transistor. By contrast, examples of the case where the expression “A and B are indirectly connected” cannot be used include the case where an insulator is present on the path from A to B. Specific examples thereof include the case where a capacitor is connected between A and B and the case where a gate insulating film of a transistor or the like is present between A and B. In such cases, the expression “a gate (A) of a transistor and a source or a drain (B) of the transistor are indirectly connected” cannot be used.

Another example of the case where the expression “A and B are indirectly connected” cannot be used is the case where a plurality of transistors are connected through their sources and drains on the path from A to B and a constant electric potential V is supplied from a power source, GND, or the like to a node between one of the transistors and another one of the transistors.

In this specification and the like, the expression “having substantially the same top surface shapes” means that the outlines of stacked layers at least partly overlap with each other. For example, the case of patterning or partly patterning an upper layer and a lower layer with the use of the same mask pattern is included. The expression “having substantially the same top surface shapes” also sometimes includes the case where the outlines do not completely overlap with each other; for instance, the edge of the upper layer may be positioned on the inner side or the outer side of the edge of the lower layer.

Note that in this specification and the like, a top surface shape of a component means the outline of the component in the plan view. A plan view means that the component is observed from a normal direction of a surface where the component is formed or from a normal direction of a surface of a support (e.g., a substrate) where the component is formed.

Note that the expressions indicating directions such as “over” and “under” are basically used to correspond to the directions of drawings. However, in some cases, the term “over” or “under” in the specification indicates a direction that does not correspond to the apparent direction in the drawings, for the purpose of easy description or the like. For example, in the description of the stacked order (formation order) of a stacked body or the like, even in the case where a surface on which the stacked body is provided (e.g., a formation surface, a support surface, a bonding surface, or a planarization surface) is located over the stacked body in the drawings, the following expressions are used in some cases: the formation surface side is under the stacked body or the stacked body side is over the formation surface side.

Note that in this specification and the like, the channel length direction of a transistor refers to one of directions parallel to the shortest straight line connecting a source region and a drain region. That is, the channel length direction corresponds to one of directions of current flow in a semiconductor layer when a transistor is in an on state. The channel width direction refers to a direction orthogonal to the channel length direction. Each of the channel length direction and the channel width direction is not fixed to one direction in some cases depending on the structure or the shape of a transistor.

In this specification and the like, the terms “film” and “layer” can be interchanged with each other. For example, in some cases, the term “insulating layer” can be interchanged with the term “insulating film”.

Unless otherwise specified, an off-state current in this specification and the like refers to a drain current of a transistor in an off state (also referred to as a non-conduction state or a cutoff state). Unless otherwise specified, the off state of an n-channel transistor means that a gate-source voltage Vgs is lower than a threshold voltage Vth, and the off state of a p-channel transistor means that Vgs is higher than Vth.

In this specification and the like, the term “parallel or substantially parallel” indicates, for example, a state where the angle formed between two straight lines is greater than or equal to −10° and less than or equal to 10°. Thus, the case where the angle is greater than or equal to −5° and less than or equal to 5° is also included. The term “perpendicular or substantially perpendicular” indicates that, for example, the angle subtended between two straight lines is greater than or equal to 80° and less than or equal to 100°. Thus, the case where the angle is greater than or equal to 85° and less than or equal to 95° is also included.

### Embodiment 1

In this embodiment, structure examples of a semiconductor device of one embodiment of the present invention and a manufacturing method example thereof are described. The semiconductor device described below can be applied to a memory device.

The semiconductor device of one embodiment of the present invention includes a plurality of memory cells. The memory cell includes one transistor and one memory element. As the memory element, any of a variety of elements that can retain stored data, such as a capacitor, a resistive random access element, a ferroelectric element, a charge trap element, and a floating-gate element, can be used.

In the transistor included in the memory cell, a source electrode and a drain electrode are located at different heights, so that a current flows in a semiconductor layer in the height direction. In other words, the channel length direction includes a height (vertical) component, so that one embodiment of the present invention can be referred to as a vertical field effect transistor (VFET), a vertical transistor, a vertical-channel transistor, or the like. Note that the height of the source electrode and the height of the drain electrode can be determined based on, for example, a substrate surface or the formation surface of each electrode.

A capacitor included in the memory cell can be provided below the transistor. Stacking the transistor and the capacitor enables the memory cells to be arranged at high density. The capacitor can be what is called a metal-insulator-metal (MIM) capacitor, in which a dielectric is provided between a pair of electrodes. In that case, the lower electrode of the transistor also preferably functions as the upper electrode of the capacitor. In that case, the upper electrode of the transistor preferably functions as a bit line. When a ferroelectric is used as the dielectric included in the capacitor, the capacitor can be a ferroelectric capacitor. Thus, a nonvolatile memory device can be achieved.

In one embodiment of the present invention, the semiconductor layer preferably includes a metal oxide exhibiting semiconductor characteristics (an oxide semiconductor). For example, to form a source region and a drain region using silicon, which is a typical material of a semiconductor, the regions need to be doped with an impurity functioning as a donor or an acceptor. However, in the vertical transistor of one embodiment of the present invention, it may be difficult to perform impurity doping on the semiconductor layer with high accuracy because the levels of a source and a drain are different from each other and the channel formation region is oriented in the vertical direction with respect to the substrate surface, for example. By contrast, the oxide semiconductor can be connected to the source electrode and the drain electrode favorably; thus, a transistor having a three-dimensional structure as in one embodiment of the present invention can be fabricated with high yield.

More specific examples are described below with reference to drawings.

### [Structure Example]

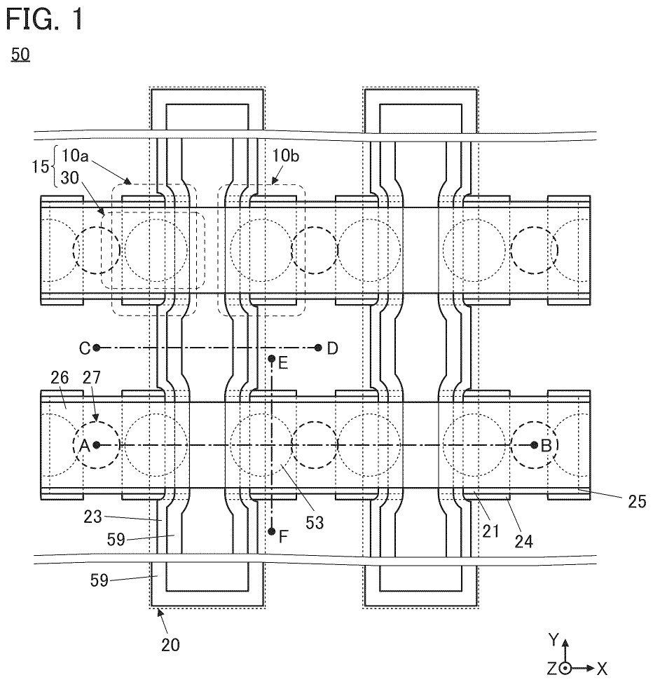

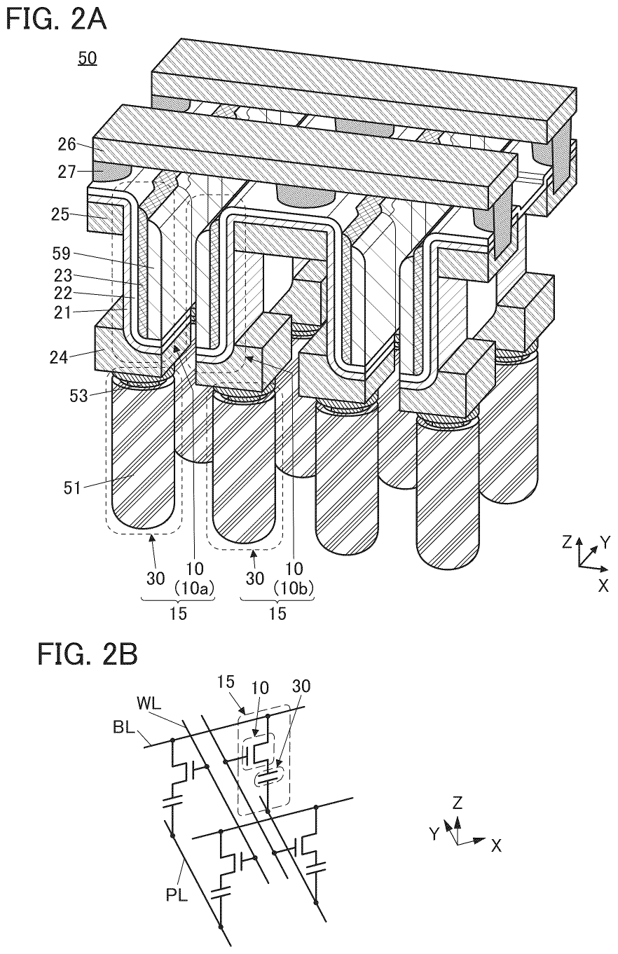

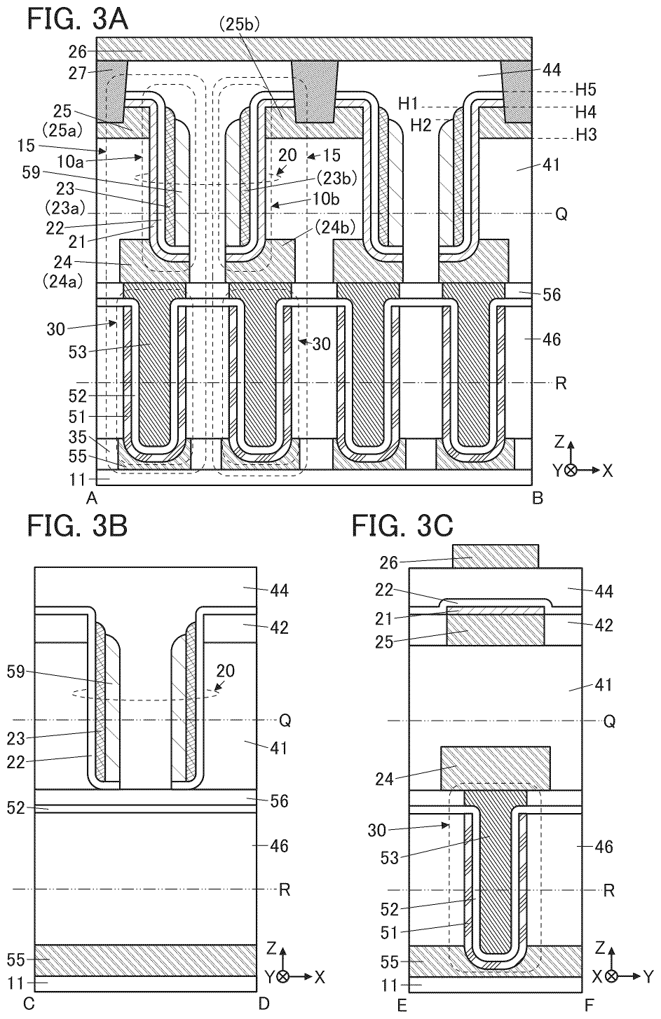

FIG. 1 is a top view of a semiconductor device 50. FIG. 2A is a perspective view of the semiconductor device 50 illustrated in FIG. 1. FIGS. 3A, 3B, and 3C are cross-sectional views taken along lines A-B, C-D, and E-F, respectively, in FIG. 1. Note that some components (e.g., insulating layers) are omitted in FIG. 1, FIG. 2A, and the top views and the perspective views mentioned below. In this specification, arrows indicating the X, Y, and Z directions may be illustrated in the drawings. The X, Y, and Z directions are orthogonal to each other.

The semiconductor device 50 has a structure in which a plurality of memory cells 15 are arranged in the X direction and the Y direction. In the semiconductor device 50, a conductive layer 26 functioning as a bit line extends in the X direction and a conductive layer 23 functioning as a word line extends in the Y direction. As illustrated in FIG. 2A and the like, the memory cell 15 includes a transistor 10 and a capacitor 30 below the transistor 10.

FIG. 2B is a circuit diagram corresponding to the semiconductor device 50. FIG. 2B illustrates a plurality of wirings BL functioning as bit lines, a plurality of wirings WL that are orthogonal to the bit lines and function as word lines, and a wiring PL. FIG. 2B illustrates an example in which the wiring PL is parallel to the wirings WL. In some cases, the memory cells 15 connected to different wirings WL may be connected to the same wiring PL. In such a case, the wiring PL can be a flat-plate conductive layer so that the conductive layer functioning as the wiring PL can be shared by the memory cells 15 connected to the different wirings WL. Alternatively, the wiring PL can be parallel to the wirings BL.

The memory cell 15 includes one transistor 10 and one capacitor 30. A gate of the transistor 10 is connected to the wiring WL, one of a source and a drain of the transistor 10 is connected to the wiring BL, and the other of the source and the drain of the transistor 10 is connected to one of the pair of electrodes of the capacitor 30. The other of the pair of electrodes of the capacitor 30 is connected to the wiring PL.

The wiring BL functions as a wiring for writing and reading data. The wiring WL functions as a wiring for controlling on and off states (conduction and non-conduction states) of the transistor 10 functioning as a switch. The wiring PL has a function of a constant potential line connected to the capacitor 30.

As illustrated in FIG. 3A and the like, the transistor 10 and the capacitor 30 are provided over an insulating layer 11 provided over a substrate (not illustrated). The insulating layer 11 functions as a base insulating layer.

The transistor 10 includes a semiconductor layer 21, an insulating layer 22 functioning as a gate insulating layer, the conductive layer 23 functioning as a gate electrode, a conductive layer 24 functioning as one of a source electrode and a drain electrode, and a conductive layer 25 functioning as the other of the source electrode and the drain electrode.

The capacitor 30 is provided over a conductive layer 55 functioning as the wiring PL. The capacitor 30 includes a conductive layer 51 functioning as a lower electrode, a conductive layer 53 functioning as an upper electrode, and an insulating layer 52 positioned therebetween and functioning as a dielectric.

The conductive layer 24 is provided over the conductive layer 53. One of the source electrode and the drain electrode of the transistor 10 is connected to the upper electrode of the capacitor. The conductive layer 24 is preferably provided in contact with a top surface of the conductive layer 53.

The conductive layer 55 is provided so as to be embedded in the insulating layer 35 over the insulating layer 11.

An insulating layer having a barrier property can be provided between the insulating layer 11 and the conductive layer 55. Alternatively, the insulating layer 11 may function as an insulating layer having a barrier property. The insulating layer has a function of preventing diffusion of impurities such as hydrogen into the semiconductor layer 21 from the insulating layer 11 or from below the insulating layer 11. For example, a film which is less likely to allow diffusion of hydrogen (which has a higher barrier property against hydrogen) than a silicon oxide film, such as a silicon nitride film, a silicon nitride oxide film, an aluminum oxide film, a magnesium oxide film, a hafnium oxide film, or a gallium oxide film, can be used. Specifically, a silicon nitride film or a silicon nitride oxide film is preferably used.

Note that in this specification and the like, oxynitride refers to a material in which an oxygen content is higher than a nitrogen content, and nitride oxide refers to a material in which a nitrogen content is higher than an oxygen content. For example, silicon oxynitride refers to a material that contains more oxygen than nitrogen, and silicon nitride oxide refers to a material that contains more nitrogen than oxygen.

An insulating layer 46 is provided over the conductive layer 55. The insulating layer 46 functions as an interlayer insulating layer. An opening portion reaching the conductive layer 55 is provided in the insulating layer 46. A side surface of the opening portion is preferably perpendicular or substantially perpendicular to a substrate surface.

The conductive layer 51 includes a portion positioned in the opening portion provided in the insulating layer 46. The conductive layer 51 includes a region in contact with a top surface of the conductive layer 55 in the opening portion and a region in contact with a side surface of the insulating layer 46 in the opening portion. The insulating layer 52 is stacked over the conductive layer 51. The insulating layer 52 includes a portion that faces the side surface of the insulating layer 46 with the conductive layer 51 therebetween in the opening portion, and a portion that covers a top surface of the insulating layer 46.

In the structure illustrated in FIG. 3A and the like, an upper end of the conductive layer 51 and the top surface of the insulating layer 46 are substantially level with each other.

The conductive layer 51 and the insulating layer 52 are stacked along the side surface of the opening portion in the insulating layer 46 and along the top surface of the conductive layer 55. The conductive layer 53 is provided on the insulating layer 52 to fill the opening portion. The capacitor 30 having such a structure may be referred to as a trench-type capacitor or a trench capacitor.

As illustrated in FIG. 3A, the insulating layer 52 covers a top surface of the conductive layer 51 at the upper end of the conductive layer 51. This can prevent a short circuit between the conductive layer 51 and the conductive layer 53, which function as the pair of electrodes of the capacitor 30.

FIG. 3A and the like illustrate an example in which a bottom portion of the conductive layer 51 is rounded (has a concave surface). Furthermore, a bottom portion of the insulating layer 52 provided along the conductive layer 51 and a bottom portion of the conductive layer 53 provided along the insulating layer 52 are each rounded, and the bottom portion of the conductive layer 53 includes a convex curved surface protruding toward the conductive layer 51. When the conductive layer 51 which forms the formation surface of the insulating layer 52 has no corner portion in this manner, the insulating layer 52 can be prevented from being locally thinned. Furthermore, when the bottom portion of the conductive layer 51 has no corner portion, local concentration of electric fields can be prevented. Accordingly, the leakage current of the capacitor can be controlled and its reliability can be increased.

Moreover, the top surface of the conductive layer 55 is provided with a rounded depression, and the bottom portion of the conductive layer 51 is provided along the depression. In this structure, the contact area between the conductive layers 55 and 51 is larger than that in the structure where the contact surface between the conductive layers 55 and 51 is flat; accordingly, the contact resistance therebetween can be reduced. When the opening portion is formed in the insulating layer 46, an upper portion of the conductive layer 55 is partly etched, thereby forming the depression of the conductive layer 55.

In the structure illustrated in FIG. 3A and the like, an insulating layer 56 is provided over the insulating layer 46 and the insulating layer 52, and the conductive layer 53 is provided to have the top surface substantially level with the top surface of the insulating layer 56. The conductive layer 24 is positioned to overlap with the conductive layer 53. An insulating layer 41 is provided above the conductive layer 53 and the insulating layer 56. The insulating layer 41 includes a slit 20, which extends in the Y direction and has a band shape. A side surface of the insulating layer 41 in the slit 20 is preferably perpendicular or substantially perpendicular to the substrate surface. The height of the slit 20 of the insulating layer 41 is preferably greater than or equal to 0.5 times the width of the slit 20 in the X direction.

In the structure illustrated in FIG. 2A, FIG. 3A, and the like, two transistors (also referred to as a transistor 10a and a transistor 10b) are provided for one slit 20.

The conductive layer 25 is provided over the insulating layer 41. The conductive layer 25 (a conductive layer 25a) included in the transistor 10a and the conductive layer 25 (a conductive layer 25b) included in the transistor 10b are provided to be apart from each other with the slit 20 therebetween in a plan view. The conductive layers 25a and 25b can be formed by dividing a conductive layer extending in the X direction. Specifically, the conductive layer extending in the X direction includes a portion overlapping with the slit 20 and a portion positioned outside the slit 20, and the portion overlapping with the slit 20 is removed from the conductive layer so that the conductive layer can be divided into the conductive layers 25a and 25b. In other words, the conductive layer 25 is not positioned in the region overlapping with the slit 20. That is, a pair of the conductive layers 25 are provided over the insulating layer 41 such that one slit 20 is positioned between the conductive layers 25. As illustrated in FIG. 1, FIG. 2A, FIG. 3A, and the like, the island-shaped conductive layers 25 are arranged at regular intervals along the extending direction of the slits 20 (Y direction). An insulating layer 42 is provided over the insulating layer 41, and the conductive layer 25 is formed to be embedded in the insulating layer 42 as illustrated in FIG. 3C.

FIG. 3C illustrates a structure in which the end portions of the conductive layer 25 and the semiconductor layer 21 are substantially aligned with each other, as an example. Such a structure can be formed when the conductive layer 25 and the semiconductor layer 21 are processed in the same step using the same mask, for example. In the case where the conductive layer 25 is processed in a step different from that of the semiconductor layer 21, the end portions are not necessarily aligned with each other. For example, the end portion of the conductive layer 25 may be positioned outside the end portion of the semiconductor layer 21.

In a method for manufacturing a semiconductor device of one embodiment of the present invention, a conductive layer to be the conductive layer 23 (a conductive layer 23f described later) is processed by anisotropic etching, whereby the conductive layer 23 can be formed along a side surface of the slit 20. Such a method enables the conductive layer 23 to be formed without using a mask. In other words, the self-aligned process enables the conductive layer 23 to be formed without using a mask. Thus, the conductive layer 23 can be formed without consideration of the alignment accuracy between the slit 20 and the mask, which indicates suitability for manufacture of a semiconductor device including a miniaturized transistor with a high degree of integration.

In the case where the slit 20 has a minute width in the X direction in the semiconductor device, processing a thick conductive layer in the slit 20 (e.g., a conductive layer filling the slit 20) is sometimes difficult. In the method for manufacturing a semiconductor device of one embodiment of the present invention, the conductive layer to be the conductive layer 23 (the conductive layer 23f described later) is formed to cover the side surface of the slit 20, a top surface of the conductive layer 25 with the semiconductor layer 21 therebetween, and a bottom portion of the slit 20 (e.g., a top surface of the conductive layer 24); the part of the conductive layer 23f that covers the top surface of the conductive layer 25 with the semiconductor layer 21 therebetween and the part of the conductive layer 23f that covers the bottom portion of the slit 20 are then removed; and thus the conductive layer 23 can be formed. In this manner, what should be removed in the slit 20 is only the part of the conductive layer in the bottom portion of the slit 20, which does not require processing of the thick conductive layer. This makes the manufacturing process easier.

At this time, the conductive layer (conductive layer 23f) to be the conductive layer 23 sometimes remains also in a region other than the side surface of the slit 20, e.g., remains on a side surface of a step difference in the formation surface of the conductive layer 23f. Such unintended residue remaining of the conductive layer 23f might cause leakage between a plurality of transistors 10.

Providing the insulating layer 42 between the conductive layers 25 can reduce the step difference in the formation surface of the conductive layer 23f. Thus, the unintentional remaining of the conductive layer 23f can be inhibited.

The conductive layer remaining in a region other than the side surface of the slit 20 can be removed also by etching using a mask, for example.

The semiconductor layer 21, the insulating layer 22, and the conductive layer 23 each include a portion positioned inside the slit 20. In the slit 20, the semiconductor layer 21 and the insulating layer 22 are provided along the side surface of the insulating layer 41 and the top surface of the conductive layer 24. In the slit 20, the conductive layer 23 is provided so as to face the side surface of the insulating layer 41 with the semiconductor layer 21 and the insulating layer 22 therebetween. In the structure illustrated in FIG. 2A, FIG. 3A, and the like, parts of the semiconductor layer 21 and the insulating layer 22 are provided also over the conductive layer 25.

The semiconductor layer 21, the insulating layer 22, the conductive layer 23, and the conductive layer 24 are divided in the slit 20 into two parts along the extending direction of the slit 20. The transistor 10a is composed of one of the divided semiconductor layers 21, one of the divided insulating layers 22, one of the divided conductive layers 23, and one of the divided conductive layers 24, and the transistor 10b is composed of the others thereof. With reference to FIG. 3A and the like, the conductive layer 23, the conductive layer 24, and the conductive layer 25 included in the transistor 10a are referred to as a conductive layer 23a, a conductive layer 24a, and a conductive layer 25a, respectively, and the conductive layer 23, the conductive layer 24, and the conductive layer 25 included in the transistor 10b are referred to as a conductive layer 23b, a conductive layer 24b, and a conductive layer 25b, respectively. The semiconductor layer 21, the insulating layer 22, and the conductive layer 25 in the transistor 10b in the slit 20 each form a continuous layer with those in the transistor 10 provided in the adjacent slit 20. In the slit 20, the semiconductor layer 21 and the insulating layer 22 included in the transistor 10a are provided along one of the pair of side surfaces of the insulating layer 41, and those included in the transistor 10b are provided along the other of the side surfaces.

The conductive layer 53 of the capacitor 30 is placed to overlap with each of the divided conductive layers 24. One slit 20 can be said to be shared by two memory cells 15.

The height of an upper end of the conductive layer 23 (a height H1 in FIG. 3A) is preferably lower than or equal to the top surface level of the insulating layer 22 over the conductive layer 25 (a height H5 in FIG. 3A), and is, for example, lower than or equal to the top surface level of the conductive layer 25 (a height H4 in FIG. 3A). In the structure illustrated in FIG. 3A and the like, the conductive layer 25 includes a side surface continuous with the side surface of the slit 20. Here, the height H4 is the top surface level of the conductive layer 25. The height H4 is the top surface level of the vicinity of the side surface of the conductive layer 25 that is continuous with the slit 20, for example. The heights H1 to H5 and the like are each a height from the reference surface. For example, a substrate surface can be used as the reference surface. Alternatively, for example, the top surface of the insulating layer 11, the top surface of the conductive layer 24, or the like can be used as the reference surface.

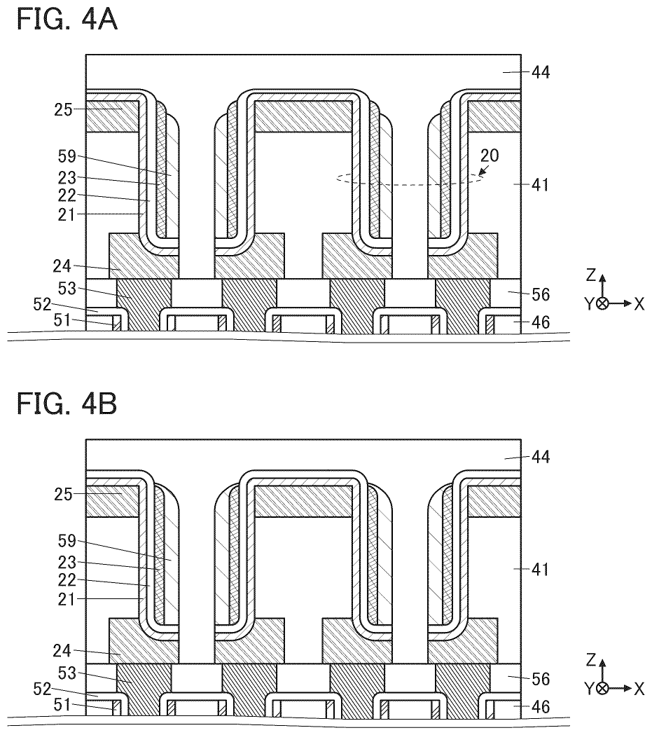

In the manufacturing process, the insulating layer over the conductive layer 25 may be thinned. In an example shown in FIG. 4A, a portion of the insulating layer 22 over the conductive layer 25 is thinner than a portion of the insulating layer 22 that covers the side surface of the slit 20 in the insulating layer 41. Alternatively, the insulating layer 22 over the conductive layer 25 may disappear in the manufacturing process. In such a case, for example, the height of the upper end of the conductive layer 23 is preferably lower than or equal to the top surface level of the semiconductor layer 21 over the conductive layer 25. The height of the upper end of the conductive layer 23 (the height H1 in FIG. 3A) is preferably higher than the bottom surface level of the conductive layer 25 over the insulating layer 41 (a height H3 in FIG. 3A, i.e., the top surface level of the insulating layer 41 in FIG. 3A and the like).

An insulating layer 59 is provided along a side surface of the conductive layer 23. The insulating layer 59 preferably covers at least part of the side surface of the conductive layer 23. An insulating layer to be the insulating layer 59 (an insulating layer 59f described later) is processed by anisotropic etching, whereby the insulating layer 59 can be formed to cover the side surface of the conductive layer 23.

The conductive layers 24 included in the two transistors 10 (transistors 10a and 10b) facing each other can be formed by dividing one conductive layer. In the division of this conductive layer by etching, the insulating layer 59 can function as a mask. Similarly, the insulating layer 59 can function as a mask in division to form the semiconductor layers 21 and the insulating layers 22 included in the two transistors 10.

As described above, the conductive layers 24, the semiconductor layers 21, and the insulating layers 22 included in the two transistors 10 facing each other can be formed using the insulating layer 59 as a mask. Thus, the alignment accuracy of the mask or the like is not necessarily taken into consideration, so that the integration degree of the semiconductor device can be increased.

Covering the conductive layer 23 with the insulating layer 59 as illustrated in FIG. 4B can reduce damage to the conductive layer 23 in the manufacturing process of the semiconductor device.

In the slit 20, the insulating layer 59 is provided so as to face the side surface of the insulating layer 41 with the semiconductor layer 21, the insulating layer 22, and the conductive layer 23 therebetween. The insulating layer 59 is referred to as a sidewall, a sidewall insulating layer, a sidewall protective layer, or the like in some cases.

Based on the lower end of the conductive layer 23 formed over the conductive layer 24, a height H2 of an upper end of the insulating layer 59 is preferably higher than or equal to 0.3 times, further preferably higher than or equal to half the height of the upper end of the conductive layer 23.

The insulating layer 59 is formed as follows: for example, the insulating layer to be the insulating layer 59 is formed to cover the inside of the slit 20 and the area over the conductive layer 25 outside the slit 20; and the insulating layer is processed by anisotropic etching so that a portion of the insulating layer that covers the side surface of the conductive layer 23 remains. In such formation, a portion of the insulating layer that covers the upper end of the conductive layer 23 also remains in some cases. A structure in which the insulating layer 59 covers the upper end of the conductive layer 23 is shown in FIG. 4B.

As a material of the insulating layer 59, for example, it is preferable to use a material having high selectivity under the etching conditions of the conductive layer 24, the semiconductor layer 21, and the insulating layer 22; specifically, it is preferable to use a material that enables the etching rate of the insulating layer 59 under each etching condition to be sufficiently low.

For the insulating layer 59, silicon nitride or silicon nitride oxide can be used, for example.

The semiconductor layer 21 includes a portion in contact with the top and side surfaces of the conductive layer 25, a portion in contact with the side surface of the insulating layer 41 inside the slit 20, and a portion in contact with the top surface of the conductive layer 24.

Since the semiconductor layer 21 and the insulating layer 22 are formed along the side surface of the slit 20 in the insulating layer 41, the thicknesses of the semiconductor layer 21 and the insulating layer 22 are sometimes reduced in the slit 20 by some film formation methods. For example, when a film formation method such as a sputtering method or a plasma enhanced CVD (PECVD) method using plasma is used, a film formed on a surface inclined with respect to the substrate surface or a surface perpendicular to the substrate surface tends to be thinner than a film formed on a surface parallel to the substrate surface. By contrast, a film formation method such as an atomic layer deposition (ALD) method or a thermal CVD method allows a film with a uniform thickness to be formed on a surface with any angle. The semiconductor layer 21 and the insulating layer 22 are preferably formed by an ALD method when an angle formed by the side surface of the slit 20 in the insulating layer 41 and the substrate surface is 75° or more, 80° or more, or 85° or more, for example.

In the transistor 10, the source electrode and the drain electrode are located at different heights, so that a current flows in the height direction in the semiconductor. Since two or more of the source electrode, the semiconductor, and the drain electrode can overlap with each other in the transistor 10, the area occupied by the transistor 10 can be significantly smaller than that occupied by what is called a planar transistor (also referred to as a lateral transistor, a lateral FET (LFET), or the like) in which a semiconductor is positioned over a flat plane.

The channel length of the transistor 10 can be precisely adjusted by the thickness of the insulating layer 41 functioning as a spacer; thus, a variation in the channel length can be extremely smaller than that of a planar transistor. Furthermore, by reducing the thickness of the insulating layer 41, a transistor with an extremely short channel length can be manufactured. Thus, it is possible to achieve a transistor with an extremely short channel length that could not be achieved with a light-exposure apparatus for mass production. Moreover, a transistor with a channel length shorter than 10 nm can also be achieved without using an extremely expensive light-exposure apparatus used in the latest LSI technology.

The channel length of the transistor 10 is, for example, greater than or equal to 0.1 nm and less than or equal to 60 nm, greater than or equal to 0.1 nm and less than or equal to 50 nm, greater than or equal to 0.1 nm and less than or equal to 40 nm, greater than or equal to 0.1 nm and less than or equal to 30 nm, greater than or equal to 0.1 nm and less than or equal to 20 nm, or greater than or equal to 0.1 nm and less than or equal to 10 nm. For another example, the channel length is greater than or equal to 1 nm and less than or equal to 60 nm, greater than or equal to 1 nm and less than or equal to 50 nm, greater than or equal to 1 nm and less than or equal to 40 nm, greater than or equal to 1 nm and less than or equal to 30 nm, greater than or equal to 1 nm and less than or equal to 20 nm, or greater than or equal to 1 nm and less than or equal to 10 nm. For another example, the channel length is greater than or equal to 5 nm and less than or equal to 60 nm, greater than or equal to 5 nm and less than or equal to 50 nm, greater than or equal to 5 nm and less than or equal to 40 nm, greater than or equal to 5 nm and less than or equal to 30 nm, greater than or equal to 5 nm and less than or equal to 20 nm, or greater than or equal to 5 nm and less than or equal to 10 nm, for example.

The channel length of the transistor 10 corresponds to the thickness of the insulating layer 41 over the conductive layer 24 and does not affect the area occupied by the transistor 10, e.g., the area of the transistor 10 in the plan view. When the channel length of the transistor 10 is set to, for example, less than or equal to 1 μm, less than or equal to 500 nm, or less than or equal to 300 nm, the productivity, yield, and the like can be improved in formation of the insulating layer 41, formation of the slit 20 in the insulating layer 41, and the like.

A variety of semiconductor materials can be used for the semiconductor layer 21; in particular, an oxide semiconductor including a metal oxide is preferably used. The use of an oxide semiconductor formed under an appropriate condition allows a transistor having both a high on-state current and an extremely low off-state current to be achieved at a low cost. Described below are structure examples of the case where an oxide semiconductor is used for the semiconductor layer 21 unless otherwise specified.

In the example illustrated in FIG. 3A, a top surface of a region of the conductive layer 24 that overlaps with the slit 20 has a rounded depression (a concave surface). Thus, in the slit 20, bottom portions of the semiconductor layer 21, the insulating layer 22, and the conductive layer 23 are provided along the concave surface of the conductive layer 24. This enables the structure where an electric field is less likely to be concentrated. Consequently, a transistor having a low leakage current and high reliability can be achieved.

An insulating layer 44 functioning as an interlayer insulating layer is provided to cover the insulating layer 22, the conductive layer 23, and the insulating layer 59. In addition, the conductive layer 26 functioning as a bit line is provided over the insulating layer 44. A plug 27 connecting the conductive layers 25 and 26 is provided inside an opening portion provided in the insulating layer 44, the insulating layer 22, and the semiconductor layer 21. Thus, the conductive layers 25 arranged in the X direction with the slits 20 therebetween can be connected to each other by the conductive layer 26. In FIG. 3A and the like, part of the plug 27 is embedded in the conductive layer 25.

As each of the insulating layers 46, 41, and 44, an insulating layer functioning as a protective insulating layer can be used. Alternatively, the insulating layers 46, 41, and 44 can each have a stacked-layer structure including an insulating layer functioning as a protective insulating layer as one or more layers.

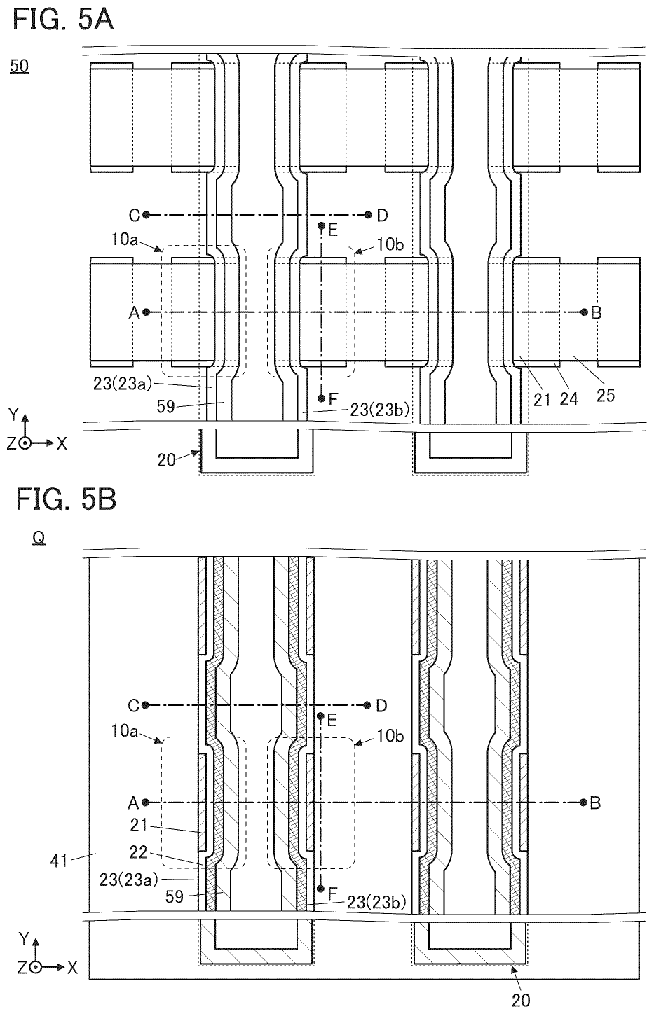

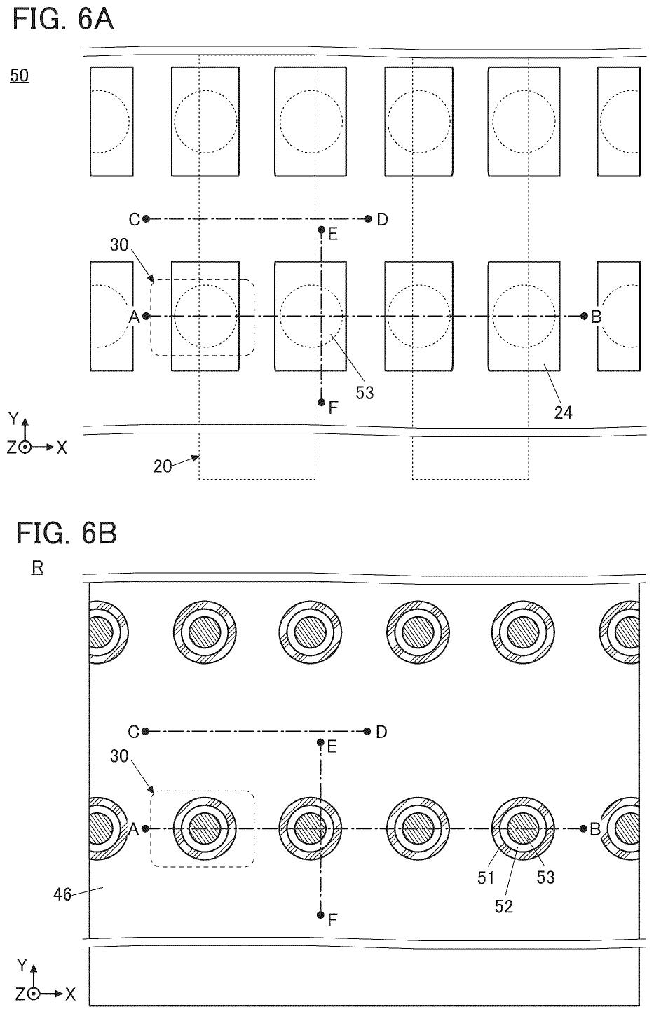

FIG. 5A selectively illustrates the conductive layer 24 and a layer positioned above the conductive layer 24 in the top view illustrated in FIG. 1, and FIG. 6A selectively illustrates the conductive layer 24 and a layer positioned below the conductive layer 24 in the top view illustrated in FIG. 1. Note that the conductive layer 26 and the plug 27 are omitted in FIG. 5A.

FIG. 5B is a cross-sectional view taken along the plane Q parallel to the X-Y plane seen from the Z direction, and FIG. 6B is a cross-sectional view taken along the plane R parallel to the X-Y plane seen from the Z direction. Dashed double-dotted lines corresponding to the planes Q and R are illustrated in each of FIGS. 3A to 3C.

As illustrated in FIG. 1 and FIGS. 5A and 5B, the conductive layer 23 is provided along the side surface of the slit 20. The conductive layer 23 is divided at an end portion of the slit 20 in the Y direction. That is, a pair of conductive layers 23 that have been divided are provided in the slit 20. In FIGS. 5A and 5B, the conductive layer 23a refers to the conductive layer 23 functioning as a gate of the transistor 10a, and the conductive layer 23b refers to the conductive layer 23 functioning as a gate of the transistor 10b. The two conductive layers 23 (conductive layers 23a and 23b) are provided in the slit 20; the conductive layer 23a is provided along one of two side surfaces facing each other in the slit 20 and the conductive layer 23b is provided along the other of the side surfaces.

The conductive layers 23a and 23b extend in the slit 20 in the Y direction. In the slit 20, a plurality of transistors 10a arranged in the Y direction and a plurality of transistors 10b arranged in the Y direction are provided. The conductive layer 23a is shared by the plurality of transistors 10a. The conductive layer 23b is shared by the plurality of transistors 10b.

The conductive layer 51 is preferably circular in the plan view, as illustrated in FIGS. 6A and 6B. In addition, the conductive layer 51, the insulating layer 52, and the conductive layer 53 are preferably arranged substantially concentrically in this order in one capacitor 30 in the plan view. Although an example in which the conductive layer 51 is circular in the plan view is shown, the shape of the conductive layer 51 is not limited to a circular shape and can be an elliptical shape, a quadrangular shape with rounded corners, or the like. The conductive layer 51 may be shaped like a regular polygon such as a regular triangle, a square, or a regular pentagon or a polygon other than a regular polygon, in the plan view. When the conductive layer 51 has a concave polygonal shape in which at least one interior angle is greater than 180°, such as a star polygonal shape, the channel widths can be increased. Alternatively, a polygonal shape with rounded corners, a closed curve in which a straight line and a curve are combined, or the like can be employed. The shape of the conductive layer 51 influences the shapes of the insulating layer 52 and the conductive layer 53 in the plan view.

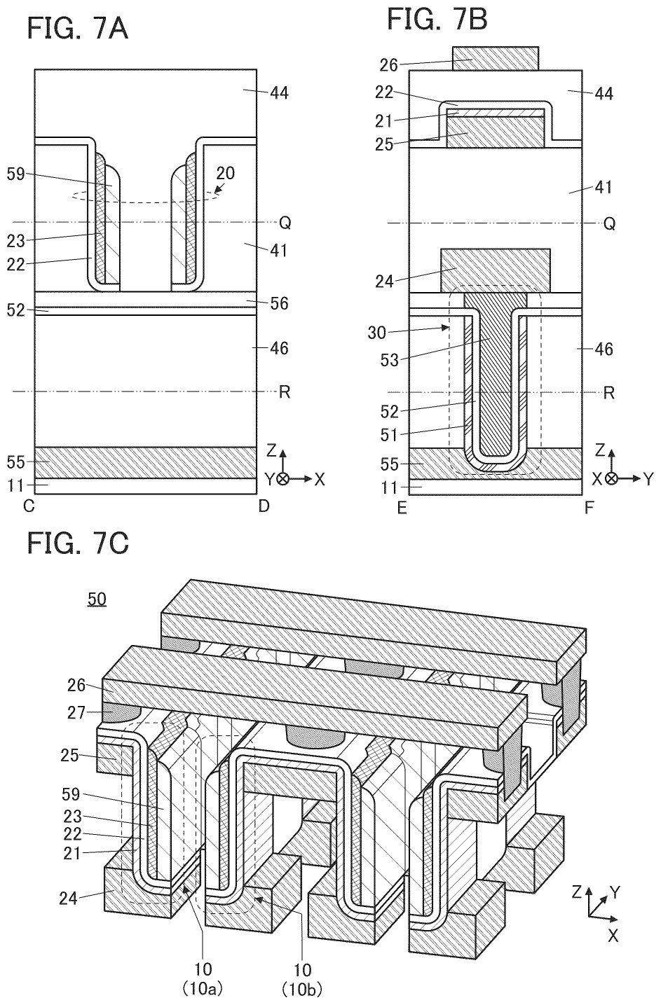

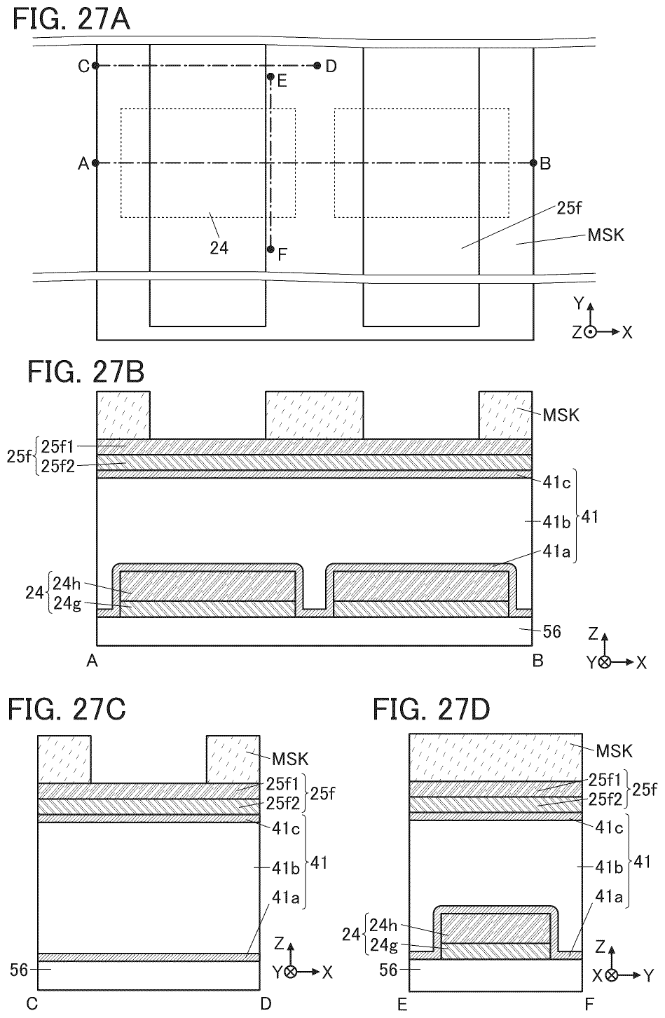

The structure illustrated in FIGS. 7A to 7C is different from that in FIGS. 3B and 3C mainly in that the insulating layer 42 over the insulating layer 41 is not provided. Since the insulating layer 42 is unnecessary, the number of manufacturing steps can be reduced. Furthermore, in the case where a later-described manufacturing method illustrated in FIG. 27A to FIG. 30D is employed, the conductive layer 25 and the semiconductor layer 21 can be processed using the same mask, which simplifies the process. In the structure illustrated in FIG. 7B, the end portion of the conductive layer 25 can be aligned with the end portion of the semiconductor layer 21. This is advantageous to the integration of the transistors 10.

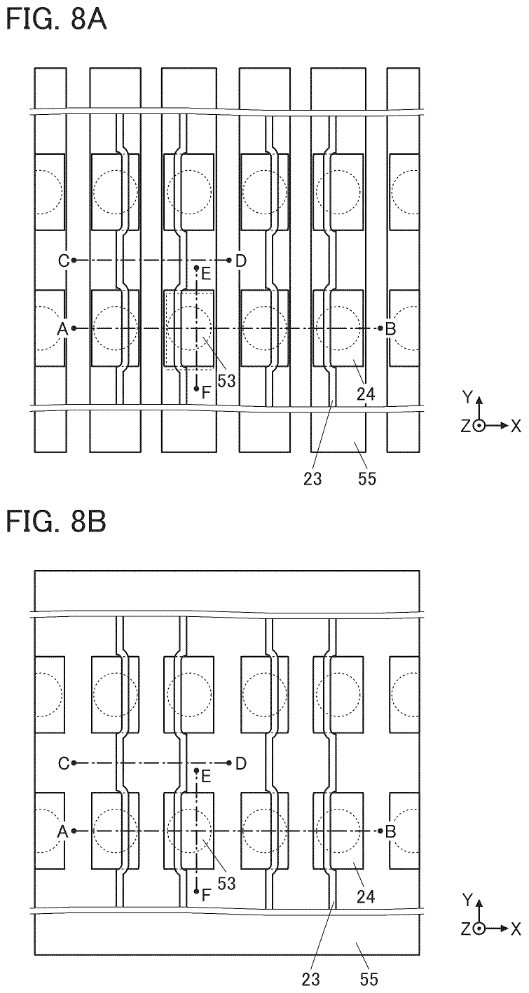

FIG. 8A is a top view selectively illustrating the conductive layers 55, 53, 24, and 23. The conductive layer 23 functioning as the wiring WL extends in the Y direction. The conductive layer 55 functioning as the wiring PL extends in the Y direction, and the conductive layer 24 functioning as one of the source electrode and the drain electrode of the transistor 10 is provided at a position overlapping with the conductive layer 55. FIG. 8A can be applied to a structure in which the wiring PL is parallel to the wiring WL, for example.

As illustrated in FIG. 8B, the conductive layer 55 may have a two-dimensional flat-plate shape. FIG. 8B can be applied to a structure in which the wiring PL is shared by the memory cells 15 connected to different wirings WL, for example.

The conductive layer 55 can be a wiring extending in the X direction or in a direction different from both the X and Y directions. Alternatively, the conductive layer 55 can have a lattice shape in which two or more portions extending in different directions are combined.

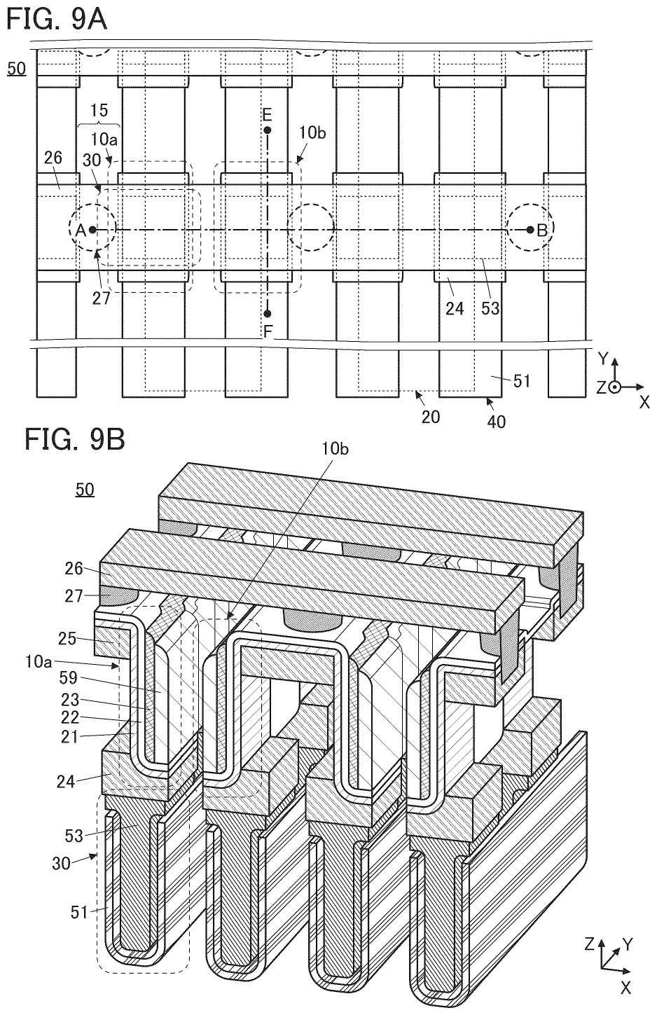

The structure of the semiconductor device illustrated in FIG. 9A to FIG. 11 is different from that in FIG. 1 to FIG. 6B in that the capacitor 30 is placed in a slit provided in the insulating layer 46, for example.

FIG. 9A is a top view of the semiconductor device 50. FIG. 9B is a perspective view of the semiconductor device 50 illustrated in FIG. 9A. Note that in FIG. 9A, the semiconductor layer 21, the conductive layer 23, and the insulating layer 59 are omitted for better viewing. FIG. 1, FIG. 2A, and the like can be referred to for the structure of the transistor 10 including the semiconductor layer 21, the conductive layer 23, and the insulating layer 59.

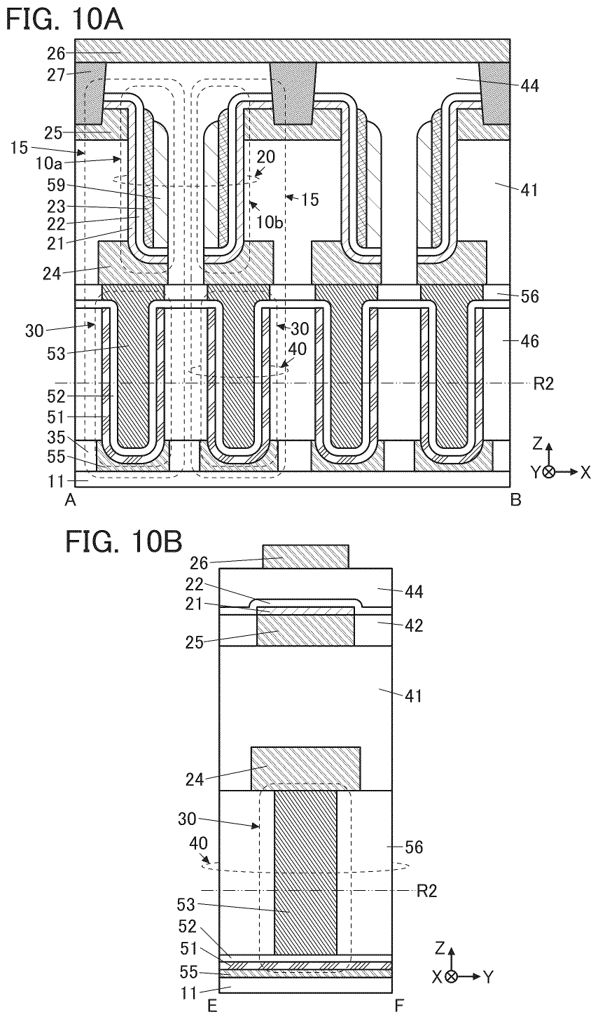

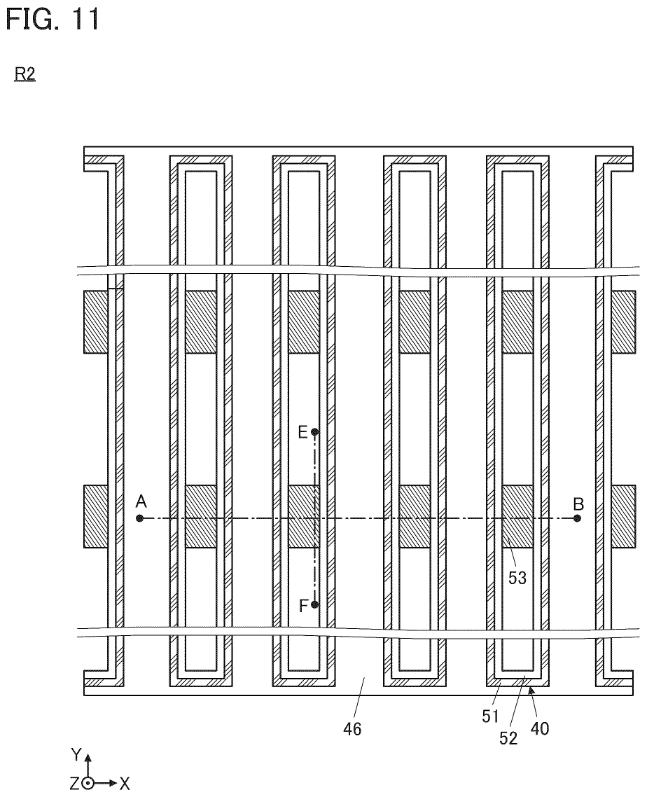

FIGS. 10A and 10B are cross-sectional views taken along the cutting line A-B and the cutting line E-F, respectively, in FIG. 9A. FIG. 11 illustrates a cross section taken along a plane R2 parallel to the X-Y plane when viewed from the Z direction, and a dashed double-dotted line corresponding to the plane R2 is illustrated in each of FIGS. 10A and 10B.

A plurality of slits 40 are provided in the insulating layer 46. The slits 40 extend in the Y direction. A plurality of capacitors 30 corresponding to the plurality of memory cells 15 aligned in the Y direction are provided in the slits 40. The side surface of the insulating layer 46 in the slit 40 is preferably perpendicular or substantially perpendicular to the substrate surface. The height of the insulating layer 46 is preferably greater than the width thereof in the X direction.

Two slits 40 are provided for one slit 20. The slit 40 is provided at a position shifted in the X direction from the center of the slit 20.

The slit 40 is provided to reach the conductive layer 55. The conductive layer 51 is in contact with the top surface of the conductive layer 55 in a bottom portion of the slit 40.

The conductive layer 51 includes a portion provided along the side surface of the insulating layer 46 in the slit 40 and a portion in contact with the top surface of the conductive layer 55. A cross section of the conductive layer 51 parallel to the X-Z plane is U-shaped, and the conductive layer 51 has a depression. The insulating layer 52 includes a portion provided along the depression of the conductive layer 51, a portion in contact with the top surface of the conductive layer 51, and a portion in contact with the top surface of the insulating layer 46. The conductive layer 53 is provided to fill the depression of the conductive layer 51 with the insulating layer 52 therebetween. In addition, the conductive layer 53 includes a portion provided over the insulating layer 46 with the insulating layer 52 therebetween. The conductive layer 51 is provided in the slit 40 to extend in the Y direction. That is, the conductive layer 51 is shared by the plurality of capacitors 30 aligned in the Y direction. By contrast, the conductive layer 53 is provided for each memory cell 15.

As illustrated in FIG. 11 and the like, the conductive layer 51 is provided along the extending direction (Y direction) of the slit 40. In the slit 40, the conductive layers 53 are provided at regular intervals in the Y direction. The conductive layer 51 may also be provided in an end portion of the slit 40 in the Y direction to have a loop shape along the side surface of the slit 40. In FIG. 11, the conductive layer 51 and the insulating layer 52 are provided along the side surface of the insulating layer 46 at the end portion of the slit 40 in the Y direction, whereby the conductive layer 51 and the insulating layer 52 each have a loop-shaped cross section. The loop-shaped cross section can be rephrased as a cross section parallel to the X-Y plane.

In FIG. 10A and the like, the conductive layer 51 has a rounded bottom portion, and the insulating layer 52 provided along the conductive layer 51 and the conductive layer 24 provided along the insulating layer 52 also have rounded bottom portions. This can prevent local thinning of the insulating layer 52 and also local electric field concentration.

Moreover, the top surface of the conductive layer 55 is provided with a round depression, and the bottom portion of the conductive layer 51 is provided to be fitted in the round depression. Such a structure can increase the contact area between the conductive layer 55 and the conductive layer 51 and reduce contact resistance therebetween. When the slit 40 is formed in the insulating layer 46, the upper portion of the conductive layer 55 is partly etched, thereby forming the depression of the conductive layer 55.

In the case where the conductive layer 51 extends in the Y direction, the conductive layer 55 is not necessarily placed in the entire bottom surface of the conductive layer 51. For example, the conductive layer 55 may be placed only in a region overlapping with an end portion of the conductive layer 51 extending in the Y direction and the vicinity thereof. In this case, the conductive layer 51 functions as a wiring extending in the Y direction.

Although the example in which the slits 20 and 40 extend in the same direction (Y direction here) is described above, they can extend in different directions.

### <Conductive Layer>

The conductive layers 24 and 25 are in contact with the semiconductor layer 21. Here, when the semiconductor layer 21 is formed using an oxide semiconductor and a part of the conductive layer 24 or the conductive layer 25 in contact with the semiconductor layer 21 is formed using, for example, a metal that is likely to be oxidized such as aluminum, an insulating oxide (e.g., aluminum oxide) may be formed between the conductive layer 24 or 25 and the semiconductor layer 21, which may inhibit electrical continuity between the conductive layer and the semiconductor layer. Therefore, at least a part of the conductive layer 24 or the conductive layer 25 in contact with the semiconductor layer 21 is preferably formed using a conductive material that is less likely to be oxidized, a conductive material that maintains low electric resistance even when oxidized, or an oxide conductive material.

For a conductive layer in contact with the semiconductor layer 21, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or materials that maintain the conductivity even when oxidized.

It is also possible to use a conductive oxide such as indium oxide, zinc oxide, In—Sn oxide, In—Zn oxide, In—W oxide, In—W—Zn oxide, In—Ti oxide, In—Ti—Sn oxide, In—Sn—Si oxide, or Ga—Zn oxide. A conductive oxide containing indium is particularly preferable because of its high conductivity. Alternatively, the above-described oxide material such as In—Ga—Zn oxide that can be used for the semiconductor layer 21 can be used for the conductive layer when the carrier concentration is increased.

For each of the conductive layers 24 and 25, any of the following structures can be used: a single-layer structure of the above conductive oxide film, a three-layer structure in which a titanium nitride film, a tungsten film, and a titanium nitride are stacked in this order, a two-layer structure in which a ruthenium film or a ruthenium oxide film is stacked over a tungsten film, a two-layer structure in which a ruthenium film or a ruthenium oxide film is stacked over the above conductive oxide film, a two-layer structure in which the above conductive oxide film is stacked over a ruthenium film or a ruthenium oxide film, or the like, for example.

The conductive layer 23 functions as a gate electrode and can be formed using a variety of conductive materials. The conductive layer 23 can be formed using, for example, a metal element selected from aluminum, chromium, copper, silver, gold, platinum, tantalum, nickel, cobalt, titanium, molybdenum, tungsten, hafnium, vanadium, niobium, manganese, magnesium, zirconium, beryllium, indium, ruthenium, iridium, strontium, lanthanum, and the like; or an alloy containing any of the above metal elements. It is also possible to use a nitride or an oxide of any of the above metals or the alloy. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electric conductivity, typified by polycrystalline silicon containing an impurity element such as phosphorus, or silicide such as nickel silicide may be used.

For the conductive layer 23, the nitride and the oxide that can be used for the conductive layers 24 and 25 may be used.

The conductive layers 23, 24, and 25 also function as wirings and thus are preferably formed using stacked low-resistance conductive materials. For example, the above-described low-resistance conductive material that can be used for the conductive layer 23 can also be used for a conductive layer 24g and a conductive layer 25h.

### <Insulating Layer>

The insulating layers 11, 35, 41, 42, 44, and 46 each function as an interlayer insulating film.

The insulating layer functioning as an interlayer insulating film is preferably formed by a film formation method such as a sputtering method or a plasma CVD method, for example.

For formation of the insulating layer functioning as an interlayer insulating film, it is preferable to use a film formation method that enables a higher deposition rate than those of the other insulating layers. For example, a silicon oxide film formed by a plasma CVD method using tetraethyl orthosilicate (TEOS) whose chemical formula is Si(OC₂H₅)₄) (also referred to as a TEOS film) may be used. The productivity can be thus increased.

In particular, a layer in contact with the semiconductor layer 21 of the transistor 10, such as the insulating layer 41 or 44, or a layer in the vicinity thereof preferably includes an insulating layer that inhibits diffusion of impurities and an insulating layer functioning as a barrier film against impurities. In this case, diffusion of impurities into the semiconductor layer 21 can be inhibited.

The insulating layer 41 is in contact with the channel formation region of the semiconductor layer 21 and therefore is preferably formed using an oxide insulating film. In particular, an oxide insulating film from which oxygen is released by heating is preferably used. An oxide insulating film that can be used as the gate insulating layer can be used as the insulating layer 41.

The insulating layer 41 can be a film having an extremely low hydrogen content when formed by a sputtering method in which hydrogen does not need to be used as a deposition gas. Consequently, supply of hydrogen to the semiconductor layer 21 is inhibited and the electrical characteristics of the transistor 10 can be stabilized.

For the insulating layer 59, a material that sufficiently lowers the etching rate of the insulating layer 59 under the etching conditions of the conductive layer 24, the semiconductor layer 21, and the insulating layer 22 is preferably used. For the insulating layer 59, silicon nitride or silicon nitride oxide can be used, for example. For the insulating layer 59, a material with a high dielectric constant described later may be used, for example.

The insulating layer 52 functions as the dielectric of the capacitor 30. An insulating material similar to that of the insulating layer 22 can be applied to the insulating layer 52. When the above-described material exhibiting ferroelectricity is used for the insulating layer 52, the capacitor 30 can be a ferroelectric capacitor, which enables a nonvolatile memory device. Note that as the capacitor 30, a resistive random access memory element utilizing a colossal electro resistance (CER) effect can also be used.

The conductive layers and the insulating layers may each have a stacked-layer structure.

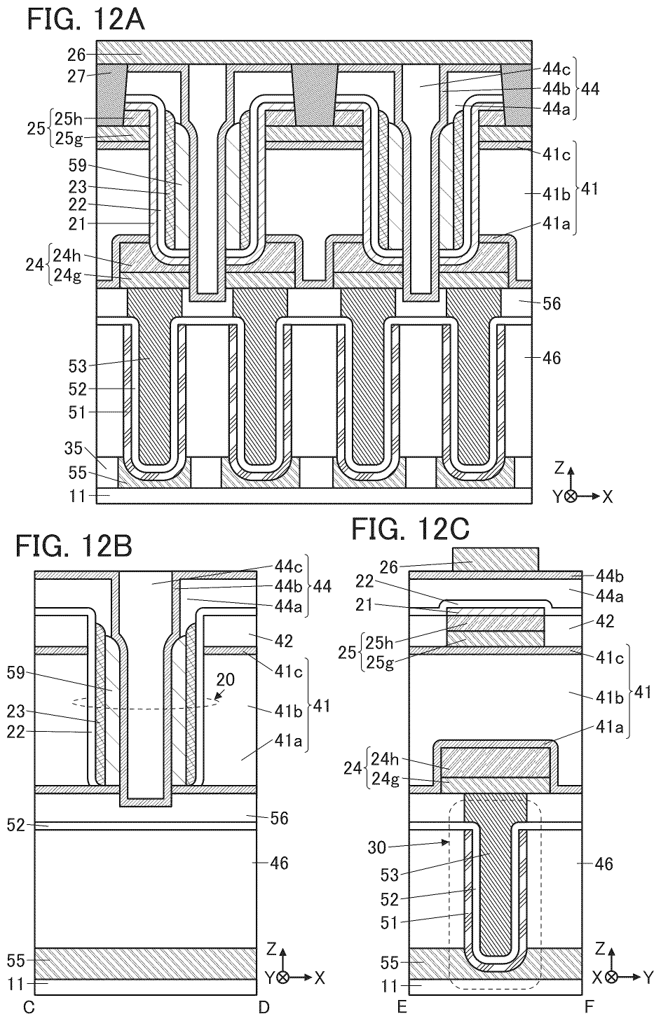

FIGS. 12A to 12C illustrate an example in which the conductive layer 24 in FIGS. 3A to 3C includes the conductive layer 24g and a conductive layer 24h over the conductive layer 24g. In this example, the conductive layer 25 includes a conductive layer 25g and the conductive layer 25h over the conductive layer 25g. Also in this example, the insulating layer 41 includes an insulating layer 41a, an insulating layer 41b over the insulating layer 41a, and an insulating layer 41c over the insulating layer 41b. Also in this example, the insulating layer 44 includes an insulating layer 44a over the insulating layer 22 and the conductive layer 23, an insulating layer 44b covering a side surface of the insulating layer 44a, a side surface of the insulating layer 59, the side surface of the conductive layer 24, and the top surface of the insulating layer 56, and an insulating layer 44c provided to fill the slit 20 by covering a side surface of the insulating layer 44b.

A conductive oxide (an oxide conductor) is preferably used for each of the conductive layers 24h and 25h.

Using a conductive oxide for each of the conductive layers 24h and 25h having a large contact area with the semiconductor layer 21 containing a metal oxide is preferable because the contact resistance between the semiconductor layer and the conductive layer can be reduced and load on the wiring can be reduced. The use of the same metal element as the metal element included in the semiconductor layer 21 is particularly preferable because it can further reduce the contact resistance. Specifically, the semiconductor layer 21 and the conductive layers preferably include the same element(s) that is/are one or more selected from In, Sn, Zn, Ga, and Ti. In particular, the semiconductor layer 21 and the conductive layers preferably contain In.

The conductive layer 24g preferably contains a conductive material having lower resistance than the conductive layer 24h and preferably contains a metal material, in particular. The conductive layer 25g preferably contains a conductive material having lower resistance than the conductive layer 25h and preferably contains a metal material, in particular. When the conductive layer has a stacked-layer structure of a layer containing a low-resistance metal material and a layer capable of reducing the contact resistance, both the contact resistance and the wiring resistance can be reduced, so that the load on the wirings can be reduced.

FIG. 12A illustrates an example in which the plug 27 penetrates the conductive layer 25h and is in contact with the conductive layer 25g. Such a structure in which the plug 27 is in contact with the low-resistance conductive layer 25g is preferable because the contact resistance therebetween can be reduced and the load on the wirings can be reduced. Note that a bottom surface of the plug 27 can be in contact with the conductive layer 25h or the semiconductor layer 21.

The semiconductor layer 21 is provided in contact with the side surface of the insulating layer 41 in the slit 20. An oxide insulating film is preferably used as the insulating layer 41b. In particular, an oxide insulating film from which oxygen is released by heating is preferably used. Furthermore, the insulating layer 41b is preferably interposed between the insulating layers 41a and 41c having a barrier property against oxygen. This enables oxygen contained in the insulating layer 41b to be enclosed in a region surrounded by the insulating layers 41a and 41c and the semiconductor layer 21. Furthermore, oxygen in the insulating layer 41b can be prevented from decreasing by being released during the process. Accordingly, oxygen can be supplied to the semiconductor layer 21 more efficiently.

A part of the semiconductor layer 21 that is in contact with the insulating layer 41b is a region where oxygen vacancies are reduced, i.e., an i-type region. The other part of the semiconductor layer 21 that is not in contact with the insulating layer 41b is preferably an n-type region including a large amount of carriers. That is, the part of the semiconductor layer 21 that is in contact with the insulating layer 41b can be referred to as a channel formation region and regions of the outer side of the channel formation region can be referred to as low-resistance regions (or a source region or a drain region).

The insulating layer 41b is preferably a film that includes hydrogen as little as possible because the insulating layer 41b is in contact with the semiconductor layer 21. Bonding of oxygen vacancies in the semiconductor layer 21 and hydrogen causes generation of carriers, which might affect the threshold voltage of the transistor 10, for example. Thus, the insulating layer 41b may be an insulating film which does not easily allow diffusion of hydrogen other than an oxide insulating film. For example, a single layer of an insulating film having a barrier property against hydrogen and oxygen can be used as the insulating layer 41.

The insulating layer 41b can be used as an interlayer insulating film. The insulating layer 41b is preferably formed by a film formation method such as a sputtering method or a plasma CVD method, for example. It is particularly preferable to employ a sputtering method, in which hydrogen does not need to be used for a deposition gas, to form a film having an extremely low hydrogen content. Consequently, supply of hydrogen to the semiconductor layer 21 is inhibited and the electrical characteristics of the transistor 10 can be stabilized.

The insulating layer 41b is in contact with the channel formation region of the semiconductor layer 21 and therefore is preferably formed using an oxide insulating film. In particular, an oxide insulating film that releases oxygen by heating is preferably used. An oxide insulating film that can be used as the gate insulating layer can be used as the insulating layer 41b.

Since the insulating layer 41b functions as an interlayer insulating layer, it is preferably formed by a film formation method that enables a higher film formation rate than those of the other insulating layers. For example, an insulating film formed by a plasma CVD method using TEOS may be used as the insulating layer 41b. This can increase the productivity.

The insulating layer 41b functioning as an interlayer insulating layer is preferably formed to have a lower dielectric constant than the other insulating layers, in which case the parasitic capacitance between the conductive layers 24 and 25 can be reduced.

As the insulating layers 41a and 41c, films which does not easily allow diffusion of hydrogen are preferably used. The layers 41a and 41c which does not easily allow diffusion of hydrogen are provided above and below the insulating layer 41b, respectively, thereby preventing entry of hydrogen from the outside into the insulating layer 41b in contact with the semiconductor layer 21.

For the insulating layer 41a and the insulating layer 41c, for example, one or more of silicon nitride, silicon nitride oxide, silicon oxynitride, aluminum oxide, aluminum oxynitride, aluminum nitride, hafnium oxide, and hafnium aluminate can be used. Silicon nitride and silicon nitride oxide are particularly suitable for the insulating layer 41a and the insulating layer 41c because they release fewer impurities (e.g., water and hydrogen) and are less likely to transmit oxygen and hydrogen.

The insulating layer 44b preferably functions as a barrier film against impurities. In this case, impurities such as hydrogen contained in the layer positioned above the insulating layer 44b can be prevented from diffusing into the semiconductor layer 21.

The structures and materials given for the insulating layers 41a and 41c, for example, can be used for the insulating layer 44b. The structure and materials given for the insulating layer 41b, for example, can be used for the insulating layers 44a and 44c.

The insulating layer 44a can function as an interlayer insulating film between the conductive layers 25 and 26. Using an insulating layer with a low dielectric constant as the insulating layer 44a can reduce the parasitic capacitance between the conductive layers 25 and 26. The insulating layer 44c is positioned between two conductive layers 23 that face each other. Using an insulating layer with a low dielectric constant as the insulating layer 44c can reduce the parasitic capacitance between the two facing conductive layers 23.

Examples of the material with a low relative permittivity include inorganic insulating materials such as silicon oxide and silicon oxynitride, and resins such as polyester, polyolefin, polyamide (e.g., nylon and aramid), polyimide, polycarbonate, and an acrylic resin. Other examples of the inorganic insulating material with a low relative permittivity include silicon oxide containing fluorine, silicon oxide containing carbon, and silicon oxide containing carbon and nitrogen. Another example is porous silicon oxide. Note that these silicon oxides can contain nitrogen.

Examples of the material with a high relative permittivity include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

As a barrier film that prevents diffusion of hydrogen and the like, a film which is less likely to allow diffusion of hydrogen (which has a higher barrier property against hydrogen) than a silicon oxide film, such as a silicon nitride film, a silicon nitride oxide film, an aluminum oxide film, a magnesium oxide film, a hafnium oxide film, or a gallium oxide film, can be used, for example. Specifically, a silicon nitride film or a silicon nitride oxide film is preferably used.

The insulating layers 46, 41, and 44, for example, each preferably have a stacked-layer structure of an insulating film functioning as the above-described barrier film and an insulating film having a function of capturing or fixing hydrogen. The insulating film having a function of capturing or fixing hydrogen is preferably positioned closer to the semiconductor layer 21 of the transistor 10 or the capacitor 30 than the insulating film functioning as a barrier film is. In this case, the insulating film can capture or fix hydrogen when heat is applied during the manufacturing process of the transistor 10 or the capacitor 30, for example, so that the concentration of hydrogen contained in the transistor 10 or the capacitor 30 can be reduced. Consequently, the memory cell 15 with favorable electrical characteristics and high reliability can be obtained. As the insulating film that captures or fixes hydrogen, a hafnium oxide film, a hafnium silicate film, an aluminum oxide film, a hafnium zirconium oxide film, or the like is preferably used.

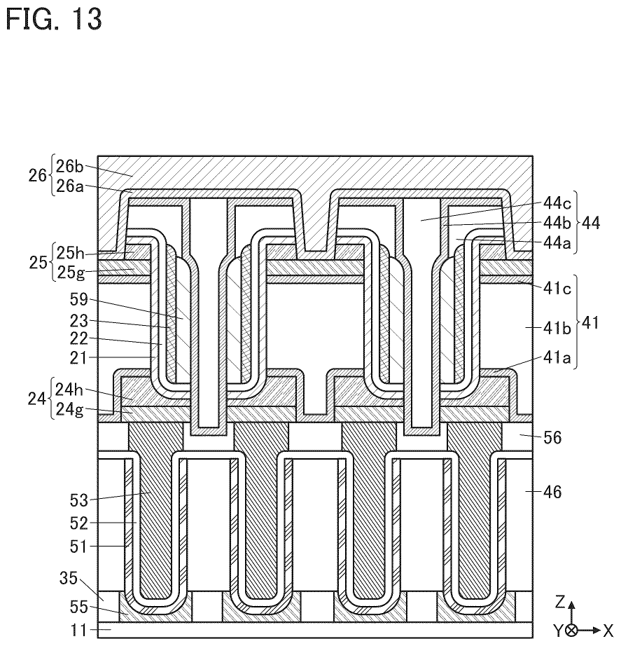

FIG. 13 is different from FIG. 12A in that the conductive layer 26 functions as a conductive layer over the insulating layer 44 and as a plug filling the opening portion in the insulating layer 44. The conductive layer 26 illustrated in FIG. 13 and the like can be formed by a dual damascene process, for example.

FIG. 13 illustrates an example in which the conductive layer 26 includes a conductive layer 26a and a conductive layer 26b over the conductive layer 26a. As the conductive layer 26a, a conductive layer with high coverage is preferably used. As the conductive layer 26a, for example, a conductive layer having a barrier property against oxygen, hydrogen, or the like may be used. For example, a metal nitride can be used for the conductive layer 26a. For the conductive layer 26b, a material with high conductivity is preferably used.

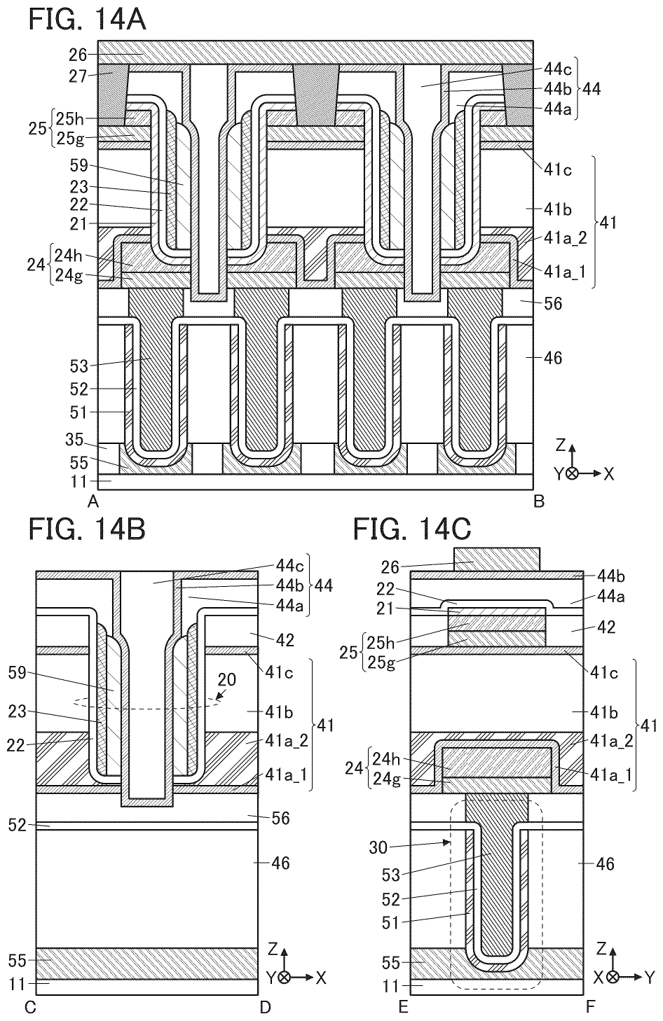

FIGS. 14A to 14C are different from FIGS. 12A to 12C mainly in that the insulating layer 41a includes an insulating layer 41a_1 and an insulating layer 41a_2 and a top surface of the insulating layer 41a_2 is planarized. The insulating layer 41a_1 can be formed by a film formation method that enables high coverage and is preferably formed by an ALD method or the like, for example. The insulating layer 41a_2 can be formed by a method with a high deposition rate and is preferably formed by a sputtering method or the like, for example. The insulating layer 41a_2 is formed to fill a region between the plurality of conductive layers 24. The top surface of the insulating layer 41a_2 is preferably planarized by planarization treatment.

Top surfaces of the insulating layers 41a, 41b, and 41c can be made flat. For example, the insulating layer 41a is subjected to planarization treatment after formed. As the planarization treatment, chemical mechanical polishing (CMP) treatment is suitable. As the planarization treatment, treatment using etching (also referred to as etch back treatment) may be performed. The insulating layers 41b and 41c are formed over the insulating layer 41a after the insulating layer 41a is subjected to planarization treatment, whereby the top surfaces of the insulating layers 41b and 41c can be made flat. By the planarization treatment on the insulating layer 41a, a region of the insulating layer 41a that does not overlap with the conductive layer 24 can be thicker than a region of the insulating layer 41a that overlaps with the conductive layer 24, for example.

In the case where etching takes a long time in an etching step in processing the semiconductor layer 21 in the slit 20, the region of the insulating layer 41 in the slit 20 that does not overlap with the conductive layer 24 is exposed to the etching gas for a long time. In such a case, the etching might reach the insulating layer 56 below the insulating layer 41 in the region so that the insulating layer 56 might be unintentionally processed. When the region of the insulating layer 41a that does not overlap with the conductive layer 24 has a larger thickness, the unintentional processing of the insulating layer 56 can be inhibited.

A material that can be used for the insulating layer 52 of the capacitor 30 and functions as a ferroelectric is described.

Examples of the material exhibiting ferroelectricity include oxides such as hafnium oxide, zirconium oxide, and hafnium zirconium oxide. A material obtained by adding a Group 3 (Group IIIa) element to any of these oxides is preferably used. For example, the oxide preferably contains one or more of scandium, yttrium, and an element belonging to lanthanoid. In particular, yttrium, lanthanum, or scandium is preferable because it is relatively easy to handle and has high compatibility with a semiconductor manufacturing process. When such an element is added, not only stable ferroelectricity can be exhibited but also degradation of characteristics caused by rewriting repeatedly can be inhibited, so that reliability can be improved. Furthermore, the breakdown voltage of the insulating layer 52 can be increased. For example, the element is preferably added at higher than or equal to 0.5 atomic % and lower than or equal to 10 atomic %. Here, the content percentage of these elements can be calculated such that the content percentages of the metal elements contained in the metal oxide described above are 100 atomic %, for example. For example, in the case where a first metal element and a second metal element are added to hafnium oxide, calculation can be performed such that the sum of the content percentages of hafnium, the first metal element, and the second metal element is 100 atomic %. Other examples of the additive element include silicon, aluminum, gadolinium, and scandium. Note that for the insulating layer 52, not only a material exhibiting ferroelectricity but also a material exhibiting anti-ferroelectricity can be used.

An oxide containing one or both of hafnium and zirconium exhibits ferroelectricity easily even when it is used in an extremely thin film formed by a formation method of a thin film, such as a sputtering method or an atomic layer deposition method, and thus the oxide has high compatibility with a semiconductor manufacturing process and can reduce the manufacturing cost.

For the insulating layer 52, a piezoelectric ceramic having a perovskite structure, such as barium titanate, lead titanate, strontium titanate, barium strontium titanate (BST), lead zirconate titanate (PZT), strontium bismuth tantalate (SBT), or bismuth ferrite (BFO), may be used.

For the insulating layer 52, an organic ferroelectric such as polyvinylidene fluoride (PVDF) or a copolymer of vinylidene fluoride (VDF) and trifluoroethylene (TrFE).

As the material exhibiting ferroelectricity, a mixture or compound containing a plurality of materials selected from the above-listed materials can be used, for example. Alternatively, the insulating layer 52 can have a stacked-layer structure of a plurality of materials selected from the above-listed materials.

Specifically, as the material exhibiting ferroelectricity, hafnium oxide, a material containing hafnium oxide and zirconium oxide (HZO), and a material containing yttrium in addition to HZO (HZYO) are preferable because they exhibit ferroelectricity even when being a thin film of several nanometers. With a film containing hafnium oxide, HZO, or HZYO, the thickness of the insulating layer 52 can be greater than or equal to 3 nm and less than or equal to 100 nm, preferably greater than or equal to 3 nm and less than or equal to 50 nm, further preferably greater than or equal to 3 nm and less than or equal to 20 nm, still further preferably greater than or equal to 4 nm and less than or equal to 10 nm.

In the case where hafnium zirconium oxide (HfZrO_{X} (X is a real number greater than 0)) is used as the material exhibiting ferroelectricity, film formation is preferably performed by an ALD method, particularly a thermal ALD method. It is preferable to use an ALD method (including a thermal ALD method) using plasma to increase reactivity (plasma enhanced ALD (PEALD) method).

In the case of using a thermal ALD method, a material containing an organometallic compound can be used as a precursor. For example, in the case where hafnium zirconium oxide is used, an organometallic compound such as tetrakis(ethylmethylamide) hafnium (TEMAHf) can be used as a precursor containing hafnium, and an organometallic compound such as tetrakis(ethylmethylamide) zirconium (TEMAZr) can be used as a precursor containing zirconium. Alternatively, a material that does not have a hydrocarbon group can be used. Examples of the precursor that does not have a hydrocarbon group include a chlorine-based material. Note that in the case of using hafnium zirconium oxide, a chlorine-based precursor such as HfCl₄ or ZrCl₄ can be used as a precursor.

Note that in the case where an oxide such as hafnium oxide, zirconium oxide, or hafnium zirconium oxide is used for the insulating layer 52, the remanent polarization can sometimes be increased when an appropriate amount of carbon is contained.

In the case where hafnium zirconium oxide is used for the insulating layer 52, a layer containing hafnium and a layer containing zirconium are preferably deposited alternately by a thermal ALD method or a PEALD method to have a composition of hafnium: zirconium at the atomic ratio of 1:1 or in the neighborhood thereof.

As an oxidizer used for the thermal ALD method or the PEALD method, H₂O or O₃ can be used. Note that the oxidizer is not limited thereto; O₂, N₂O, NO₂, H₂O₂, or the like can be used, and two or more of them may be used. In particular, to reduce the hydrogen concentration and the nitrogen concentration in the film, O₂ or O₃ is preferably used as the oxidizer, and O₃ is further preferably used.

The hydrogen concentration in a film used for the insulating layer 52 is preferably low. This can prevent diffusion of hydrogen from the insulating layer 52 into the semiconductor layer 21 and an increase in the carrier concentration in the semiconductor layer 21. Specifically, the hydrogen concentration in the film is preferably lower than or equal to 5×10²⁰ atoms/cm³, further preferably lower than or equal to 1×10²⁰ atoms/cm³.

A crystal structure of the film used for the insulating layer 52 is not particularly limited as long as the crystal structure is non-centrosymmetric and has polarity. For example, a crystal system except a cubic crystal system can be employed as the crystal structure of the film used for the insulating layer 52. The film used for the insulating layer 52 may have a single crystal structure or a polycrystalline structure, or may have a composite structure including an amorphous structure and a crystal structure.

Each of the conductive layers 51 and 53 that are in contact with the insulating layer 52 or positioned in the vicinity of the insulating layer 52 is preferably formed using a conductive material having a function of absorbing oxygen. Accordingly, oxygen can be absorbed from the insulating layer 52, so that the concentration of oxygen vacancies in the insulating layer 52 can be increased. Thus, the remanent polarization of the insulating layer 52 can be increased. As a conductive material having a function of absorbing oxygen, a metal or an alloy is preferably used. In particular, tungsten, molybdenum, titanium, tantalum, or the like is preferably used. Tungsten, which easily increases the remanent polarization of the insulating layer 52 in terms of stress, is particularly preferable.

A conductive material in which oxygen is less likely to diffuse is preferably used for each of the conductive layers 51 and 53. In this case, the breakdown voltage of the insulating layer 52 can be increased, and the rewrite endurance of the ferroelectric capacitor can be improved. It is particularly preferable to use a metal nitride such as titanium nitride or tantalum nitride.

The conductive layer 53 may have a stacked-layer structure. In that case, a low-resistance conductive material is preferably used for a layer not in contact with the insulating layer 52. For example, as the low-resistance conductive material, a metal or an alloy containing one or more selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like can be used. It is particularly preferable to use a high-melting-point material such as tungsten, molybdenum, tantalum, ruthenium, or hafnium because the temperature of heat treatment performed later can be high. Note that in addition to the above low-resistance conductive material, an oxide material such as indium tin oxide, indium tin oxide to which silicon is added, indium zinc oxide, or indium gallium zinc oxide may be used.

Here, in the semiconductor device 50, a layer where the memory cell 15 is provided and a layer where a functional circuit is provided are preferably stacked. As the functional circuit, a driver circuit for driving the memory cell 15, an arithmetic circuit, a power supply circuit, or the like can be provided, for example. The driver circuit includes, for example, one or more of a row decoder, a column decoder, a row driver, a column driver, an input circuit, an output circuit, and a sense amplifier. Accordingly, the footprint of the semiconductor chip including the semiconductor device 50 can be reduced, and wiring length can be shorter than that in the case where the functional circuit and the memory cell 15 are arranged side by side; hence, high-speed operation and low power consumption can be achieved.

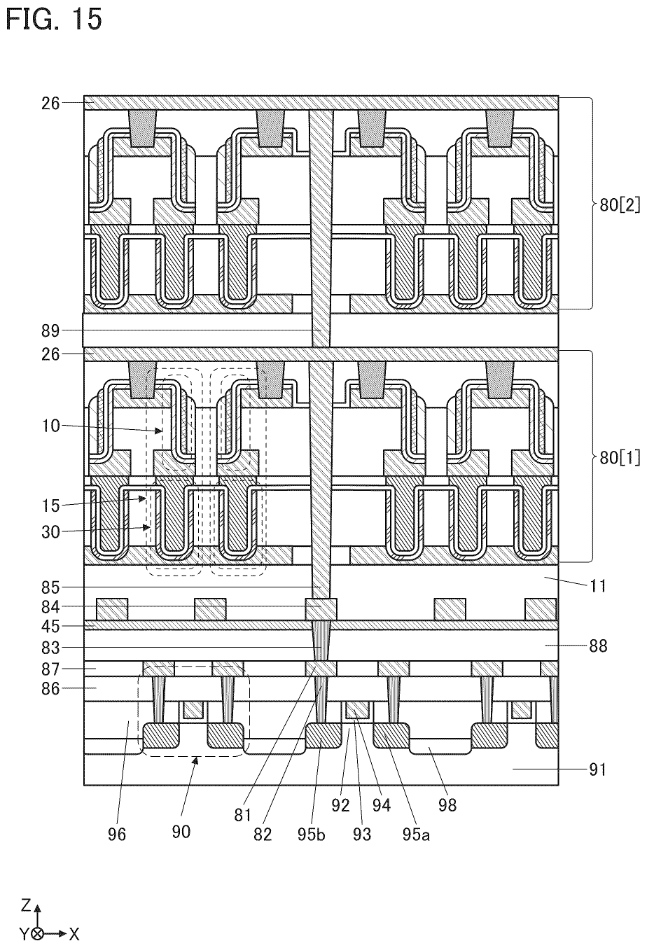

FIG. 15 illustrates an example in which a transistor 90 included in the functional circuit is provided below a layer 80 provided with the memory cell 15. In this example, one of a source electrode and a drain electrode of the transistor 90 is connected to the conductive layer 26 functioning as a bit line. Although FIG. 15 illustrates an example in which two layers 80 (a layer 80[1] and a layer 80[2]) are stacked, the layer 80 may be composed of only one layer or three or more layers.

The transistor 90 is a transistor whose channel is formed in part of a substrate 91, which is a single crystal semiconductor substrate. For the substrate 91, single crystal silicon can be typically used. For the substrate 91, a semiconductor of a single element such as germanium, or a compound semiconductor of silicon carbide, silicon germanium, gallium arsenide, indium phosphide, zinc oxide, gallium oxide, or gallium nitride can be used, for example. The above semiconductor substrate in which an insulator region is included, e.g., a silicon on insulator (SOI) substrate, may be used as the substrate 91.

The transistor 90 is provided on the substrate 91 and includes a conductive layer 94 functioning as a gate, an insulating layer 93 functioning as a gate insulating layer, a semiconductor region 92 that is a part of the substrate 91, and a low-resistance region 95a and a low-resistance region 95b functioning as a source region and a drain region. As the transistor 90, either a p-channel transistor or an n-channel transistor can be used. In the substrate 91, an element isolation layer 98 is provided between two adjacent transistors 90.

In the transistor 90, the semiconductor region 92 where a channel is formed has a projecting shape (fin shape). Although not illustrated in FIG. 15, the conductive layer 94 is provided to cover a side surface and the top surface of the semiconductor region 92 with the insulating layer 93 therebetween in the Y direction. A transistor like the transistor 90 is also referred to as a FIN transistor.

An insulating layer 96 is provided to cover the transistor 90, an insulating layer 86 is provided over the insulating layer 96, and an insulating layer 87 is provided over the insulating layer 86. A conductive layer 81 is provided to be embedded in the insulating layer 87. An insulating layer 88 is provided to cover the conductive layer 81 and the insulating layer 87, an insulating layer 45 is provided over the insulating layer 88, and the insulating layer 11 is provided over the insulating layer 45. A plug 82 is provided in the opening portion provided in the insulating layer 96 and the insulating layer 86, and the conductive layer 81 and the low-resistance region 95b are connected to each other through the plug 82. A conductive layer 84 is provided over the insulating layer 45, and the conductive layer 84 is connected to the conductive layer 81 through a plug 83 provided in an opening portion provided in the insulating layer 45 and the insulating layer 88. The conductive layer 84 and the conductive layer 26 are connected to each other through a plug 85 provided in an opening portion provided in each of the insulating layers between the conductive layer 84 and the conductive layer 26. Thus, one of a source and a drain of the transistor 90 is connected to the conductive layer 26.

Although an example in which the conductive layer 81 is provided as a wiring layer is described here, a structure in which an interlayer insulating layer and a wiring layer are alternately stacked (also referred to as a multilayer wiring layer) can be provided between the layer where the transistor 90 is provided and the layer 80 where the memory cell 15 is provided.

The plug 85 connects the conductive layer 84 to the conductive layer 26 included in the layer 80[1]. Furthermore, a plug 89 connects the conductive layer 26 included in one layer 80 to the conductive layer 26 included in another layer 80. Thus, two of the conductive layers 26 included in the layers 80[1] and 80[2] are connected to the one of the source and the drain of the transistor 90.

Although the structure in which the layer 80 is stacked directly over the substrate 91 where the transistor 90 is provided is described here, one embodiment of the present invention is not limited thereto. For example, the substrate 91 provided with the transistor 90 and the substrate provided with the memory cell 15 may be bonded to each other. For example, two substrates can be bonded to each other by direct bonding (hybrid bonding) using a direct bonding technique typified by Cu—Cu bonding. Alternatively, a method may be used in which two or more layers are bonded to each other with their insulating surfaces and then a through electrode is formed to connect electrodes or the like provided in the layers to each other. A method using direct bonding or a through electrode is particularly preferably used, in which case the pitch width between the connection electrodes can be extremely narrowed and thus a large amount of connection electrodes can be arranged at high density, whereby a larger amount of data can be transmitted between layers.

When two layers are bonded, any of a chip on chip (CoC) bonding, a chip on wafer (CoW) bonding, or a wafer on wafer (WoW) bonding may be used as a bonding method. The WoW bonding bonds wafers to each other and is thus excellent in productivity; however, since the WoW bonding bonds all the chips, including defective and non-defective chips, to each other, the yield is reduced in some cases. Meanwhile, the CoW bonding where a chip is bonded to a wafer and the CoC bonding where chips are bonded to each other are inferior to the WoW bonding in terms of productivity; however, the CoW bonding and the CoC bonding can bond non-defective chips to each other and thus achieve a significantly improved yield. Although the CoC bonding is less productive than the other two bonding methods, the CoC bonding can bond two layers with largely different sizes and thus has high versatility.

Note that a wiring layer such as an interposer may be provided between two layers. Thus, the positions of the bonding electrodes and the like do not need to be aligned between the two adjacent layers, so that the design flexibility of the layers can be increased and a semiconductor device with higher performance can be achieved.

### [Components]

### <Substrate>

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, gallium oxide, or gallium nitride. Other examples include the above semiconductor substrate including an insulator region, e.g., an SOI substrate. Examples of the conductor substrate include a graphite substrate, a metal substrate, an alloy substrate, and a conductive resin substrate. Other examples of the conductor substrate include a substrate including a nitride of a metal and a substrate including an oxide of a metal. Moreover, other examples of the conductor substrate include an insulator substrate provided with a conductive layer or a semiconductor layer, a semiconductor substrate provided with a conductive layer or an insulating layer, and a conductor substrate provided with a semiconductor layer or an insulating layer. Alternatively, these substrates provided with elements may be used. Examples of the elements provided over the substrates include a capacitor, a resistor, a switching element (such as a transistor), a light-emitting element, and a memory element.

### <Semiconductor Layer>

The semiconductor layer 21 preferably includes a metal oxide (an oxide semiconductor).

As described above, the semiconductor layer 21 includes a channel formation region. The semiconductor layer 21 further includes a source region and a drain region. The source region and the drain region are n-type regions (low-resistance regions) having a higher carrier concentration than the channel formation region. The semiconductor layer 21 may have a stacked-layer structure of two or more layers.

There is no particular limitation on the crystallinity of the semiconductor material used for the semiconductor layer 21, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

When oxygen vacancies (V_{O}) and impurities are in a channel formation region of a metal oxide in an OS transistor, electrical characteristics of the OS transistor easily vary and the reliability thereof might worsen. In some cases, a defect that is an oxygen vacancy into which hydrogen enters (hereinafter, sometimes referred to as V_{O}H) is formed and an electron functioning as a carrier is generated. Thus, if the channel formation region of the metal oxide includes oxygen vacancies, the OS transistor tends to have normally-on characteristics. Therefore, the oxygen vacancies and the impurities are preferably reduced as much as possible in the channel formation region in the metal oxide. In other words, the metal oxide preferably includes an i-type (intrinsic) or substantially i-type channel formation region with a low carrier concentration.

Meanwhile, preferably, the source region and the drain region of the OS transistor include more oxygen vacancies, include more V_{O}H, or have a higher concentration of an impurity such as hydrogen, nitrogen, or a metal element than the channel formation region, and thus are low-resistance regions with high carrier concentrations. In other words, the source region and the drain region of the OS transistor are preferably n-type regions having higher carrier concentrations and lower resistances than the channel formation region.

The band gap of the metal oxide functioning as a semiconductor is preferably greater than or equal to 2.0 eV, further preferably greater than or equal to 2.5 eV. The use of a metal oxide having a wide band gap for the oxide semiconductor layer can reduce the off-state current of the transistor. The off-state current of the OS transistor is small, so that power consumption of the semiconductor device can be sufficiently reduced. The OS transistor has high frequency characteristics, which enables the semiconductor device to operate at high speed.

Examples of the metal oxide that can be used for the semiconductor layer of the OS transistor include indium oxide.

Examples of the metal oxide that can be used for the semiconductor layer of the OS transistor include an oxide containing one or more elements selected from In, Sn, Zn, Ga, Al, and Ti. In these oxides, the content percentage of one or more elements selected from In, Sn, Zn, Ga, Al, and Ti is preferably higher than or equal to 1 atomic %, for example.

As the metal oxide, in addition to indium oxide described above, it is possible to use zinc oxide, tin oxide, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (In—Sn—Zn oxide), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO), for example. Alternatively, indium tin oxide containing silicon, gallium tin oxide (Ga—Sn oxide), aluminum tin oxide (Al—Sn oxide), or the like can be used.

Specifically, an atomic ratio of In:Zn=1:1 or in the neighborhood thereof, an atomic ratio of In:Zn=2:1 or in the neighborhood thereof, or an atomic ratio of In:Zn=4:1 or in the neighborhood thereof can be employed as the composition. Note that the neighborhood of the atomic ratio includes ±30% of an intended atomic ratio.

Specifically, an In-M-Zn metal oxide having an atomic ratio of In:M:Zn=1:1:1 or the neighborhood thereof, In:M:Zn=1:1:1.2 or the neighborhood thereof, In:M:Zn=1:1:0.5 or the neighborhood thereof, In:M:Zn=1:1:2 or the neighborhood thereof, In:M:Zn=4:2:3 or the neighborhood thereof, In:M:Zn=1:3:2 or the neighborhood thereof, or In:M:Zn=1:3:4 or the neighborhood thereof is used as the composition. Alternatively, a metal oxide containing a slight amount of the element M can have an atomic ratio of, for example, In:M:Zn=4:0.1:1 or the neighborhood thereof, In:M:Zn=2:0.1:1 or the neighborhood thereof, or In:M:Zn=1:0.1:1 or the neighborhood thereof. Examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

Amorphous (including a completely amorphous structure), c-axis-aligned crystalline (CAAC), nanocrystalline (nc), cloud-aligned composite (CAC), single-crystal, polycrystalline structures, and the like can be given as examples of the crystal structure of the metal oxide functioning as a semiconductor.

Increasing the proportion of zinc atoms to the sum of atoms of the metal elements that are the main components in the metal oxide enables the metal oxide to have high crystallinity, so that diffusion of impurities in the metal oxide can be inhibited. Consequently, a change in the electrical characteristics of the transistor can be reduced to improve the reliability of the transistor.

Increasing the proportion of the element M atoms to the sum of atoms of the metal elements that are the main components in the metal oxide can inhibit formation of oxygen vacancies in the metal oxide. Accordingly, generation of carriers due to oxygen vacancies is inhibited, which makes the off-state current of the transistor low. Furthermore, a change in the electrical characteristics of the transistor can be reduced to improve the reliability of the transistor.

Increasing the proportion of indium atoms to the sum of atoms of all the metal elements in the metal oxide can increase the field-effect mobility of the transistor. Typically, a transistor using single crystal indium oxide or polycrystal indium oxide for a semiconductor layer can have significantly increased field-effect mobility. A transistor using single crystal indium oxide or polycrystal indium oxide for a semiconductor layer can also have favorable frequency characteristics.

The oxide semiconductor layer in one embodiment of the present invention includes, for example, a metal oxide having crystallinity. Examples of the structure of a metal oxide having crystallinity include a CAAC structure, a polycrystal structure, and an nc structure. By using a metal oxide having crystallinity for the oxide semiconductor layer, the density of defect states in the oxide semiconductor layer can be reduced. This can improve the reliability of the transistor including the oxide semiconductor layer of one embodiment of the present invention, thereby improving the reliability of a semiconductor device including the transistor.

For the semiconductor device of this embodiment, a transistor including a different semiconductor material in its channel formation region may be used. Examples of the different semiconductor material include a single-element semiconductor and a compound semiconductor.

Examples of the single-element semiconductor that can be used as the semiconductor material include silicon and germanium. Examples of silicon that can be used as the semiconductor material include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic crystal structure. Other examples of the compound semiconductor include an organic semiconductor and a nitride semiconductor. Note that the above-described metal oxide is also one kind of the compound semiconductor. These semiconductor materials may contain an impurity as a dopant.

An indium oxide film that can be used for the oxide semiconductor layer of one embodiment of the present invention will be described below.

In this specification and the like, indium oxide including at least a crystal part or a crystal region in a film is referred to as crystal IO or crystalline IO. Examples of crystal IO or crystalline IO include single crystal indium oxide, polycrystal indium oxide, and microcrystal indium oxide.

Indium oxide is a semiconductor material having physical properties completely different from those of an oxide semiconductor such as In—Ga—Zn oxide (hereinafter, also referred to as IGZO) or zinc oxide.

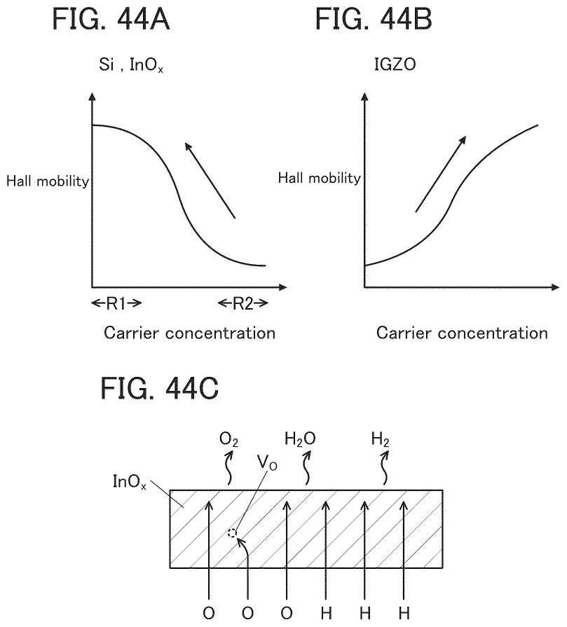

The dependence of the Hall mobility on the carrier concentration of indium oxide, silicon, and IGZO will be described. FIG. 44A is a schematic view showing the dependence of the Hall mobility on the carrier concentration of silicon (Si) and indium oxide (InO_{X}), and FIG. 44B is a schematic view showing the dependence of the Hall mobility on the carrier concentration of IGZO.

As indicated by an arrow in FIG. 44B, IGZO has a tendency in which the Hall mobility is higher as the carrier concentration is higher. By contrast, as indicated by an arrow in FIG. 44A, indium oxide has a tendency in which the Hall mobility is higher as the carrier concentration is lower (see Non-Patent Document 1). This tendency is similar to that of silicon; as the concentration of a dopant (impurity) in a material is lower, impurity scattering is inhibited more and thus the Hall mobility is higher. That is, indium oxide having higher purity and being more intrinsic has higher Hall mobility. Consequently, the physical properties of indium oxide are different from those of IGZO and similar to those of silicon. Note that the characteristics of indium oxide in FIG. 44A are based on the assumption of single crystal indium oxide; thus, the characteristics of non-single-crystal (e.g., polycrystal) indium oxide are sometimes different from those in FIG. 44A.

In FIG. 44A, the Hall mobility is extremely high in a range R1 with a low carrier concentration; thus, the range R1 can be regarded as a carrier concentration range suitable for a channel formation region of a transistor, for example. In the case of indium oxide, for example, the range R1 is a range including a carrier concentration of 1×10¹⁵ cm⁻³, e.g., a range with a carrier concentration higher than or equal to 1×10¹⁴ cm⁻³ and lower than or equal to 1×10¹⁸ cm⁻³. The adequately lowered carrier concentration will increase the Hall mobility to approximately 270 cm²/(V·s).

A region of indium oxide where the carrier concentration falls within the range R1 can include an element that reduces the carrier concentration. Examples of the element that reduces the carrier concentration include magnesium, calcium, zinc, cadmium, and copper. When indium is replaced with any of these elements, the carrier concentration can be reduced. Other examples of the element that reduces the carrier concentration include nitrogen, phosphorus, arsenic, and antimony. For example, when oxygen is replaced with nitrogen, phosphorus, arsenic, or antimony, the carrier concentration can be reduced.

A range R2 with a high carrier concentration has low electric resistance and is a carrier concentration range suitable for a source region and a drain region of a transistor, a resistor, or a transparent conductive film, for example. The range R2 is a range including a carrier concentration of 1×10²⁰ cm⁻³, e.g., a range with a carrier concentration higher than or equal to 1×10¹⁹ cm⁻³ and lower than or equal to 1×10²² cm⁻³. The adequately increased carrier concentration will decrease the resistivity to 1×10⁻⁴ Ω·cm or lower.

A region of indium oxide where the carrier concentration falls within the range R2 can include an element that increases the carrier concentration. For example, the region preferably includes the same element as a source electrode and a drain electrode of a transistor. Examples of the element that increases the carrier concentration include titanium, zirconium, hafnium, tantalum, tungsten, molybdenum, tin, silicon, and boron. It is particularly preferable that an oxide of the element have conductivity or semiconductor properties. As a method for supplying the element that increases the carrier concentration, a method in which a film containing the element is formed to diffuse the element, an ion implantation method, an ion doping method, a plasma immersion ion implantation method, or plasma treatment can be employed. In this specification and the like, whether or not mass separation is performed is not limited, unless otherwise specified. In this specification and the like, a method by which mass-separated ions are supplied is referred to as an ion implantation method, and a method by which non-mass-separated ions are supplied is referred to as an ion doping method, for example.

In this manner, the region with a low carrier concentration and the region with a high carrier concentration of indium oxide are used as a channel formation region and source and drain regions, respectively, of a transistor. That is, indium oxide can be regarded as an oxide whose valence electron can be controlled. As for IGZO, distortion due to stress of an electrode in contact with IGZO is formed in a source region and a drain region and n-type regions are formed in some cases. Since a valence electron can be controlled in indium oxide unlike in IGZO, formation of distortion can be inhibited in a film of indium oxide. The film with less distortion will have higher reliability. For example, when the region where the carrier concentration falls within the range R1 and the region where the carrier concentration falls within the range R2, which are shown in FIG. 44A, are separately formed in an indium oxide film, what is called an n-i-n junction (a junction between an n-type region, an i-type region, and an n-type region) can be formed. Although valence electron control in a transistor containing silicon is generally known, valence electron control in a transistor containing indium oxide is a novel technical idea that cannot be conceived usually.

With the use of the above technical idea, a transistor containing indium oxide in this specification and the like has two or more, preferably three or more, further preferably four or more, and most preferably all of the following features (1) to (5): (1) high on-state current (i.e., high mobility); (2) low off-state current; (3) normally-off characteristics; (4) high reliability; and (5) high cutoff frequency (fT). For example, the transistor containing indium oxide in this specification and the like has high mobility, low off-state current, and normally-off characteristics. This transistor is different from a normally-on transistor having high mobility.

The expression “a semiconductor is of an i-type” can be replaced with the expression “the Fermi level (Ef) is equal to the intrinsic Fermi level (Ei) (Ef=Ei)”. As shown in FIG. 44B, the Hall mobility is lower as the carrier concentration is lower in IGZO. Accordingly, in the case where Ef eventually becomes equal to Ei, carriers disappear (i.e., the physical properties of IGZO become similar to those of an insulator) and a transistor containing IGZO cannot operate. By contrast, the Hall mobility is higher as the carrier concentration is lower in indium oxide as shown in FIG. 44A. In the case where Ef eventually becomes equal to Ei, the Hall mobility is the highest. That is, a transistor containing indium oxide can have high field-effect mobility when Ef is equal to Ei. Note that a transistor containing indium oxide has a low carrier concentration and thus tends to be normally off. Hence, a transistor containing indium oxide can have both normally-off characteristics and high field-effect mobility.

Normally off means a state where no current flows through a transistor when a potential is not applied to its gate or its gate-source voltage is 0 V. The normally-off characteristics can be evaluated using the threshold voltage (Vth) or shift value (Vsh) of a transistor. Note that Vth is calculated by a constant current method unless otherwise specified. Specifically, Vth is gate voltage (Vg) at which a value of drain current (Id)×channel length (L)/channel width (W) in the Id-Vg characteristics of a transistor is 1 nA (1×10⁻⁹ A). Vsh is gate voltage (Vg) at a point of intersection of a straight line of Id=1 pA (1×10⁻¹² A) and a tangent line of drain current (Id) on a logarithmic scale that has the highest gradient in the Id-Vg characteristics of the transistor, or gate voltage (Vg) at a point of intersection of a straight line of Id=1 pA and a straight line extrapolated from two points where the slope of Id on a logarithmic scale has the highest gradient in the Id-Vg characteristics of the transistor. For example, when at least one of Vth and Vsh is 0 or a positive value, the transistor can be regarded as being normally off.

In order that a semiconductor can be of an i-type, i.e., Ef can be equal to Ei, in a transistor containing indium oxide, the structure of a film in contact with an indium oxide film is important. For example, a transistor containing indium oxide can have a film structure in which a silicon oxide film, which is in contact with an indium oxide film, a hafnium oxide film, and a silicon nitride film are stacked. Such a film structure can achieve Ef=Ei, enabling a semiconductor device to have high reliability.

In the above film structure, a film containing oxygen, such as a silicon oxynitride film, a silicon nitride oxide film, an aluminum oxide film, or a gallium oxide film, can be used instead of the silicon oxide film. Also in the above film structure, a silicon nitride oxide film, a silicon oxynitride film, or the like can be used instead of the silicon nitride film. The hafnium oxide film that is closer to the indium oxide film than the silicon nitride film is functions as a hydrogen gettering site.

The above film structure can be regarded as a structure in which a film that is capable of supplying oxygen to the indium oxide film (e.g., the silicon oxide film), a film that is capable of gettering hydrogen (e.g., the hafnium oxide film), and a film that is capable of inhibiting entry of oxygen and hydrogen (e.g., the silicon nitride film) are stacked in this order from the indium oxide film side. With this structure, oxygen vacancies in the indium oxide film are filled with oxygen in the silicon oxide film. Moreover, hydrogen in the indium oxide film is captured in the hafnium oxide film by heat treatment or the like. Providing the silicon nitride film inhibits entry of oxygen and hydrogen from the outside. That is, the above film structure enables the indium oxide film to be closer to an i-type film. Thus, a transistor including the indium oxide film has high field-effect mobility and high reliability.

Next, an indium oxide film used for a transistor will be described. The indium oxide film preferably has crystallinity (i.e., has a crystal grain). Examples of a film having a crystal grain include a single crystal film, a polycrystal film, and an amorphous film having a crystal grain (also referred to as a microcrystal film). In particular, the indium oxide film is preferably a polycrystal film, further preferably a single crystal film. A single crystal film does not have a crystal grain boundary (also referred to as a grain boundary). Impurities that block the carrier flow (typically, an insulating impurity, an insulating oxide, or the like) are likely to be segregated at a crystal grain boundary. The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystal film is preferable because it can reduce carrier scattering as compared with a microcrystal film or an amorphous film and enables a transistor to have high field-effect mobility. In the case of using a polycrystal film, it is preferable to use a film that has as large a crystal grain size as possible and few crystal grain boundaries. In the case where the crystal grain boundary is neither included nor observed in a channel formation region of a transistor including a polycrystal indium oxide film, the channel formation region is positioned in a single crystal region included in the polycrystal film and thus the transistor can be regarded as a transistor containing single crystal indium oxide.

The crystallinity of indium oxide can be analyzed with an X-ray diffraction (XRD) pattern, a transmission electron microscope (TEM) image, or an electron diffraction (ED) pattern, for example. Alternatively, two or more of these methods may be combined for the analysis.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be referred to as a single crystal film. A semiconductor layer where the direction of a crystal axis is continuously changed with another crystal axis or a crystal orientation as a rotation axis in one crystal grain in a channel formation region can also be referred to as a single crystal film.

A channel formation region refers to a region of a semiconductor layer that overlaps with (or faces) a gate electrode with a gate insulating layer therebetween and is positioned between a region in contact with a source electrode and a region in contact with a drain electrode. A current path in a channel formation region is the shortest distance between a source electrode and a drain electrode. Thus, a crystal grain, a crystal grain boundary, a crystal axis, a crystal orientation, or the like in a channel formation region can be confirmed in observation of a cross section including a semiconductor layer, a source electrode, and a drain electrode.

The impurity concentration in an indium oxide film in a channel formation region is preferably as low as possible. Impurities in the indium oxide film in the channel formation region can function as a carrier scattering source and cause a reduction in field-effect mobility. Such impurities might inhibit crystal growth of the indium oxide film. Examples of the impurities for the indium oxide film include boron and silicon. The concentrations of these impurities in the indium oxide film are each preferably lower than or equal to 0.1%, further preferably lower than or equal to 0.01% (100 ppm). Note that carbon, hydrogen, and the like are elements that would be contained in a film formation gas or a precursor in film formation, and the amounts of these elements remaining in the indium oxide film might be larger than those of the impurities.

The indium oxide film in the channel formation region may contain an element that can form a trivalent cation like indium as long as the cubic crystal structure (bixbyite structure) is retained. Examples of the element include Group 13 elements such as gallium and aluminum and Group 3 elements in the periodic table. Since these elements exist mainly as trivalent cations in oxides, the carrier concentration of indium oxide can be kept low.

An indium oxide film in this specification and the like has high film density. Table 1 lists the film densities of indium oxides (In₂O₃ here) that can be used in one embodiment of the present invention.

TABLE 1
Film density of In₂O₃

| | | | | Film |
|---|---|---|---|---|
| | | | | density |
| | Condition 1 | Condition 2 | Condition 3 | [g/cm³] |
| Sample 1 | glass | SP | as-depo | 6.72 |
| Sample 2 | glass | SP | 350° C. baking in | 6.75 |
| | | | CDA | |
| Sample 3 | glass | SP | 650° C. baking in | 6.74 |
| | | | CDA | |
| Sample 4 | SiOx | ALD | as-depo | 6.97 |
| Sample 5 | YSZ | ALD | as-depo | 7.05 |
| Sample 6 | YSZ | ALD | 250° C. baking in | 7.08 |
| | | | vacuum | |

As shown in Table 1, the film densities of the indium oxide films are evaluated at six levels, Sample 1 to Sample 6. In Table 1, Condition 1 corresponds to the base conditions of the indium oxide films: glass for Samples 1 to 3; a SiOx film formed by a sputtering method for Sample 4; and yttria-stabilized zirconia (YSZ) for Samples 5 and 6. Condition 2 corresponds to the deposition conditions of the indium oxide films: a sputtering (SP) method for Samples 1 to 3; and an ALD method for Samples 4 to 6. Condition 3 corresponds to the heat treatment conditions after the deposition of the indium oxide films: no heat treatment (as-depo) for Samples 1, 4, and 5; 350° C. baking in a CDA atmosphere for Sample 2; 650° C. baking in a CDA atmosphere for Sample 3; and 250° C. baking in a vacuum atmosphere for Sample 6.

In Table 1, CDA means clean dry air. Note that the content of hydrogen, water, and the like in the atmosphere for the heat treatment (corresponding to Condition 3) after the deposition of the indium oxide films is preferably as low as possible. As the atmosphere, a high-purity gas with a dew point of −60° C. or lower, preferably −100° C. or lower is preferably used.

As shown in Table 1, the indium oxide film that is subjected to heat treatment tends to have a higher film density than the film that is not subjected to heat treatment (Sample 1, 4, or 5). This is because heat treatment causes release of impurity elements (e.g., carbon, nitrogen, hydrogen, and argon) from the film, making the indium oxide film highly purified. As can be found from Samples 5 and 6, the indium oxide films over YSZ each have a film density exceeding 7.00 g/cm³. The theoretical film density of the indium oxide film is 7.18 g/cm³. The film density of the indium oxide film in this specification and the like ranges from 6.70 g/cm³ to 7.18 g/cm³, preferably from 6.90 g/cm³ to 7.18 g/cm³, further preferably from 7.00 g/cm³ to 7.18 g/cm³.

The film density can be evaluated by Rutherford backscattering spectrometry (RBS) or X-ray reflection (XRR), for example. A difference in film density can be evaluated using a cross-sectional TEM image in some cases. In TEM observation, a transmission electron (TE) image is dark-colored (dark) when the film density is high, and a TE image is pale (bright) when the film density is low.

A transistor including the above indium oxide film can have a field-effect mobility higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

One feature of an indium oxide film is to have a higher property of transmitting (diffusing) oxygen than an IGZO film. As shown in FIG. 44C, oxygen (O) diffusing in an indium oxide film (denoted as InO_{X}) is transmitted through the indium oxide film and released as an oxygen molecule (O₂). When reacting with hydrogen contained in the film, oxygen is released as a water molecule (H₂O) in some cases. In the case where the film includes oxygen vacancies (V_{O}), the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

As shown in FIG. 44C, hydrogen diffuses in the indium oxide film. Hydrogen diffusing into the indium oxide film from the outside is transmitted through the indium oxide film and is released as a hydrogen molecule (H₂). When reacting with oxygen contained in the film, hydrogen is released as a water molecule.

A transistor including an indium oxide film is an accumulation-type transistor in which electrons are majority carriers. Assuming that the relaxation time of carriers is constant, the electron (carrier) mobility is higher as the effective mass of electrons (carriers) is smaller. That is, a transistor in which an indium oxide with a small effective mass of electrons is used for a semiconductor layer can have a high on-state current or high field-effect mobility.

Table 2 shows the effective mass in each of single crystal indium oxide (here, In₂O₃) and single crystal silicon (Si). As shown in Table 2, indium oxide has features of a small effective mass of electrons and a large effective mass of holes. In addition, the effective mass of electrons in indium oxide hardly depends on the crystal orientation. Thus, a transistor containing indium oxide having crystallinity can have high field-effect mobility and high frequency characteristics (also referred to as f characteristics). A large effective mass of holes allows a transistor to have an extremely low off-state current. For example, the off-state current per micrometer of channel width of a vertical transistor including an indium oxide film can be lower than or equal to 1 fA (1×10⁻¹⁵ A) or lower than or equal to 1 aA (1×10⁻¹⁸ A) at 125° C., and can be lower than or equal to 1 aA (1×10⁻¹⁸ A) or lower than or equal to 1 zA (1×10⁻²¹ A) at room temperature (25° C.). Since indium oxide has a smaller effective mass of electrons and a larger effective mass of holes than silicon as shown in Table 2, a transistor containing indium oxide can have higher field-effect mobility and lower off-state current than a Si transistor.

TABLE 2
Effective mass in In₂O₃

| Electron | | | |
|---|---|---|---|
| [100] orientation | [110] orientation | [111] orientation | Hole |
| 0.17 | 0.18 | 0.19 | 3.56 |

Effective mass in Si

| Electron | Hole |
|---|---|
| 0.26 | 0.17 |

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In this case, the crystallinity of the indium oxide film can be improved. As a layer in contact with at least part of the indium oxide film having crystallinity, a substrate (e.g., a single crystal substrate) may be used.

One of methods for evaluating the degree of a lattice mismatch is a method using a value of a lattice mismatch degree described below. A lattice mismatch degree Δa [%] of a crystal included in a film to be formed (here, the indium oxide film) with respect to the crystal included in the seed layer is calculated by the formula: Δa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Δa between the seed layer and the indium oxide film is preferably as small as possible, most preferably 0. For example, Δa can be greater than or equal to −5% and less than or equal to 5%, preferably greater than or equal to −4% and less than or equal to 4%, further preferably greater than or equal to −3% and less than or equal to 3%, still further preferably greater than or equal to −2% and less than or equal to 2%.

An indium oxide crystal has a cubic crystal structure (a bixbyite structure). For example, an yttria-stabilized zirconia (YSZ) crystal can have a cubic crystal structure (a fluorite crystal structure). The lattice mismatch degree of an indium oxide crystal with respect to an YSZ crystal having the cubic crystal structure is within the range of −2% to 2%, which enables epitaxial growth of a single crystal film of indium oxide over the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film including a crystal with a cubic crystal structure. For example, when the crystal orientation of a seed layer surface is set to and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO. A single crystal film of indium oxide can be formed not only over a YSZ substrate but also over an insulating film. By contrast, a single crystal film of silicon is not easily formed over an insulating film. Note that a silicon crystal has a diamond structure. Thus, although indium oxide and silicon exhibit similar characteristics as single crystals, they differ in whether a single crystal can be formed over an insulating film.

Note that a semiconductor material that can be used for the semiconductor layer 21 is not limited to an oxide semiconductor. For example, a single-element semiconductor or a compound semiconductor can be used. Examples of the single-element semiconductor include silicon (such as single crystal silicon, polycrystalline silicon, microcrystalline silicon, and amorphous silicon) and germanium. Examples of the compound semiconductor include gallium arsenide and silicon germanium. Examples of the compound semiconductor include an organic semiconductor, a nitride semiconductor, and an oxide semiconductor. These semiconductor materials may contain impurities as dopants.

Alternatively, the semiconductor layer 21 may include a layered material functioning as a semiconductor. The layered material generally refers to a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

There is no particular limitation on the crystallinity of a semiconductor material used for the semiconductor layer 21, and any of an amorphous semiconductor, a single crystal semiconductor, and a semiconductor having other crystallinity than single crystal (a polycrystalline semiconductor, a microcrystalline semiconductor, or a semiconductor partly including crystal regions) may be used. A semiconductor having crystallinity is preferably used, in which case deterioration of transistor characteristics can be suppressed.

### <Gate Insulating Layer>

The insulating layer 22 functions as a gate insulating layer of the transistor. In the case where the semiconductor layer 21 is formed using an oxide semiconductor, an oxide insulating film is preferably used for at least a part of the insulating layer 22 that is in contact with the semiconductor layer 21. For example, one or more of silicon oxide, silicon oxynitride, aluminum oxide, aluminum oxynitride, hafnium oxide, hafnium oxynitride, gallium oxide, gallium oxynitride, yttrium oxide, yttrium oxynitride, and Ga—Zn oxide can be used. In addition, as the insulating layer 22, a nitride insulating film of silicon nitride, silicon nitride oxide, aluminum nitride, or aluminum nitride oxide can also be used. The insulating layer 22 may have a stacked-layer structure, e.g., a stacked-layer structure including at least one oxide insulating film and at least one nitride insulating film.

The insulating layer 22 preferably has a stacked-layer structure using an insulating material that includes a material having higher dielectric strength (a high-k material). A stacked-layer structure including a high-k material and a material having higher dielectric strength than the high-k material is preferably used. For example, as the insulating layer 22, an insulating film (also referred to as ZAZ) in which zirconium oxide, aluminum oxide, and zirconium oxide are stacked in this order can be used. An insulating film (also referred to as ZAZA) in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor.

Alternatively, a material that exhibits ferroelectricity may be used for the insulating layer 22. Examples of the material that exhibits ferroelectricity include metal oxides such as hafnium oxide, zirconium oxide, and HfZrO_{X} (X is a real number greater than 0). A metal oxide obtained by adding Y (yttrium) to HfZrO_{X} can also be used. When Y is added to HfZrO_{X}, the ferroelectricity can be enhanced.

In the case where the insulating layer 22 has a two-layer structure, an insulating film having a function of capturing or fixing hydrogen is preferably used as a film in contact with the semiconductor layer 21, and an insulating film having a barrier property against hydrogen is preferably used as a film closer to the conductive layer 23 functioning as the gate electrode. This can inhibit diffusion of hydrogen into the semiconductor layer 21 from the conductive layer 23 side, so that the transistor can have high reliability.

As the insulating film that captures or fixes hydrogen, a hafnium oxide film, a hafnium silicate film, an aluminum oxide film, or the like is preferably used. As the insulating film having a barrier property against hydrogen, a silicon nitride film, a silicon nitride oxide film, an aluminum oxide film, a magnesium oxide film, a hafnium oxide film, a gallium oxide film, or the like is preferably used.

Alternatively, an insulating film that releases oxygen by heating may be used as the film in contact with the semiconductor layer 21, and an insulating film having a barrier property against hydrogen may be used as the film positioned on the conductive layer 23 side. Alternatively, an insulating film that releases oxygen by heating may be used as the film in contact with the semiconductor layer 21, and an insulating film having a function of capturing or fixing hydrogen may be used as the film positioned on the conductive layer 23 side.

In the case where the insulating layer 22 has a three-layer structure, it is preferable that an insulating film including a material having a lower dielectric constant than other films be used as the film in contact with the semiconductor layer 21, an insulating film having a barrier property against hydrogen and oxygen be used as the film positioned on the conductive layer 23 side, and an insulating film having a function of capturing or fixing hydrogen be used as a film positioned between the film in contact with the semiconductor layer 21 and the film positioned on the conductive layer 23 side. As a low-dielectric-constant material, silicon oxide or silicon oxynitride can be used. With such a structure, oxygen can be supplied from the film in contact with the semiconductor layer 21 to the semiconductor layer 21. The film positioned on the conductive layer 23 side can prevent diffusion of oxygen to the conductive layer 23 side and inhibit oxidation of the conductive layer 23.

As an insulating film having a barrier property against oxygen, an aluminum oxide film, a silicon nitride film, a hafnium oxide film, a hafnium silicate film, or the like is preferably used. As an insulating film having a barrier property against oxygen and hydrogen, an aluminum oxide film, a silicon nitride film, a hafnium oxide film, or the like is preferably used.

In the case where the insulating layer 22 has a four-layer structure, it is preferable that an insulating film having a barrier property against oxygen be used as the film in contact with the semiconductor layer 21, an insulating film including a material having a lower dielectric constant than the other films be used as the film that is the second closest to the semiconductor layer 21, an insulating film having a function of capturing or fixing hydrogen be used as the film that is the third closest to the semiconductor layer 21, and an insulating film having a barrier property against hydrogen and oxygen be used as the film that is the closest to the conductive layer 23. That is, a structure in which the film in contact with the semiconductor layer 21 is added to the above-described three-layer structure can be employed. When an insulating film having a barrier property against oxygen is used as the film in contact with the semiconductor layer 21, release of oxygen from the semiconductor layer 21 can be inhibited. In that case, an aluminum oxide film is suitably used as the film in contact with the semiconductor layer 21. Aluminum oxide has a function of capturing or fixing hydrogen in addition to having a barrier property against oxygen, and thus has an effect of preventing diffusion of hydrogen into the semiconductor layer 21.

In the case where the insulating layer 22 has a stacked-layer structure, each insulating film thereof is preferably a thin film. For example, when the insulating layer 22 has a thickness greater than or equal to 1 nm and less than or equal to 20 nm, preferably greater than or equal to 3 nm and less than or equal to 10 nm, the subthreshold swing value (also referred to as S value) of the transistor can be reduced. The thickness of each insulating layer is preferably greater than or equal to 0.1 nm and less than or equal to 10 nm, further preferably greater than or equal to 0.1 nm and less than or equal to 5 nm, further preferably greater than or equal to 0.5 nm and less than or equal to 5 nm, further preferably greater than or equal to 1 nm and less than 5 nm, further preferably greater than or equal to 1 nm and less than or equal to 3 nm.

As a specific example of the insulating layer 22, a four-layer structure in which an aluminum oxide film, a silicon oxide film, a hafnium oxide film, and a silicon nitride film are stacked in this order from the semiconductor layer 21 side is preferably employed, and their thicknesses are preferably 1 nm, 2 nm, 2 nm, and 1 nm from the semiconductor layer 21 side.

Note that in this specification and the like, the barrier property refers to a property that does not easily allow diffusion of a target substance (also referred to as, a property with low permeability of a target substance or a function of inhibiting diffusion of a target substance). Note that hydrogen described as a target substance refers to at least one of a hydrogen atom, a hydrogen molecule, and a substance bonded to hydrogen, such as a water molecule or OH, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

Here, a transistor including a metal oxide film can have stable electrical characteristics when surrounded by an insulating film having a function of inhibiting passage of impurities and oxygen. The insulating film having a function of inhibiting passage of impurities and oxygen can have, for example, a single-layer structure or a stacked-layer structure of an insulating film containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum.

Specific examples of a material for the insulating film having a function of inhibiting passage of oxygen and impurities such as water and hydrogen include oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the material for the insulating film having a function of inhibiting passage of oxygen and impurities such as water and hydrogen include oxides containing aluminum and hafnium (hafnium aluminate). Other examples of the material for the insulating layer having a function of inhibiting passage of oxygen and impurities such as water and hydrogen include nitrides such as aluminum nitride, nitrides containing aluminum and titanium, silicon nitride oxide, and silicon nitride.

Nitrides containing aluminum and titanium may have insulating or conducting properties depending on the content ratio of aluminum to titanium.

Examples of a material for an insulating film having a function of capturing or fixing hydrogen include metal oxides such as an oxide containing hafnium, an oxide containing magnesium, an oxide containing aluminum, and an oxide containing aluminum and hafnium (hafnium aluminate). Furthermore, these metal oxides may further contain zirconium, and an example of such a metal oxide is an oxide containing hafnium and zirconium. Note that in a metal oxide having an amorphous structure, some oxygen atoms have a dangling bond, which allows the metal oxide to have a high property of capturing or fixing hydrogen. Thus, these metal oxides preferably have an amorphous structure. For example, these oxides may have an amorphous structure by containing silicon. For example, an oxide containing hafnium and silicon (hafnium silicate) is preferably used. Note that the metal oxide may partly include one or both of a crystal region and a crystal grain boundary.

The above is the description of the components.

### [Manufacturing Method Example]

An example of a method for manufacturing a semiconductor device of one embodiment of the present is described below. Here, the semiconductor device including the memory cell 15 described in the above structure example is described as an example.

Note that thin films included in the semiconductor device (e.g., insulating layers, semiconductor layers, and conductive layers) can be formed by a sputtering method, a chemical vapor deposition (CVD) method, a vacuum evaporation method, a pulsed laser deposition (PLD) method, an atomic layer deposition method, or the like.

Alternatively, the thin films included in the semiconductor device (e.g., an insulating layer, a semiconductor layer, and a conductive layer) can be formed by a method such as spin coating, dipping, spray coating, inkjet printing, dispensing, screen printing, or offset printing or with a doctor knife, a slit coater, a roll coater, a curtain coater, or a knife coater.

Examples of the sputtering method include an RF sputtering method using a high-frequency power source for a sputtering power source, a DC sputtering method using a DC power source, and a pulsed DC sputtering method in which voltage applied to an electrode is changed in a pulsed manner. For film formation using an insulating target, an RF sputtering method is preferably used. A DC sputtering method is used mainly in the case of film formation using a conductive target. In a DC sputtering method, not only formation of a conductive film but also formation of an insulating film is possible by reactive sputtering using a pulsed DC sputtering method. The pulsed DC sputtering method can be specifically used to form a layer of a compound such as an oxide, a nitride, or a carbide by a reactive sputtering method.

CVD methods can be classified into a PECVD method, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object. A thermal CVD method yields a film with few defects because of no plasma damage during film formation.

As an ALD method, a thermal ALD method, in which a precursor and a reactant react with each other only by a thermal energy, a PEALD method, in which a reactant excited by plasma is used, or the like can be used.

Unlike a sputtering method, a CVD method and an ALD method are less likely to be influenced by the shape of an object to be processed and thus enable favorable step coverage. In particular, an ALD method allows excellent step coverage and excellent thickness uniformity and can be suitably used to cover a surface of an opening portion with a high aspect ratio, for example. Note that an ALD method has a relatively low film formation rate; hence, in some cases, an ALD method is preferably combined with another film formation method with a high film formation rate, such as a CVD method.

By a CVD method, a film with a certain composition can be formed by adjusting the flow rate ratio of the source gases. For example, a CVD method enables formation of a film whose composition is gradually changed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Hence, the productivity of the semiconductor device can be improved in some cases.

An ALD method, in which a plurality of different kinds of precursors are introduced at a time, enables formation of a film with a desired composition. In the case where a plurality of different kinds of precursors are introduced, the number of cycles for each precursor is controlled, whereby a film with a desired composition can be formed. Furthermore, a film whose composition is continuously changed can be formed as in the CVD method.

Thin films included in the semiconductor device can be formed by a photolithography method or the like. Besides, a nanoimprinting method, a sandblasting method, a lift-off method, or the like may be employed to process the thin films. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Instead of the light for exposure, an electron beam can be used. EUV, X-rays, or an electron beam is preferably used to enable extremely minute processing. Note that a photomask is not needed when exposure is performed by scanning with a beam such as an electron beam.

For etching of thin films, a dry etching method, a wet etching method, a sandblast method, or the like can be used.

### Manufacturing Method Example 1

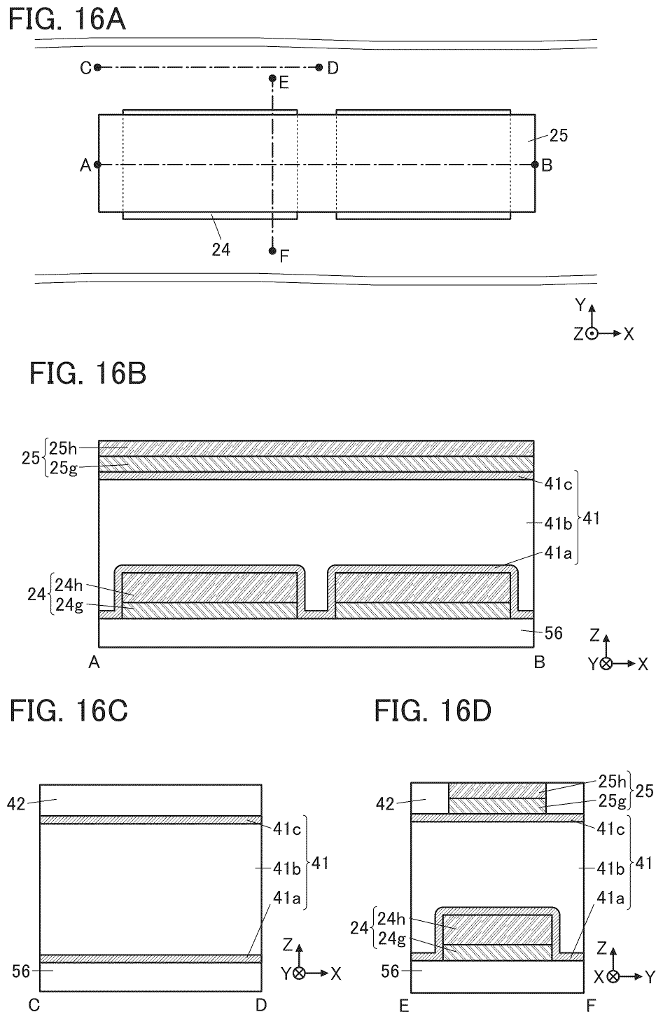

An example of a method for manufacturing the semiconductor device illustrated in FIG. 1 to FIG. 6B is described with reference to FIG. 16A to FIG. 26D.

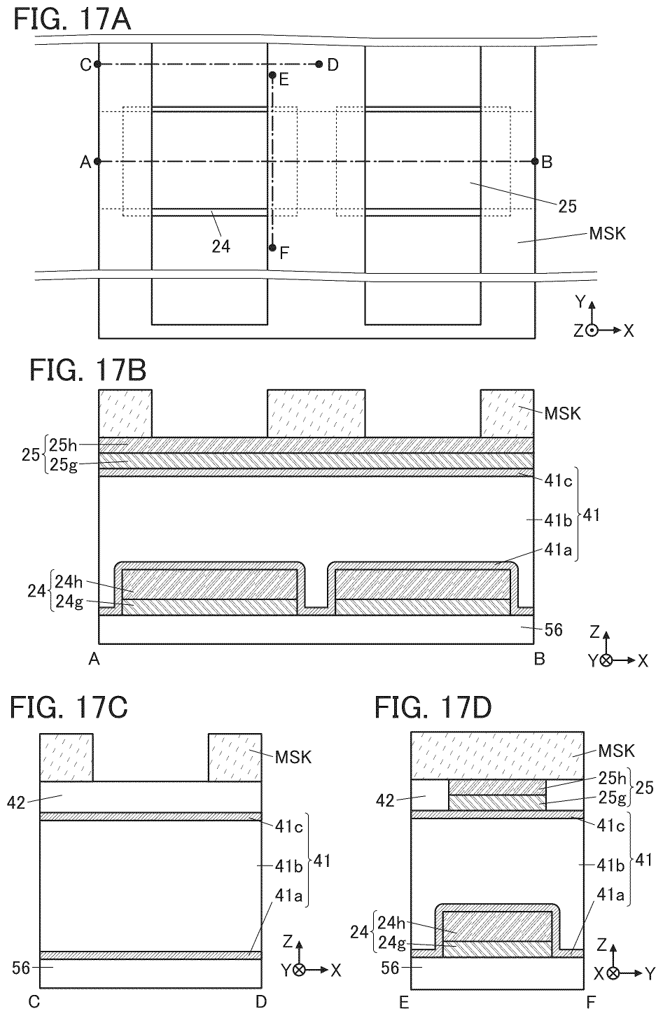

FIG. 16A to FIG. 26D are top views and cross-sectional views corresponding to steps in the manufacturing method example described below. FIG. 16A is a top view and FIGS. 16B to 16D are cross-sectional views taken along the cutting line A-B, the cutting line C-D, and the cutting line E-F, respectively, in the top view; the same applies to FIG. 17A to FIG. 26D.

First, a substrate (not illustrated) is prepared, and the insulating layer 56 is formed over the substrate. Although the inside of the insulating layer 56 is filled with the conductive layer 53 in FIG. 1 to FIG. 6B, the conductive layer 53 is not described here because the formation of the capacitor 30 including the conductive layer 53 is described later.

As the substrate, a substrate that has heat resistance high enough to withstand at least heat treatment performed later can be used.

An inorganic insulating film such as a silicon oxide film or a silicon oxynitride film can be used as the insulating layer 56. The insulating layer 56 can be formed by a sputtering method, a CVD method, an MBE method, a PLD method, an ALD method, or the like.

Next, the conductive layer 24g and the conductive layer 24h over the conductive layer 24g are formed as the conductive layer 24 over the insulating layer 56. Next, the insulating layer 41 is formed over the conductive layer 24 and the insulating layer 56. Here, a stacked-layer structure of the insulating layers 41a, 41b, and 41c is formed as the insulating layer 41. A top surface of the insulating layer 41b is planarized and then the insulating layer 41c is formed, whereby a top surface of the insulating layer 41 can be made flat.

The insulating layer 41 can be formed by a film formation method such as a sputtering method, an ALD method, or a CVD method.

The insulating layer 41 is preferably an oxide film including a large amount of oxygen so that oxygen is released by heating and including a small amount of hydrogen. The insulating layer 41 can be formed by a film formation method such as a PECVD method, a sputtering method, or an ALD method, and is particularly preferably formed by a sputtering method. In particular, when a gas containing not hydrogen but oxygen is used as a deposition gas, an insulating film including an extremely small amount of hydrogen and an excess amount of oxygen can be formed. When the insulating layer 41 is deposited in this manner, oxygen can be supplied to the channel formation region of the semiconductor layer 21 from the insulating layer 41, so that oxygen vacancies can be reduced.

Next, heat treatment may be performed. The heat treatment is preferably performed at a temperature higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, the heat treatment may be performed in such a manner that heat treatment is performed in a nitrogen gas atmosphere or an inert gas atmosphere, and then another heat treatment is performed in an atmosphere containing an oxidizing gas at 10 ppm or more, 1% or more, or 10% or more in order to compensate for released oxygen. By the above-described heat treatment, impurities such as water and hydrogen included in the insulating layer 41, for example, can be reduced before an oxide semiconductor film to be the semiconductor layer is formed.

The gas used in the above heat treatment is preferably highly purified. For example, the amount of moisture contained in the gas used in the above-described heat treatment is preferably 1 ppb (0.001 ppm) or less, preferably 0.1 ppb or less, and further preferably 0.05 ppb or less. The heat treatment using a highly purified gas can, for example, prevent the entry of moisture into the insulating layer 41 as much as possible.

After the formation of the insulating layer 41, treatment for supplying oxygen to the insulating layer 41 may be performed. Accordingly, oxygen can be supplied from the insulating layer 41 to a semiconductor layer 21f by heat applied after the formation of the semiconductor layer 21f later, or the like.

Examples of the treatment for supplying oxygen include heat treatment in an oxygen-containing atmosphere, plasma treatment in an oxygen-containing atmosphere (including microwave plasma), and the like, or an oxide film (preferably a metal oxide film) may be formed by a sputtering method in an oxygen-containing atmosphere to supply oxygen to the insulating layer. The formed oxide film may be removed immediately or left as it is. Note that examples of the atmosphere containing oxygen include not only an atmosphere containing oxygen (O₂) but also an atmosphere containing a gas of a compound containing oxygen, such as ozone (O₃) or dinitrogen monoxide (N₂O).

Next, the conductive layer 25g and the conductive layer 25h over the conductive layer 25g are formed as the conductive layer 25 over the insulating layer 41. The conductive layers 25g and 25h can each be formed by a film formation method such as a sputtering method, an ALD method, or a CVD method. The conductive layer 25 is provided to extend in the X direction.

Next, an insulating film to be the insulating layer 42 is formed over the conductive layer 25 and planarization treatment is performed until the top surface of the conductive layer 25 is exposed, whereby the insulating layer 42 can be formed (FIGS. 16A to 16D). Thus, the conductive layer 25 can fill the inside of the insulating layer 42.

Note that the insulating layer 42 is not necessarily provided when not needed.

Next, a mask MSK is formed over the conductive layer 25 and the insulating layer 42 (FIGS. 17A to 17D). As the mask, for example, a three-layer structure of a spin on carbon (SOC) film, a spin on glass (SOG) film over the SOC film, and a resist over the SOG film can be used. As illustrated in FIG. 17A, the mask MSK has opening portions extending in the Y direction.

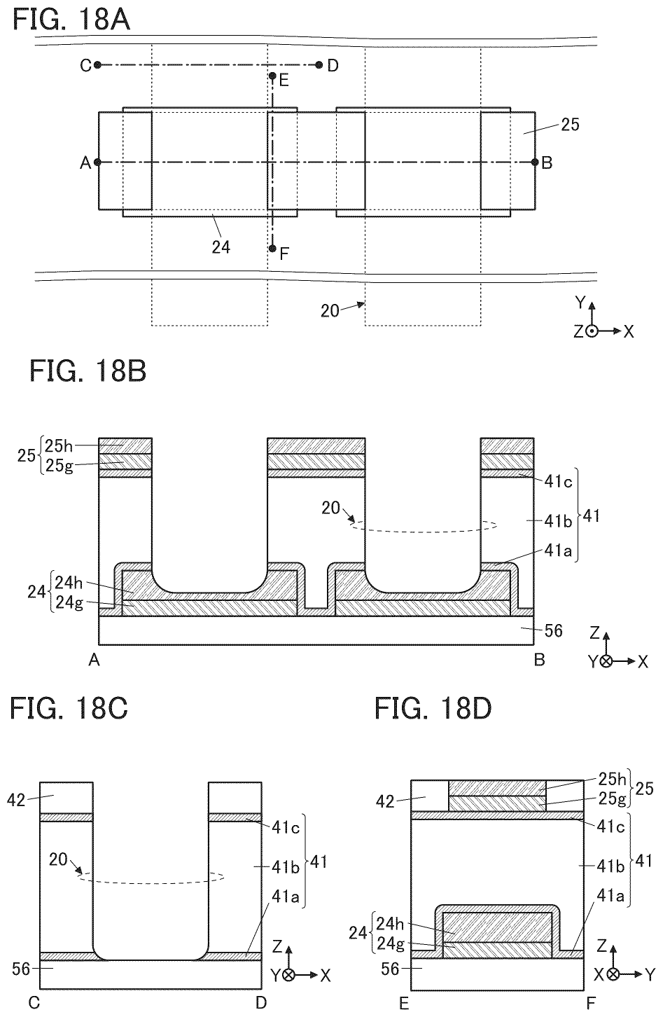

Next, part of the conductive layer 25, part of the insulating layer 42, and part of the insulating layer 41 are removed using the mask MSK (FIGS. 18A to 18D). Consequently, the slits 20 are formed in the insulating layer 41. In addition, regions of the conductive layer 25 that overlap with the slits 20 are removed, so that the conductive layer 25 is divided. In the insulating layer 42, a slit overlapping with the slit 20 is formed. The conductive layer 25 is divided into a plurality of conductive layers with the slit 20 therebetween in the plan view.

At the time of forming the slit 20, part of the conductive layer 24 positioned in the bottom portion of the slit 20 is preferably etched to form a depression in the conductive layer 24. At this time, etching is preferably performed so that a concave surface is formed at an upper portion of the conductive layer 24. In a portion where the conductive layer 24 is not provided, a concave surface is preferably formed also on the top surface of the insulating layer 41.

Anisotropic dry etching is preferably employed for processing in the formation of the slits 20 in the insulating layer 41, the division of the conductive layer 25, and the formation of the slit in the position of the insulating layer 42 that overlaps with the slit 20 so that the side surfaces of the layers exposed by processing are perpendicular or substantially perpendicular to the top surface of the insulating layer 56. Depending on the processing conditions, the side surface of the slit 20 may be inclined relative to the direction perpendicular to the formation surface to have a tapered shape.

Next, in the case where the mask MSK remains, the mask MSK is removed. The mask MSK is thinned or disappears in some cases when the insulating layer 41 or the like is processed.

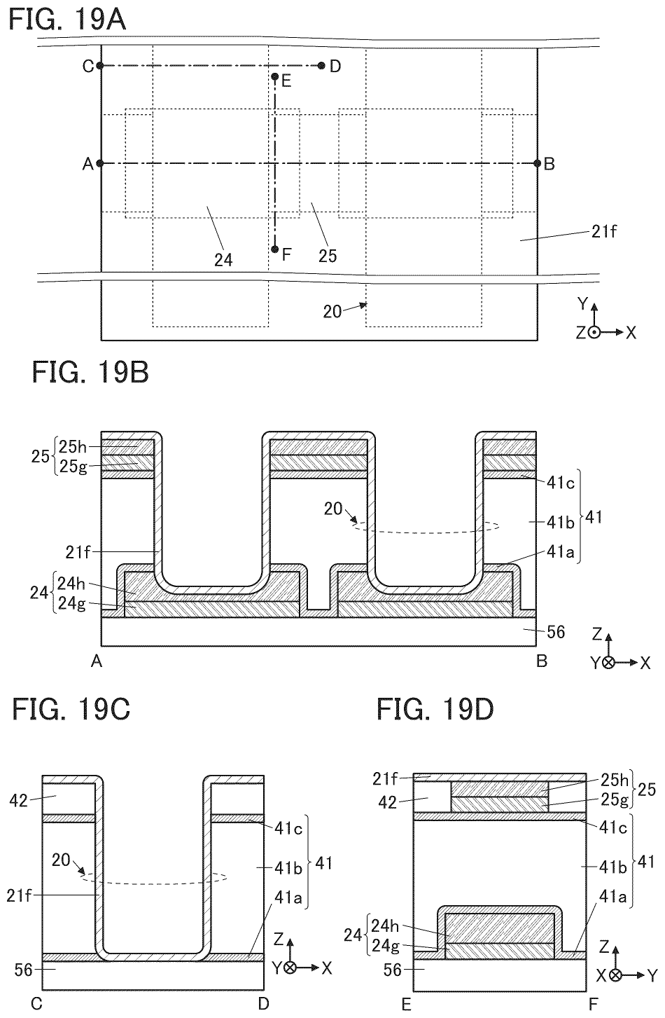

Next, the semiconductor layer 21f to be the semiconductor layer 21 is formed to cover the top and side surfaces of the conductive layer 25 and the top and side surfaces of the insulating layer 41 (FIGS. 19A to 19D).

As the semiconductor layer 21f, a metal oxide film having semiconductor characteristics (oxide semiconductor film) can be used. The formation of the metal oxide film can be performed by appropriately using a sputtering method, a CVD method, an MBE method, a PLD method, an ALD method, or the like. Here, the metal oxide film is preferably formed in contact with the side surface of the insulating layer 41 that is perpendicular or substantially perpendicular to the top surface of the insulating layer 56. Thus, the metal oxide film is preferably formed by a film formation method with favorable coverage, and is further preferably formed by an ALD method.

The metal oxide film preferably has crystallinity. It is particularly preferable that the metal oxide film of one embodiment of the present invention include a metal oxide having a CAAC structure.

Note that treatment for increasing the crystallinity of the metal oxide film is preferably performed during or after the formation of the metal oxide film. Examples of the treatment for increasing the crystallinity of the metal oxide film include heat treatment, plasma treatment, microwave (typically, 2.45 GHz) treatment, microwave plasma treatment, and light (e.g., ultraviolet light) irradiation treatment. Some of these treatments may be performed concurrently or sequentially. For example, heat treatment and microwave plasma treatment can be performed concurrently. Alternatively, microwave plasma treatment can be performed after heat treatment.

It is further preferable that the treatment for increasing the crystallinity of the metal oxide film be performed a plurality of times during the formation of the metal oxide film. For example, in the case where the metal oxide film is formed by an ALD method, microwave plasma treatment is preferably performed every time an atomic layer is formed. Alternatively, the treatment for increasing crystallinity is preferably performed every time the metal oxide film with a thickness in a predetermined range is formed, in which case the productivity can be increased. Specifically, the metal oxide film is preferably formed in the following manner: a first metal oxide film with a thickness greater than or equal to 1 nm and less than or equal to 10 nm is formed, first microwave plasma treatment is performed, a second metal oxide film with a thickness greater than or equal to 1 nm and less than or equal to 10 nm is formed, and then second microwave plasma treatment is performed.

Note that methods for forming the first metal oxide film and the second metal oxide film are not particularly limited, and can be an ALD method or a sputtering method. It is particularly preferable to form the first metal oxide film by an ALD method, in which case entry (also referred to as mixing) of an element of a layer on which the first metal oxide film is formed into the first and second metal oxide films can be prevented. Forming the first metal oxide film by an ALD method is particularly preferable in the case where the element of the layer on which the first metal oxide film is formed hinders crystallization of a metal oxide (e.g., the case where silicon, carbon, or the like is contained in the layer). The first metal oxide film and the second metal oxide film may have different compositions. Although the stacked-layer structure of the first metal oxide film and the second metal oxide film is exemplified here, one embodiment of the present invention is not limited thereto. Treatment similar to the above treatment can be performed on the metal oxide film having a single-layer structure or a stacked-layer structure of three or more layers.

The treatment for increasing the crystallinity of the metal oxide film may be performed after the formation of the metal oxide film. Specifically, after the formation of the metal oxide film, the treatment may be performed directly on the metal oxide film, or may be performed on the metal oxide film through another film such as an insulating film formed over the metal oxide film layer. For example, microwave plasma treatment may be performed on the metal oxide film after the formation of the metal oxide film; alternatively, an insulating film (e.g., a silicon nitride film, a silicon oxide film, or an aluminum oxide film) may be formed after the deposition of the metal oxide film, and then heat treatment or microwave plasma treatment may be performed on the metal oxide film through the insulating film.

Note that the treatment for increasing the crystallinity of the metal oxide film can also function as treatment for removing impurities contained in the metal oxide film. For example, carbon, hydrogen, nitrogen, and the like contained in the metal oxide film can be suitably removed. Alternatively, by performing the treatment for increasing the crystallinity of the metal oxide film layer in an oxygen gas atmosphere, oxygen vacancies in the metal oxide film layer can be reduced.

During the treatment for increasing the crystallinity of the metal oxide film, the substrate temperature is preferably higher than or equal to room temperature (e.g., 25° C.), higher than or equal to 100° C. and lower than or equal to 700° C., higher than or equal to 100° C. and lower than or equal to 600° C., or higher than or equal to 300° C. and lower than or equal to 450° C.

By increasing the crystallinity of the metal oxide film, a highly reliable transistor can be obtained.

The metal oxide film can be formed by a sputtering method using a metal oxide target, for example.

The metal oxide film is preferably a dense film with as few defects as possible. The metal oxide film is preferably a highly purified film in which impurities such as hydrogen and water are reduced as much as possible. It is particularly preferable to use a metal oxide film having crystallinity as the metal oxide film.

In forming the metal oxide film, an oxygen gas and an inert gas (such as a helium gas, an argon gas, or a xenon gas) may be mixed. Note that the higher the proportion of the oxygen gas in the whole deposition gas (hereinafter also referred to as oxygen flow rate ratio) is in forming the metal oxide film, the higher the crystallinity of the metal oxide film can be, achieving a highly reliable transistor. By contrast, the lower the oxygen flow rate ratio is, the lower the crystallinity of the metal oxide film is, offering a transistor with increased on-state current.

In forming the metal oxide film, as the substrate temperature becomes higher, a denser metal oxide film having higher crystallinity can be formed. On the other hand, as the substrate temperature becomes lower, a metal oxide film having lower crystallinity and higher electrical conductivity can be formed.

The metal oxide film is preferably formed at a substrate temperature higher than or equal to room temperature and lower than or equal to 250° C., preferably higher than or equal to room temperature and lower than or equal to 200° C., further preferably higher than or equal to room temperature and lower than or equal to 140° C. For example, the substrate temperature is preferably set to be higher than or equal to room temperature and lower than 140° C. because the productivity is increased. When the metal oxide film is formed at a substrate temperature set to room temperature or without intentional heating, the metal oxide film can have low crystallinity.

In the case of employing an ALD method, a film formation method such as a thermal ALD method or a PEALD method is preferably employed. The thermal ALD method is preferable because of its capability of forming a film with extremely high step coverage. The PEALD method is preferable because of its capability of forming a film at low temperatures, in addition to its capability of forming a film with high step coverage.

For example, the semiconductor layer 21 including a metal oxide can be formed by an ALD method using a precursor containing a constituent metal element and an oxidizer.

For example, a film of In—Ga—Zn oxide can be formed using a precursor containing indium, a precursor containing gallium, and a precursor containing zinc. Alternatively, a precursor containing indium and a precursor containing gallium and zinc may be used.

As the precursor containing indium, it is possible to use trimethylindium, triethylindium, trimethylindium, tris(2,2,6,6-tetramethyl-3,5-heptanedionato)indium, cyclopentadienylindium, indium (III) chloride, (3-(dimethylamino)propyl)dimethylindium, or the like.

As the precursor containing gallium, it is possible to use trimethylgallium, triethylgallium, tris(dimethylamido)gallium(III), gallium(III) acetylacetonate, tris(2,2,6,6-tetramethyl-3,5-heptanedionato) gallium, dimethylchlorogallium, dimethylchlorogallium, gallium(III) chloride, or the like.

As the precursor containing zinc, it is possible to use dimethylzinc, diethylzinc, bis(2,2,6,6-tetramethyl-3,5-heptanedionato) zinc, zinc chloride, or the like.

Ozone, oxygen, water, or the like can be used as the oxidizer.

As an example of a method for controlling the composition of a film to be formed, adjusting the flow rate ratio, flowing time, flowing order, or the like of the source gases is given. By adjusting such conditions, a film whose composition is gradually changed can be formed. Furthermore, two or more films having different compositions can be formed successively.

After the metal oxide film is formed, heat treatment is preferably performed. The heat treatment is preferably performed at a temperature higher than or equal to 250° C. and lower than or equal to 650° C., preferably higher than or equal to 400° C. and lower than or equal to 600° C. so that the above-described metal oxide film does not become polycrystals. Note that the heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, the heat treatment may be performed in such a manner that heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen.

The gas used in the above heat treatment is preferably highly purified. For example, the amount of moisture contained in the gas used in the above-described heat treatment is preferably 1 ppb or less, preferably 0.1 ppb or less, and further preferably 0.05 ppb or less. The heat treatment using a highly purified gas can, for example, prevent the entry of moisture into the metal oxide film as much as possible.

Although the semiconductor layer 21f is illustrated as a single layer in the drawings, a stacked-layer structure may be employed. For example, a two-layer structure formed by an ALD method, a three-layer structure formed by an ALD method, a two-layer structure in which the first layer is formed by an ALD method and the second-layer is formed by a sputtering method, or a three-layer structure in which the first layer is formed by an ALD method, the second layer is formed by a sputtering method, and the third layer is formed by an ALD method or a sputtering method can be employed. The first layer is preferably formed by an ALD method, which can inhibit mixing; alternatively, the first layer can also be formed by a sputtering method. Note that the semiconductor layer 21f may have a stacked-layer structure of four or more layers.

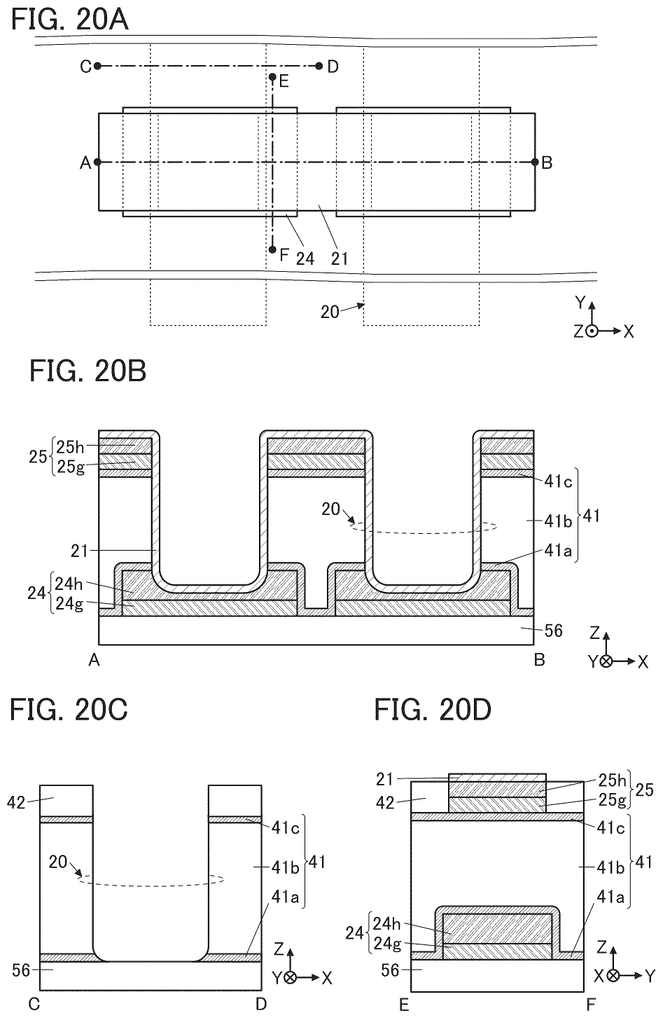

Next, the semiconductor layer 21f is partly removed by etching, thereby forming the semiconductor layer 21 (FIGS. 20A to 20D). In the etching of the semiconductor layer 21, it is difficult to remove part of the semiconductor layer 21 in contact with the side surface of the insulating layer 41 only by anisotropic dry etching; thus, the etching is preferably performed by a combination of isotropic dry etching or wet etching. Alternatively, treatment may be performed in advance on a region of the semiconductor layer 21f that is not covered with the resist mask so that the quality of part of the semiconductor layer 21f is changed to facilitate etching. Examples of the treatment include plasma treatment, doping (including ion implantation) treatment, and wet treatment.

Next, the insulating layer 22 is formed to cover the semiconductor layer 21 and the insulating layer 41. The insulating layer 22 can be formed by a film formation method such as a sputtering method, an ALD method, or a CVD method. The insulating layer 22 is preferably provided to have a thickness as uniform as possible on the surface of the portion of the semiconductor layer 21 that covers the side surface of the insulating layer 41. For this reason, an ALD method, which is a film formation method that enables extremely good coverage, is especially preferable for the formation of the insulating layer 22. In the case where the side surface of the insulating layer 41 has a tapered shape, the insulating layer 22 can be formed by a film formation method such as a sputtering method or a CVD method.

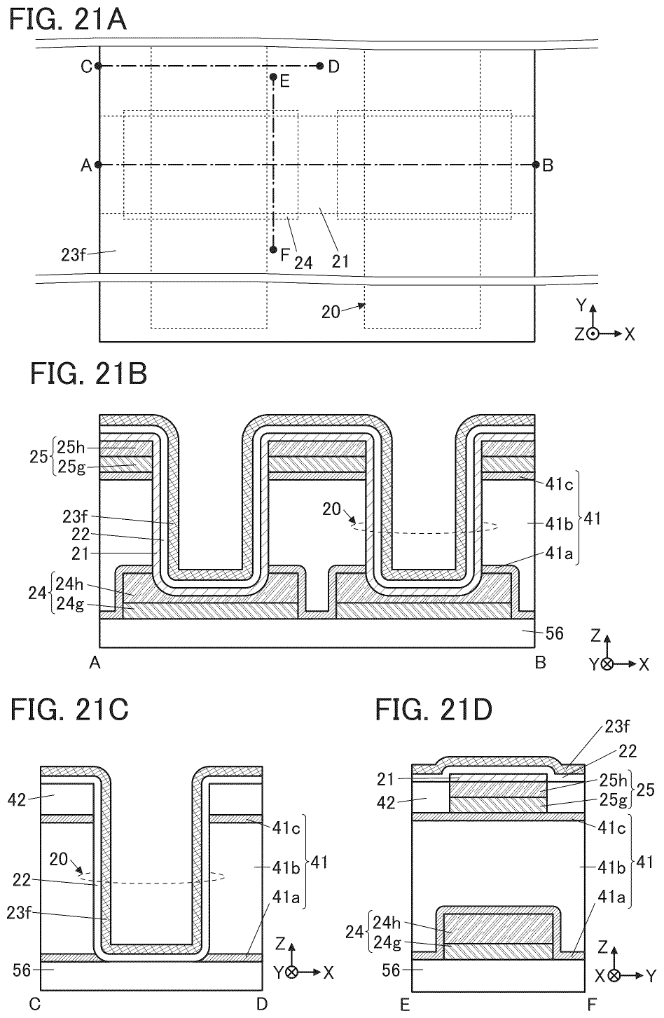

Next, the conductive layer 23f to be the conductive layer 23 later is formed to cover the insulating layer 22 (FIGS. 21A to 21D). The conductive layer 23f can be formed by a CVD method, an ALD method, a sputtering method, or the like. In terms of coverage, the conductive layer 23f is particularly preferably formed by a CVD method.

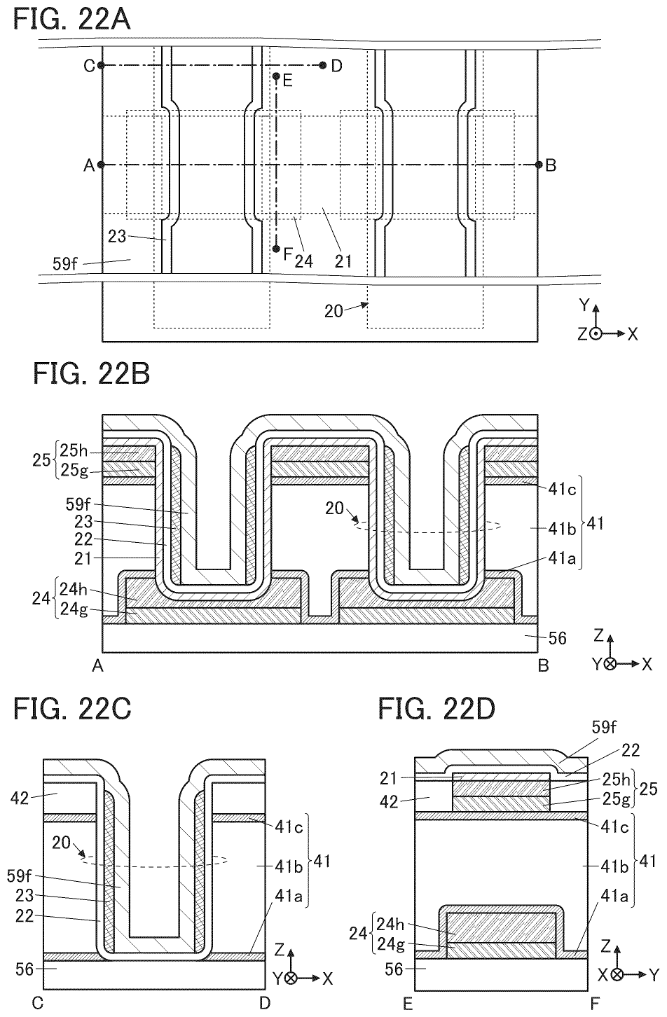

Next, the conductive layer 23f is processed by anisotropic etching, forming the conductive layer 23 along the side surface of the slit 20 (FIGS. 22A to 22D). Using a film isotropically formed on the formation surface as the conductive layer 23f enables the conductive layer 23 to be formed on the side surface of the slit 20 by anisotropic etching.

In this case, the upper end of the conductive layer 23 is preferably positioned above a bottom surface of the conductive layer 25g through the processing of the conductive layer 23f. When the height of the upper end of the conductive layer 23 is lower than the bottom surface level of the conductive layer 25g, what is called an offset region, to which a gate electric field is not applied, is formed in the semiconductor layer 21. On the other hand, when the height of the upper end of the conductive layer 23 is higher than the bottom surface level of the conductive layer 25, no offset region is formed and therefore a transistor having a high on-state current can be achieved.

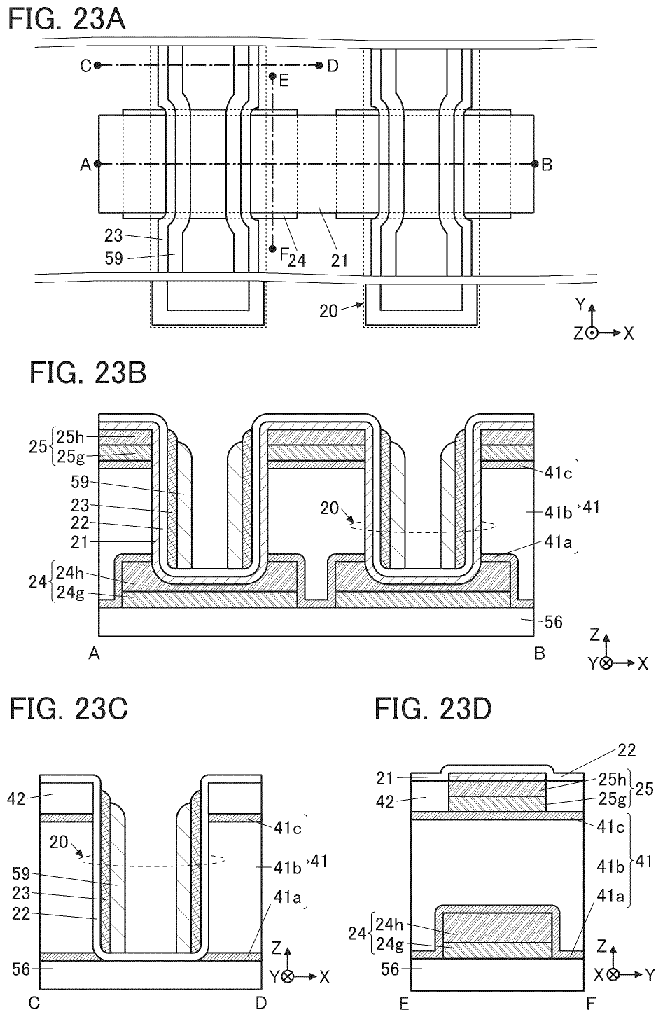

Next, the insulating layer 59f is formed to cover the insulating layer 22 and the conductive layer 23 (FIGS. 22A to 22D). The insulating layer 59f includes a portion positioned over the insulating layer 42 with the insulating layer 22 therebetween, a portion facing the side surfaces of the insulating layers 42 and 41 with the semiconductor layer 21, the insulating layer 22, and the conductive layer 23 therebetween, and a portion facing the top surface of the conductive layer 24 with the semiconductor layer 21 and the insulating layer 22 therebetween. Next, the insulating layer 59f is processed by anisotropic etching, so that the insulating layer 59 is formed (FIGS. 23A to 23D).

At least the portion of the insulating layer 59f that covers the bottom portion of the slit 20 is preferably removed. At this time, the upper end of the insulating layer 59 is processed to have a height lower than the height of the upper end of the conductive layer 23, for example. The residual of the portion of the insulating layer 59f that covers the bottom portion of the slit 20 might result in insufficient etching in a later step of dividing the conductive layer 24, the semiconductor layer 21, and the insulating layer 22.

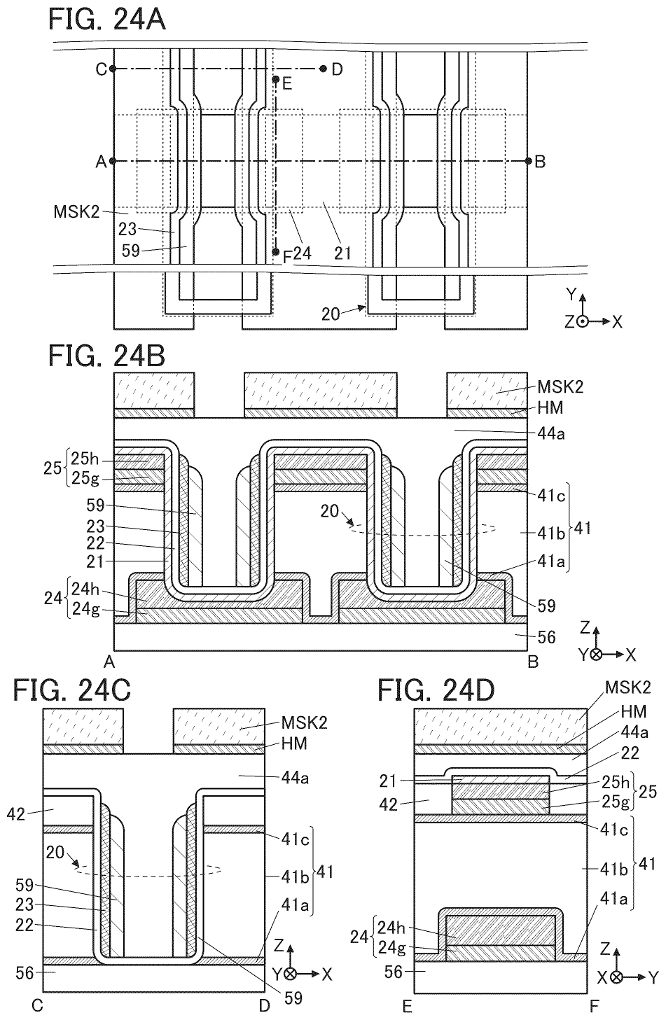

Next, the insulating layer 44a is formed over the insulating layer 22, the conductive layer 23, and the insulating layer 59. Next, a hard mask HM and a mask MSK2 are stacked over the insulating layer 44a (FIGS. 24A to 24D). Since the shape of the hard mask HM is not easily changed in the etching treatment, a recess of the mask can be inhibited from changing the width of the opening portion. Here, tungsten is used as an example. As illustrated in FIG. 24A, the mask MSK2 includes an opening portion extending in the Y direction, the width of the opening portion is narrower than the width of the slit 20, and an end of the opening portion in the X direction is enclosed by the slit 20. The hard mask HM is processed using the mask MSK2.

Next, in the case where the mask MSK2 remains, the mask MSK2 is removed. The mask MSK2 is thinned or disappears in some cases when the hard mask HM is processed.

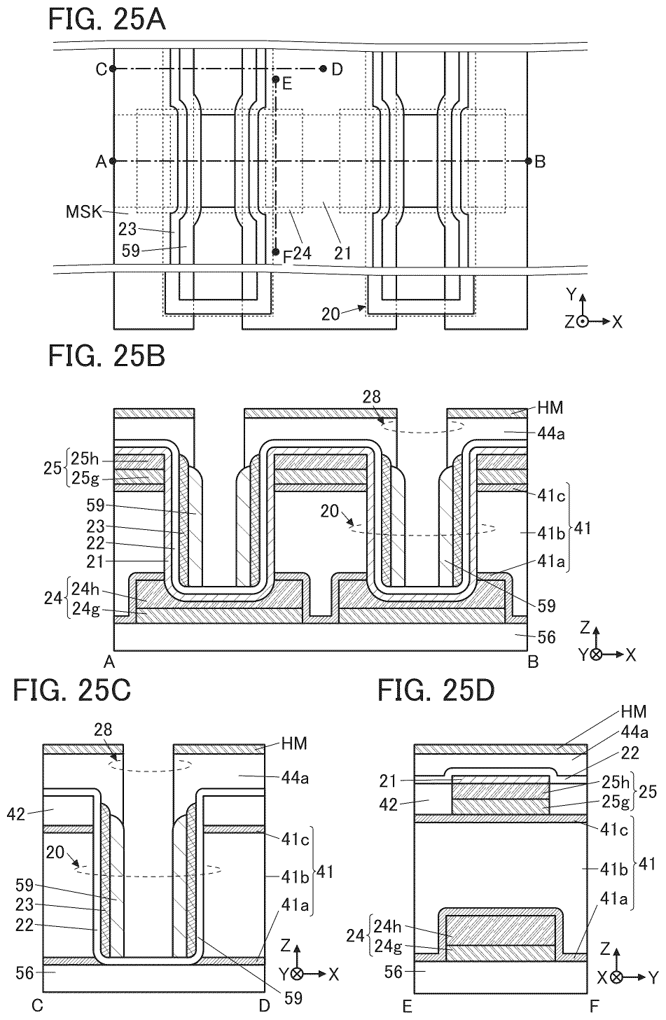

Then, a slit 28 is formed in the insulating layer 44a using the hard mask HM (FIGS. 25A to 25D). In FIGS. 25A to 25C, the insulating layer 59 is exposed by the slit 28 formed in the insulating layer 44a.

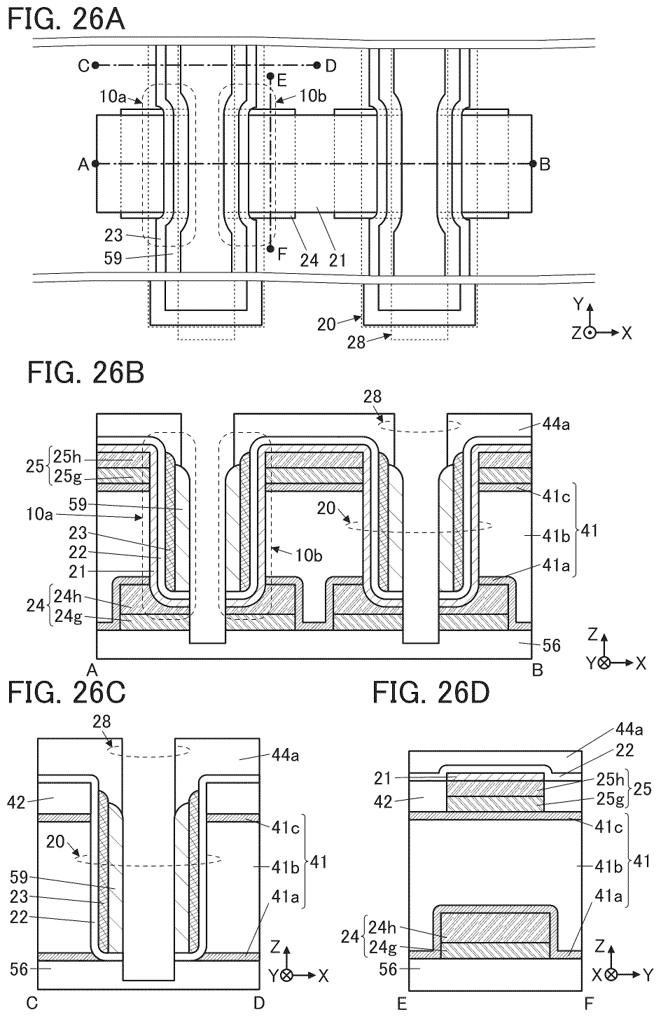

Next, the insulating layer 22, the semiconductor layer 21, and the conductive layer 24 are each divided in the slit 20 by processing using the hard mask HM and the insulating layer 59 as masks. After that, the hard mask HM is removed (FIGS. 26A to 26D).

Through the above process, the transistor 10 can be formed.

### Manufacturing Method Example 2

A method for manufacturing the semiconductor device illustrated in FIGS. 7A to 7C is described with reference to FIG. 27A to FIG. 30D. The semiconductor device illustrated in FIGS. 7A to 7C does not include the insulating layer 42.

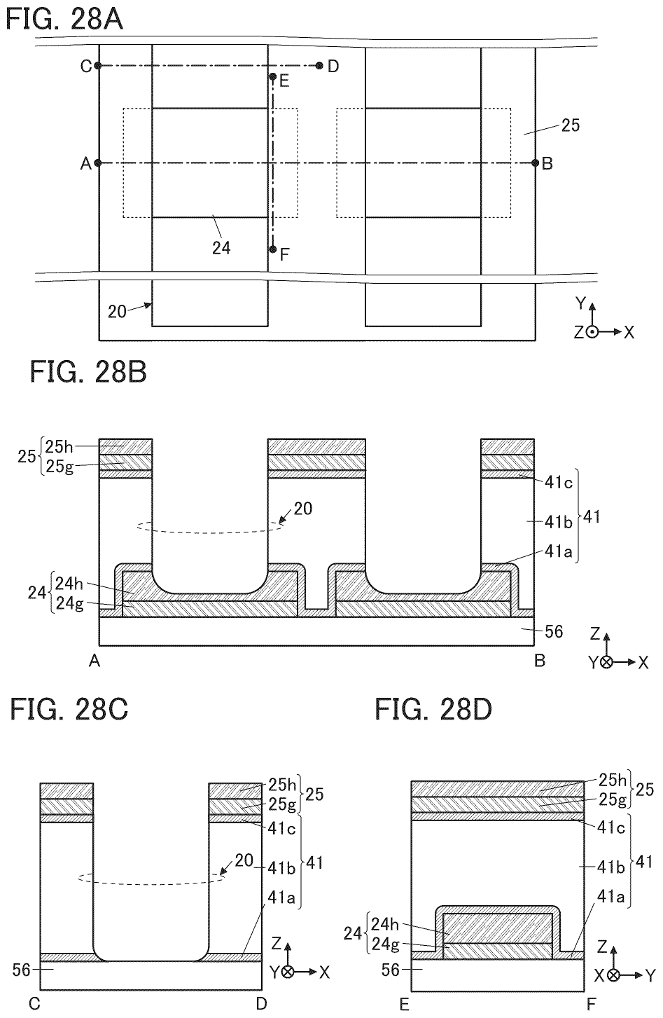

FIG. 27A to FIG. 30D are top views and cross-sectional views corresponding to steps in the manufacturing method example described below. FIG. 27A is a top view and FIGS. 27B to 27D are cross-sectional views taken along the cutting line A-B, the cutting line C-D, and the cutting line E-F, respectively, in the top view; the same applies to FIG. 28A to FIG. 30D.

First, a substrate (not illustrated) is prepared, and the insulating layer 56 is formed over the substrate. Then, the conductive layer 24 is formed over the insulating layer 56. Then, the insulating layer 41 is formed over the conductive layer 24. Then, the conductive layer 25f is formed over the insulating layer 41. Next, the mask MSK is formed over the conductive layer 25f (FIGS. 27A to 27D). The conductive layer 25f is a conductive layer to be the conductive layer 25 later. The conductive layer 25f includes a conductive layer 25f2 and a conductive layer 25f1 over the conductive layer 25f2; the conductive layer 25f1 and the conductive layer 25f2 are conductive layers to be a conductive layer 25g and a conductive layer 25h later, respectively.

Next, the slit 20 is formed in the conductive layer 25f and the insulating layer 41 with the use of the mask MSK (FIGS. 28A to 28D).

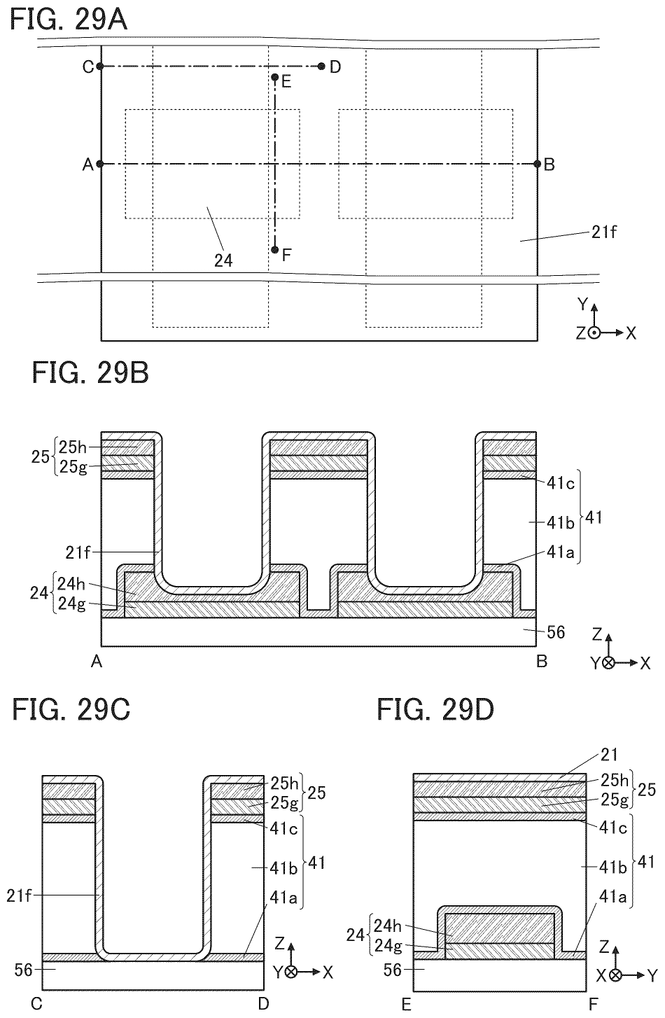

Next, the semiconductor layer 21f is formed to cover the top surface of the conductive layer 24 and the side surfaces of the insulating layer 41 and the conductive layer 25 in the slit 20 and also cover the top surface of the conductive layer 25 (FIGS. 29A to 29D). The semiconductor layer 21f is a semiconductor layer to be the semiconductor layer 21 later.

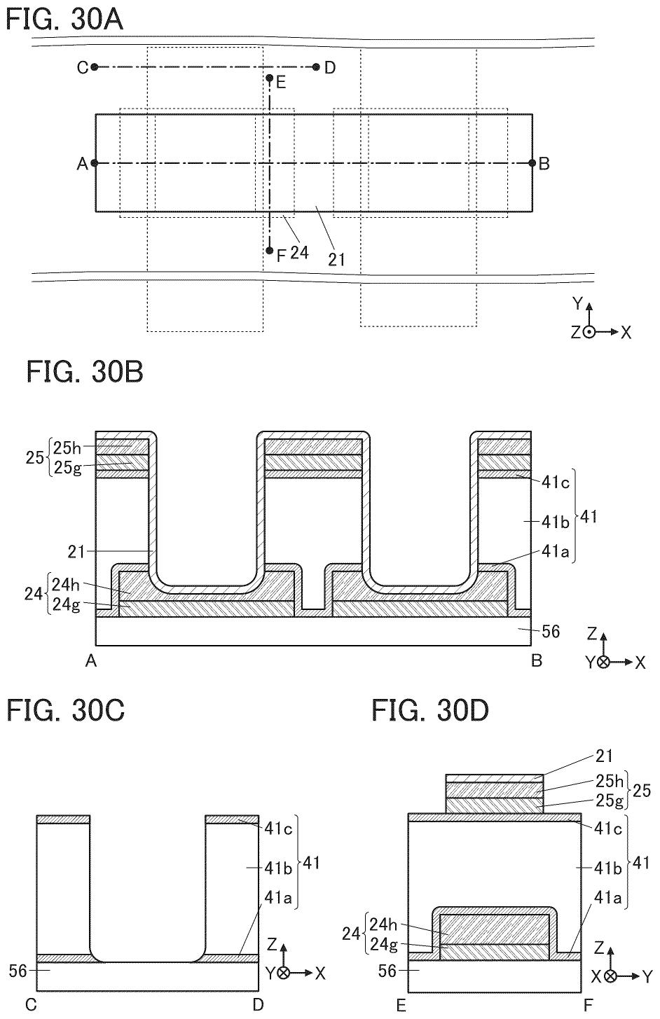

Next, the semiconductor layer 21f and the conductive layer 25f are processed using a mask or the like, whereby the semiconductor layer 21 and the conductive layer 25 are formed (FIGS. 30A to 30D). Since the semiconductor layer 21 and the conductive layer 25 can be formed using the same mask, the end portions of the semiconductor layer 21 and the conductive layer 25 in the Y direction in FIG. 30D can be aligned with each other.

Next, the insulating layer 22, the conductive layer 23, the insulating layer 59, the insulating layer 44a, and the like are formed, as in FIG. 21A to FIG. 24D. Then, the insulating layer 22, the semiconductor layer 21, and the conductive layer 24 are divided to form the transistors 10a and 10b, as in FIG. 25A to FIG. 26D.

### Manufacturing Method Example 3

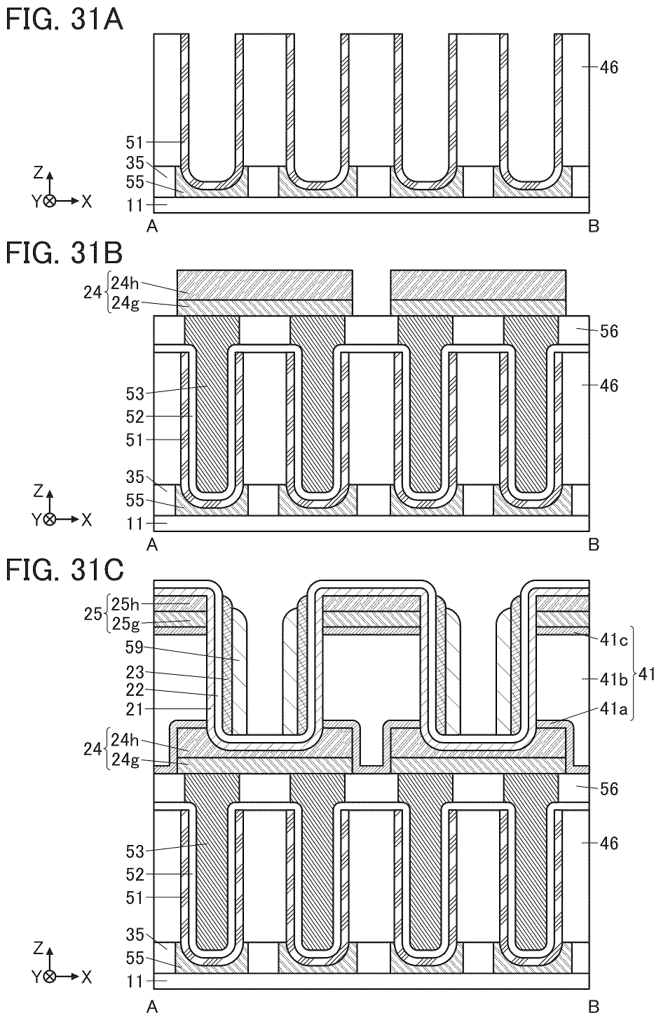

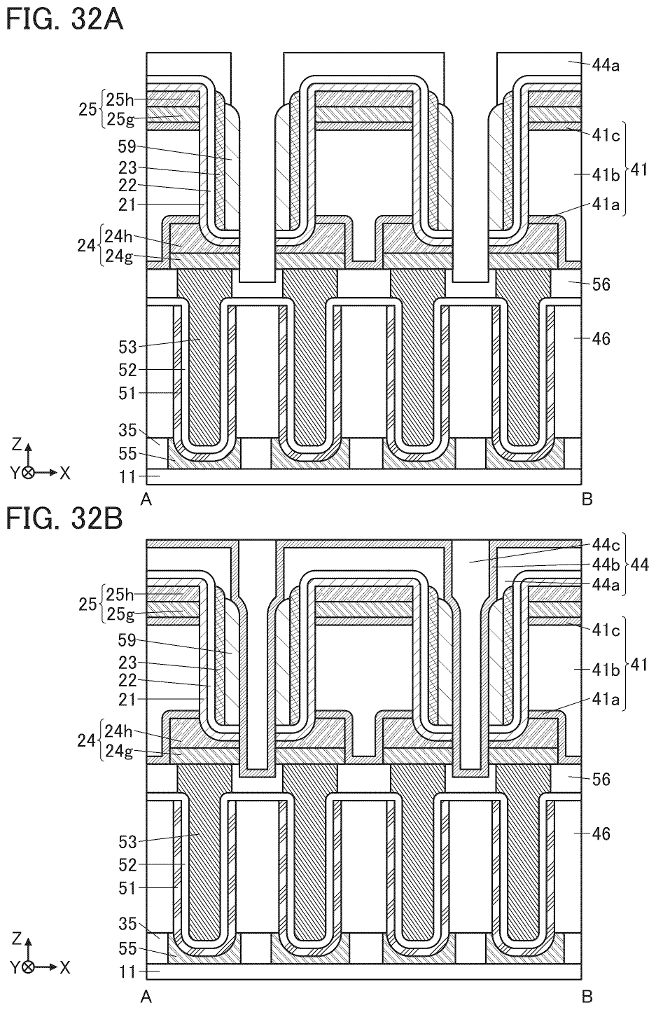

An example of a method for manufacturing the semiconductor device including the capacitor 30 illustrated in FIG. 1 to FIG. 6B is described with reference to FIG. 31A to FIG. 32B.

First, a substrate (not illustrated) is prepared, and the insulating layer 11 is formed over the substrate.

As the substrate, a substrate that has heat resistance high enough to withstand at least heat treatment performed later can be used.

An inorganic insulating film such as a silicon oxide film or a silicon oxynitride film can be used as the insulating layer 11. The insulating layer 11 can be formed by a sputtering method, a CVD method, an MBE method, a PLD method, an ALD method, or the like. In the case where the formation surface of the insulating layer 11 is not flat, planarization treatment may be performed after the deposition of the insulating layer 11 so that the insulating layer 11 has a flat top surface.

Next, a conductive layer to be the conductive layer 55 is formed over the insulating layer 11. The conductive layer can be formed by a film formation method such as a sputtering method, an ALD method, or a CVD method. Next, a resist mask is formed over the conductive layer, and an unnecessary portion of the conductive layer is removed by etching, whereby the conductive layer 55 is formed. The conductive layer 55 can have a plate-like shape, a line-like shape, or a lattice-like shape.

Next, an insulating film to be the insulating layer 35 is formed to cover the conductive layer 55, and then planarization treatment is performed until the top surface of the conductive layer 55 is exposed. Thus, the conductive layer 55 can fill the inside of the insulating layer 35. Although an example in which the insulating layer 35 is formed after the formation of the conductive layer 55 is described here, the conductive layer 55 and the insulating layer 35 may be formed in the following manner: the insulating layer 35 is formed, an opening portion (or a depression) to be filled with the conductive layer 55 is formed in the insulating layer 35, a conductive layer to be the conductive layer 55 is formed, and planarization treatment is performed until the surface of the insulating film is exposed. As the planarization treatment, for example, a CMP method, a dry etching method, or the like can be used.

Next, the insulating layer 46 is formed over the conductive layer 55 and the insulating layer 35. The insulating layer 46 can be formed by a film formation method such as a sputtering method, an ALD method, or a CVD method.

Note that in the case where the conductive layer 55 is not embedded in the insulating layer 35, the top surface of the insulating layer 46 after its formation can have an unevenness reflecting the shape of the conductive layer 55. In that case, planarization treatment is preferably performed on the top surface of the insulating layer 46.

Next, the opening portion reaching the conductive layer 55 is formed in the insulating layer 46. At this time, part of the top surface of the conductive layer 55 is etched in some cases. Etching is preferably performed such that a curved surface is formed at the upper portion of the conductive layer 55.

Next, a conductive layer to be the conductive layer 51 is formed to cover the top surface of the insulating layer 46 and the side surface of the insulating layer 46 and the top surface of the conductive layer 55 in the opening. The conductive layer can be formed by a CVD method, an ALD method, a sputtering method, or the like. In terms of coverage, the conductive layer 51 is particularly preferably formed by a CVD method.

Next, a sacrificial layer is formed over the conductive layer to be the conductive layer 51 to fill the opening portion in the insulating layer 46. Next, the sacrificial layer is removed by performing planarization treatment until the top surface of the insulating layer 46 is exposed, so that the conductive layer 51 positioned only in the opening portion in the insulating layer 46 can be formed (FIG. 31A).

Here, at the time of planarization treatment or removal of the sacrificial layer, the level of the top surface of the conductive layer 51 is lower than the level of the top surface of the insulating layer 46 in some cases. In addition, the edges of the upper end portion of the conductive layer 51 and the upper end of the insulating layer 46 in the opening portion are removed and rounded in some cases.

Next, the insulating layer 52 is formed along surfaces of the insulating layer 46 and the conductive layer 51. The insulating layer 52 can be formed by a film formation method such as a sputtering method, an ALD method, or a CVD method; particularly, an ALD method is preferable in terms of coverage. Next, the conductive layer 53 is formed over the insulating layer 52 to fill the depression in the slit 40 of the insulating layer 46. Thus, the plurality of capacitors 30 arranged in a matrix can be formed over the insulating layer 11. The conductive layer 53 can be formed by a film formation method such as a sputtering method, an ALD method, or a CVD method.

Next, an insulating layer to be the insulating layer 56 is formed over the conductive layer 53 and the insulating layer 52, and then the conductive layer 53 is exposed by planarization treatment, whereby a portion of the conductive layer 53 that is positioned above the opening portion of the insulating layer 46 can be embedded in the insulating layer 56.

Next, the conductive layer 24 is formed over the conductive layer 53 and the insulating layer 56 (FIG. 31B). The conductive layer 24 is formed to overlap with two capacitors 30. The conductive layer 24 is divided into two in a later step, one of the divided conductive layers 24 is placed over one of the capacitors 30, and the other is placed over the other of the capacitors 30.

Next, according to the manufacturing method example illustrated in FIG. 16A to FIG. 25D, the insulating layer 41 is formed over the conductive layer 24, the semiconductor layer 21 and the insulating layer 22 are sequentially formed in the slit 20 of the insulating layer 41 and over the insulating layer 41, and then the conductive layer 23 and the insulating layer 59 are sequentially formed in the slit 20 of the insulating layer 41 (FIG. 31C).

Next, the insulating layer 44a is formed over the insulating layer 22, the conductive layer 23, and the insulating layer 59. Then, a slit is formed in the insulating layer 44a. Next, the insulating layer 22, the semiconductor layer 21, and the conductive layer 24 are each divided in the slit 20 by being processed using the insulating layers 44a and 59 as masks (FIG. 32A). When the division of the conductive layer 24 by etching treatment is followed by etching treatment on the insulating layer 56, a depression is formed in the insulating layer 56 in some cases. A side surface of the depression is substantially aligned with a cross section of the conductive layer 24, for example.

Next, the insulating layer 44b is formed to cover the top and side surfaces of the insulating layer 44a, the side surface of the insulating layer 59, the divided insulating layer 22, the side surfaces of the semiconductor layer 21 and the conductive layer 24, and the top surface of the insulating layer 56. Next, the insulating layer 44c is formed over the insulating layer 44b (FIG. 32B).

The insulating layer 44 can function as an interlayer insulating layer that reduces the parasitic capacitance between the conductive layers 25 and 26 and the parasitic capacitance between the conductive layers 23 and 26. The top surface of the insulating layer 44 is preferably planarized. In this case, it is possible to inhibit significant reductions in the distance between the conductive layers 25 and 26 and the distance between the conductive layers 23 and 26, which reduces the parasitic capacitances between the conductive layers.

In the formation of the insulating layer 44, a top surface of the insulating layer 44a is preferably planarized. In this case, a top surface of the portion of the insulating layer 44b that is positioned over the insulating layer 44a can also be planarized.

After an insulating layer to be the insulating layer 44c is formed inside the slit of the insulating layer 44a and over the insulating layer 44b and then is processed by planarization treatment so that the top surface of the insulating layer 44b is exposed, whereby a top surface of the insulating layer 44c and the top surface of the insulating layer 44b can be substantially level with each other. This can planarize the top surface of the whole insulating layer 44.

Insulating layers to be the insulating layers 44a, 44b, and 44c can each be formed by a CVD method, an ALD method, a sputtering method, or the like.

Next, an opening portion reaching the conductive layer 25g is formed in the insulating layer 44, the insulating layer 22, the semiconductor layer 21, and the conductive layer 25h. After that, a conductive layer that fills the opening portion is formed and planarization treatment is performed until the top surface of the insulating layer 44 is exposed, so that the plug 27 can be formed.

Next, a conductive layer is formed over the insulating layer 44 and the plug 27, and an unnecessary portion is removed by etching, whereby the conductive layer 26 is formed

Through the above-described steps, a semiconductor device illustrated in FIG. 3A which includes the memory cell 15 including the transistor 10 and the capacitor 30 can be manufactured.

The above is the description of the manufacturing method example.

At least part of this embodiment can be implemented as appropriate in combination with any of the other embodiments described in this specification.

### Embodiment 2

In this embodiment, a semiconductor device 900 of one embodiment of the present invention, which is different from the above embodiment, will be described. The semiconductor device 900 can function as a memory device.

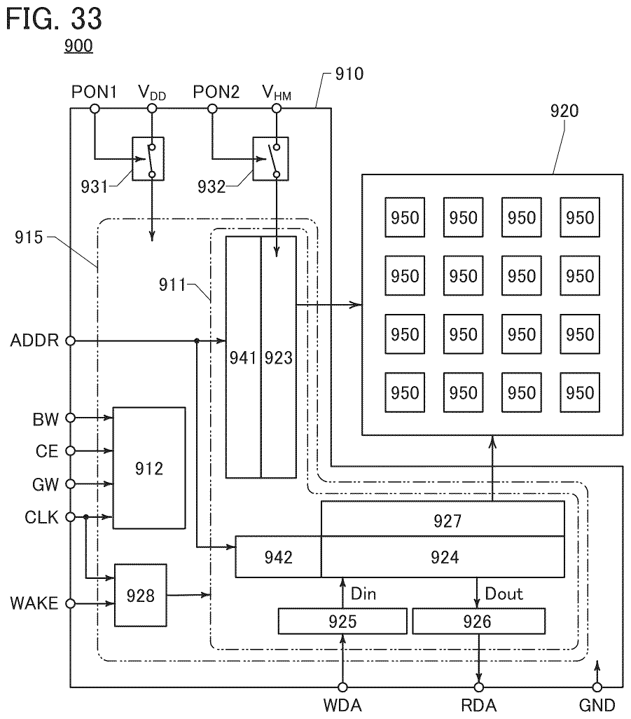

FIG. 33 is a block diagram illustrating a structure example of the semiconductor device 900. The semiconductor device 900 illustrated in FIG. 33 includes a driver circuit 910 and a memory array 920. The memory array 920 includes one or more of a memory cell 950. FIG. 33 illustrates an example in which the memory array 920 includes a plurality of memory cells 950 arranged in a matrix.

The memory cell 15 or the like exemplified in the above embodiment can be used as the memory cell 950.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and a sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply voltage is V_{DD} and a low power supply voltage is GND (ground potential). In addition, V_{HM} is a high power supply voltage used for setting a word line to high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 33 but can be more than one. In that case, a power switch is preferably provided for each power domain.

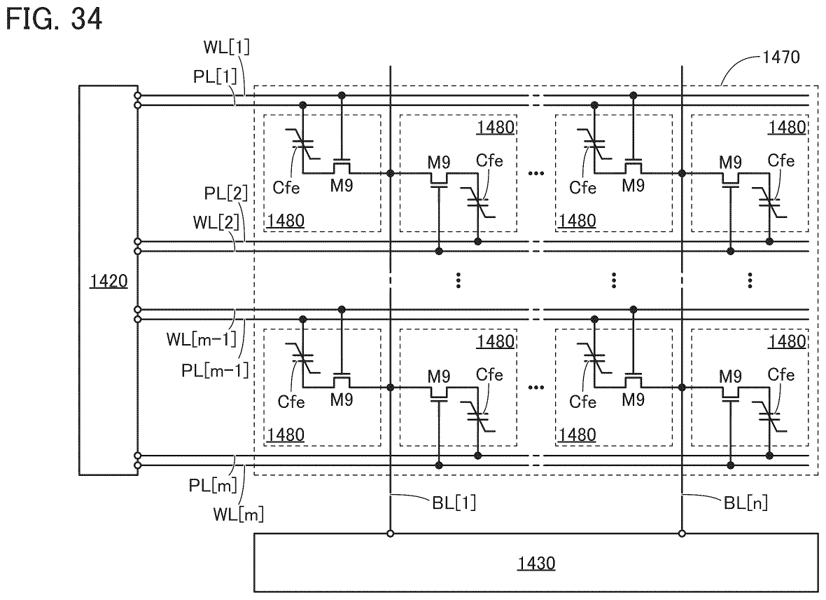

FIG. 34 illustrates a structure example applicable to the memory array of one embodiment of the present invention.

A memory cell array 1470 illustrated in FIG. 34 includes memory cells 1480 arranged in a matrix of m/2 rows and n columns (m is an even number greater than or equal to 1 and n is an integer greater than or equal to 1). The memory cell array 1470 illustrated in FIG. 34 can be used as the memory array 920 described above. The memory cell 1480 is a memory circuit that can be used for the memory cell 950 and is an example of a circuit configuration of a memory cell using a ferroelectric capacitor. Note that FIG. 34 also illustrates a row circuit 1420 and a column circuit 1430. The row circuit 1420 includes a row decoder, a word line driver circuit, and a plate line driver circuit, for example, and can select a row to be accessed. The column circuit 1430 includes a column decoder, a precharge circuit, a sense amplifier, and a write circuit, for example. The precharge circuit has a function of precharging wirings.

In FIG. 34, the memory cell 1480 includes a transistor M9 and a capacitor Cfe. In the memory cell 1480, the transistor M9 can correspond to the transistor 10 described in Embodiment 1, and the capacitor Cfe can correspond to the capacitor 30 described in Embodiment 1.

In the memory cell array 1470 in FIG. 34, m memory cells 1480 are connected to one wiring BL.

The following description is given with a focus on any one of the plurality of memory cells 1480 illustrated in FIG. 34.

One of a source and a drain of the transistor M9 is connected to the wiring BL (e.g., any one of a wiring BL[1] to the wiring BL[n]). The other of the source and the drain of the transistor M9 is connected to the one of a pair of electrodes of the capacitor Cfe. A gate of the transistor M9 is connected to the wiring WL (e.g., any one of a wiring WL[1] to a wiring WL[m]). The other of the pair of electrodes of the capacitor Cfe is connected to the wiring PL (e.g., any one of a wiring PL[1] to a wiring PL[m]).

The wiring WL has a function of a word line, and when a potential is supplied to the wiring WL as a selection signal or a non-selection signal, switching between the on state and the off state of the transistor M9 can be controlled. For example, a selection signal supplied to the wiring WL is set to a high potential (H) to turn on the transistor M9, and a non-selection signal supplied to the wiring WL is set to a low potential (L), whereby the transistor M9 can be turned off. The wiring WL is connected to the word line driver circuit included in the row circuit 1420, and can be supplied with a selection signal or a non-selection signal by the word line driver circuit.

The wiring BL functions as a bit line; when the transistor M9 is on, the potential corresponding to a data signal supplied to the wiring BL is supplied to one of the pair of electrodes of the capacitor Cfe. The wiring BL is connected to a bit line driver circuit included in the column circuit 1430. The bit line driver circuit has a function of generating a data signal to be written to the memory cell 1480. In addition, the bit line driver circuit has a function of reading data output from the memory cell 1480. Specifically, a sense amplifier is provided in the bit line driver circuit, and data output from the memory cell 1480 can be read using the sense amplifier.

The wiring PL functions as a plate line. A predetermined potential supplied to the wiring PL is supplied to the other of the pair of electrodes of the capacitor Cfe. The wiring PL is connected to the plate line driver circuit included in the row circuit 1420, and the plate line driver circuit is capable of supplying the potential to the wiring PL in a write operation or a read operation, for example.

The capacitor Cfe includes a material that can exhibit ferroelectricity as a dielectric layer between the two electrodes. When a ferroelectric layer that can be thinned is used as the dielectric layer of the capacitor and combined with a miniaturized transistor, the memory device can have a high degree of integration. The dielectric layer included in the capacitor Cfe is referred to as a ferroelectric layer in the following description.

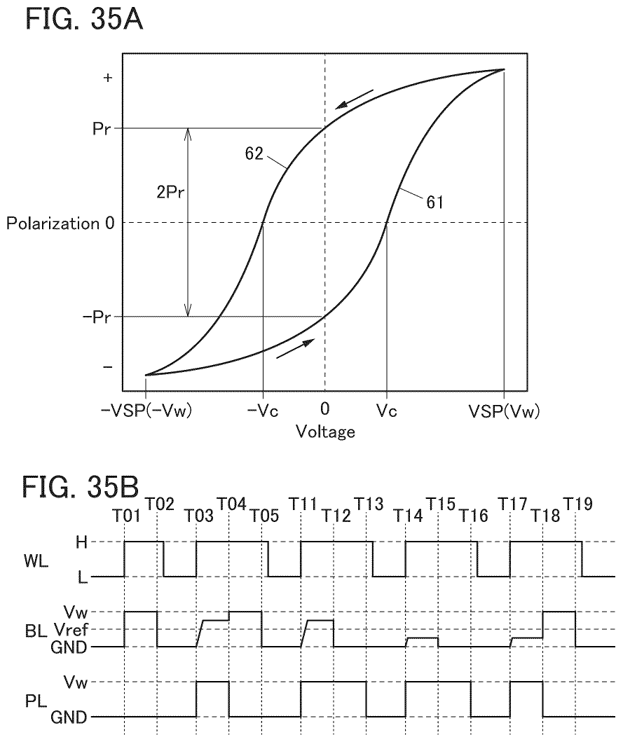

A ferroelectric layer included in the capacitor Cfe has hysteresis characteristics. FIG. 35A is a graph showing an example of the hysteresis characteristics. In FIG. 35A, the horizontal axis represents a voltage applied to the ferroelectric layer. The voltage can be a difference between the potential of one of the pair of electrodes of the capacitor Cfe and the potential of the other of the pair of electrodes of the capacitor Cfe, for example.

In FIG. 35A, the vertical axis represents polarization of the ferroelectric layer; a positive value indicates that positive charges are concentrated on one electrode side of the capacitor Cfe and negative charges are concentrated on the other electrode side of the capacitor Cfe. On the other hand, a negative value of the polarization indicates that positive charges are concentrated on the other electrode side of the capacitor Cfe and negative charges are concentrated on the one electrode side of the capacitor Cfe.

The voltage represented by the horizontal axis of the graph in FIG. 35A may be the difference between the potentials of one electrode of the capacitor Cfe and the other electrode of the capacitor Cfe. Furthermore, the polarization represented by the vertical axis of the graph in FIG. 35A may be a positive value in the case where positive charges are concentrated on the other electrode side of the capacitor Cfe and negative charges are concentrated on the one electrode side of the capacitor Cfe, and may be a negative value in the case where positive charges are concentrated on the one electrode side of the capacitor Cfe and negative charges are concentrated on the other electrode side of the capacitor Cfe.

As shown in FIG. 35A, the hysteresis characteristics of the ferroelectric layer can be represented by a curve 61 and a curve 62. The voltages at the intersecting points between the curve 61 and the curve 62 are VSP and −VSP. It can be said that VSP and −VSP have different polarities.

A voltage lower than or equal to −VSP is applied to the ferroelectric layer, and the voltage applied to the ferroelectric layer is increased, in which case the polarization of the ferroelectric layer is increased along the curve 61. On the other hand, a voltage higher than or equal to +VSP is applied to the ferroelectric layer, and then the voltage applied to the ferroelectric layer is decreased, in which case the polarization of the ferroelectric layer is decreased along the curve 62. Thus, VSP and −VSP can each be referred to as a saturation polarization voltage. Note that VSP is referred to as a first saturation polarization voltage and −VSP is referred to as a second saturation polarization voltage in some cases. In addition, the absolute values of the first saturation polarization voltage and the second saturation polarization voltage are equal to each other in FIG. 35A, but may be different from each other.

Here, Vc represents the voltage applied to the ferroelectric layer in the case where the polarization of the ferroelectric layer is 0 in the change of the polarization of the ferroelectric layer along the curve 61. In addition, −Vc represents the voltage applied to the ferroelectric layer in the case where the polarization of the ferroelectric layer is 0 in the change of the polarization of the ferroelectric layer along the curve 62. Each of Vc and −Vc can be referred to as a coercive voltage. The values of Vc and −Vc can be said to be values between −VSP and VSP. For example, Vc is referred to as a first coercive voltage and −Vc is referred to as a second coercive voltage in some cases. The absolute values of the first coercive voltage and the second coercive voltage may be different from each other though the absolute values are equal in FIG. 35A.

The maximum value and the minimum value of polarization when a voltage is not applied to the ferroelectric layer are referred to as remanent polarization Pr and remanent polarization −Pr, respectively. The difference between the remanent polarization +Pr and the remanent polarization −Pr is referred to as remanent polarization 2Pr.

As described above, the voltage applied to the ferroelectric layer included in the capacitor Cfe can also be referred to as the difference between the potentials of one of the pair of electrodes of the capacitor Cfe and the other of the pair of electrodes of the capacitor Cfe. As described above, the other of the pair of electrodes of the capacitor Cfe is connected to the wiring PL. Thus, by controlling the potential of the wiring PL, the voltage applied to the ferroelectric layer included in the capacitor Cfe can be controlled.

An example of a method for driving the memory cell 1480 illustrated in FIG. 34 is described below. In the following description, the voltage applied to the ferroelectric layer of the capacitor Cfe indicates the difference (potential difference) between the potentials of one electrode of the capacitor Cfe and the other electrode of the capacitor Cfe (wiring PL). The transistor M9 is an n-channel transistor.

FIG. 35B is a timing chart illustrating an example of the method for driving the memory cell 1480. FIG. 35B shows an example in which binary digital data is written to and read from the memory cell 1480. Specifically, in the example shown in FIG. 35B, data “1” is written to the memory cell 1480 in a period from Time T01 to Time T02, reading and rewriting are performed in a period from Time T03 to Time T05, reading and writing of data “0” to the memory cell 1480 are performed in a period from Time T11 to Time T13, reading and rewriting are performed in a period from Time T14 to Time T16, and reading and writing of data “1” to the memory cell 1480 are performed in a period from Time T17 to Time T19.

A sense amplifier connected to the wiring BL is supplied with Vref as a reference potential. In the read operation illustrated in FIG. 35B, when the potential of the wiring BL is higher than Vref, data “1” is read by the bit line driver circuit. On the other hand, when the potential of the wiring BL is lower than Vref, data “0” is read by the bit line driver circuit.

In the period from Time T01 to Time T02, a high potential is supplied as a selection signal to the wiring WL by the word line driver circuit. This turns on the transistor M9. In addition, the potential of the wiring BL is set to Vw. Since the transistor M9 is in an on state, the potential of one of the pair of electrodes of the capacitor Cfe becomes Vw. Furthermore, GND is supplied to the wiring PL by the plate line driver circuit. Accordingly, the voltage applied to the ferroelectric layer of the capacitor Cfe becomes “Vw-GND”. As a result, data “1” can be written to the memory cell 1480. Thus, the period from Time T01 to Time T02 can be referred to as a write operation period.

Here, Vw is preferably higher than or equal to VSP, and is preferably equal to VSP, for example. In this specification and the like, GND is set to a ground potential, but is not necessarily a ground potential as long as the memory cell 1480 can be driven so as to achieve an object of one embodiment of the present invention. For example, when the absolute value of the first saturation polarization voltage is different from the absolute value of the second saturation polarization voltage, and the absolute value of the first coercive voltage is different from the absolute value of the second coercive voltage, GND can be a potential other than a ground.

In the period from Time T02 to Time T03, GND is supplied to the wiring BL by the bit line driver circuit and GND is supplied to the wiring PL by the plate line driver circuit. Accordingly, the voltage applied to the ferroelectric layer of the capacitor Cfe becomes 0 V. The voltage “Vw-GND” applied to the ferroelectric layer of the capacitor Cfe in the period from Time T01 to Time T02 can be higher than or equal to VSP, and thus the polarization quantity of the ferroelectric layer of the capacitor Cfe is changed along the curve 62 in FIG. 35A in the period from Time T02 to Time T03. From the above, in the period from Time T02 to Time T03, polarization inversion does not occur in the ferroelectric layer of the capacitor Cfe.

After GND is supplied to each of the wirings BL and PL, a low potential is supplied to the wiring WL as a non-selection signal by the word line driver circuit. Thus, the transistor M9 is turned off. Accordingly, the write operation is completed, and the data “1” is retained in the memory cell 1480. Note that the potentials of the wirings BL and PL can each be any potential as long as polarization reversal does not occur in the ferroelectric layer of the capacitor Cfe, i.e., the voltage applied to the ferroelectric layer of the capacitor Cfe is higher than or equal to −Vc as the second coercive voltage.

In the period from Time T03 to Time T04, a high potential is supplied as a selection signal to the wiring WL by the word line driver circuit. This turns on the transistor M9. In addition, Vw is supplied to the wiring PL by the plate line driver circuit. By setting the potential of the wiring PL to Vw, the voltage applied to the ferroelectric layer of the capacitor Cfe becomes “GND-Vw”. As described above, in the period from Time T01 to Time T02, the voltage applied to the ferroelectric layer of the capacitor Cfe is “Vw-GND”. Thus, polarization inversion occurs in the ferroelectric layer of the capacitor Cfe. At the time of the polarization inversion, a current flows through the wiring BL, and the potential of the wiring BL becomes higher than Vref. Thus, the bit line driver circuit can read the data “1” retained in the memory cell 1480. Accordingly, the period from Time T03 to Time T04 can be referred to as a readout operation period. Note that Vref is higher than GND and lower than Vw but may be higher than Vw, for example.

Since the above reading is destructive reading, the data “1” retained in the memory cell 1480 is lost. Thus, in the period from Time T04 to Time T05, Vw is supplied to the wiring BL by the bit line driver circuit and GND is supplied to the wiring PL by the plate line driver circuit. As a result, data “1” is rewritten to the memory cell 1480. Thus, the period from Time T04 to Time T05 can be referred to as a rewrite operation period.

In the period from Time T05 to Time T11, GND is supplied to the wiring BL by the bit line driver circuit and GND is supplied to the wiring PL by the plate line driver circuit. After that, a low potential is supplied to the wiring WL as a non-selection signal by the word line driver circuit. Accordingly, the rewrite operation is completed, and the data “1” is retained in the memory cell 1480.

In the period from Time T11 to Time T12, a high potential is supplied as a selection signal to the wiring WL by the word line driver circuit. In addition, Vw is supplied to the wiring PL by the plate line driver circuit. Since the data “1” is retained in the memory cell 1480, the potential of the wiring BL becomes higher than Vref, and the data “1” retained in the memory cell 1480 is read. Thus, the period from Time T11 to Time T12 can be referred to as a readout operation period.

In the period from Time T12 to Time T13, GND is supplied to the wiring BL by the bit line driver circuit. Since the transistor M9 is in an on state, the potential of one of the pair of electrodes of the capacitor Cfe becomes GND. The potential Vw is supplied to the wiring PL by the plate line driver circuit. In the above manner, the voltage applied to the ferroelectric layer of the capacitor Cfe becomes to be “GND-Vw”. As a result, the data “0” can be written to the memory cell 1480. Thus, the period from Time T12 to Time T13 can be referred to as a write operation period.

In the period from Time T13 to Time T14, GND is supplied to the wiring BL by the bit line driver circuit and GND is supplied to the wiring PL by the plate line driver circuit. Accordingly, the voltage applied to the ferroelectric layer of the capacitor Cfe becomes 0 V. The voltage “GND-Vw” applied to the ferroelectric layer of the capacitor Cfe in the period from Time T12 to Time T13 can be set to be −VSP or lower; thus, the polarization quantity of the ferroelectric layer of the capacitor Cfe is changed along the curve 61 in FIG. 35A in the period from Time T13 to Time T14. From the above, in the period from Time T13 to Time T14, polarization inversion does not occur in the ferroelectric layer of the capacitor Cfe.

After GND is supplied to each of the wirings BL and PL, a low potential is supplied to the wiring WL as a non-selection signal by the word line driver circuit. Thus, the transistor M9 is turned off. Accordingly, the write operation is completed, and the data “0” is retained in the memory cell 1480. Note that the potentials of the wirings BL and PL can each be any potential as long as polarization reversal does not occur in the ferroelectric layer of the capacitor Cfe, i.e., the voltage applied to the ferroelectric layer of the capacitor Cfe is lower than or equal to Vc as the first coercive voltage.

In the period from Time T14 to Time T15, a high potential is supplied as a selection signal to the wiring WL by the word line driver circuit. Thus, the transistor M9 is turned on. In addition, Vw is supplied to the wiring PL by the plate line driver circuit. By setting the potential of the wiring PL to Vw, the voltage applied to the ferroelectric layer of the capacitor Cfe becomes “GND-Vw”. As described above, the voltage applied to the ferroelectric layer of the capacitor Cfe in the period from Time T12 to Time T13 is “GND-Vw”. Thus, polarization inversion does not occur in the ferroelectric layer of the capacitor Cfe. Consequently, the amount of current flowing through the wiring BL is smaller than that in the case where the polarization inversion occurs in the ferroelectric layer of the capacitor Cfe. Accordingly, the increase amount in the potential of the wiring BL is smaller than that in the case where the polarization inversion occurs in the ferroelectric layer of the capacitor Cfe; specifically, the potential of the wiring BL becomes lower than or equal to Vref. Thus, the bit line driver circuit can read the data “0” retained in the memory cell 1480. Accordingly, the period from Time T14 to Time T15 can be referred to as a readout operation period.

In the period from Time T15 to Time T16, GND is supplied to the wiring BL by the bit line driver circuit and the potential Vw is supplied to the wiring PL by the plate line driver circuit. Accordingly, data “0” is rewritten to the memory cell 1480. Thus, the period from Time T15 to Time T16 can be referred to as a rewrite operation period.

In the period from Time T16 to Time T17, GND is supplied to the wiring BL by the bit line driver circuit and GND is supplied to the wiring PL by the plate line driver circuit. After that, a low potential is supplied to the wiring WL as a non-selection signal by the word line driver circuit. Accordingly, the rewrite operation is completed, and the data “0” is retained in the memory cell 1480.

In the period from Time T17 to Time T18, a high potential is supplied as a selection signal to the wiring WL by the word line driver circuit. The potential Vw is supplied to the wiring PL by the plate line driver circuit. Since the data “0” is retained in the memory cell 1480, the potential of the wiring BL becomes lower than Vref, and the data “0” retained in the memory cell 1480 is read. Thus, the period from Time T17 to Time T18 can be referred to as a readout operation period.

In the period from Time T18 to Time T19, the potential Vw is supplied to the wiring BL by the bit line driver circuit. Since the transistor M9 is in an on state, the potential of one of the pair of electrodes of the capacitor Cfe becomes Vw. The potential GND is supplied to the wiring PL by the plate line driver circuit. Accordingly, the voltage applied to the ferroelectric layer of the capacitor Cfe becomes “Vw-GND”. As a result, the data “1” can be written to the memory cell 1480. Thus, the period from Time T18 to Time T19 can be referred to as a write operation period.

At and after Time T19, GND is supplied to the wiring BL by the bit line driver circuit and GND is supplied to the wiring PL by the plate line driver circuit. After that, a low potential is supplied to the wiring WL as a non-selection signal by the word line driver circuit. Accordingly, the rewrite operation is completed, and the data “1” is retained in the memory cell 1480.

The semiconductor device including the ferroelectric layer in the capacitor Cfe functions as a nonvolatile memory element that can retain written data even when power supply is stopped.

A DRAM requires regular refresh operation and thus increases power consumption. A semiconductor device that includes the capacitor Cfe including a ferroelectric layer does not require refresh operation and thus can have low power consumption.

In this specification and the like, a memory element or memory circuit including a ferroelectric layer is sometimes referred to as a “ferroelectric memory” or an “FE memory”. Thus, the semiconductor device of one embodiment of the present invention is a ferroelectric memory and is also an FE memory. The FE memory can achieve the number of times of data rewriting of 1×10¹⁰ or more, preferably 1×10¹² or more, further preferably 1×10¹⁵ or more. In addition, the FE memory can have an operation frequency greater than or equal to 10 MHz, preferably greater than or equal to 1 GHz.

In the FE memory, the remanent polarization 2Pr and data retention capability have a correlation; as the remanent polarization 2Pr becomes smaller, the data retention capability decreases. In this specification and the like, a period over which the remanent polarization 2Pr is reduced by 5% (the data retention capability is decreased by 5%) is referred to as a “memory retention period”. The FE memory can be expected to have a memory retention period of one day or longer, preferably ten days or longer, more preferably one year or longer, further preferably ten years or longer at a temperature of 150° C. or 200° C.

The FE memory can also be used for a cache memory, a register, and the like in a central processing unit (CPU), a graphics processing unit (GPU), and the like. A normally-off CPU (NoffCPU (registered trademark)) can be obtained by a combination of the FE memory with a cache memory, a register, and the like in a CPU. A normally-off GPU (NoffGPU (registered trademark)) can be obtained by a combination of the FE memory with a cache memory, a register, and the like in a GPU.

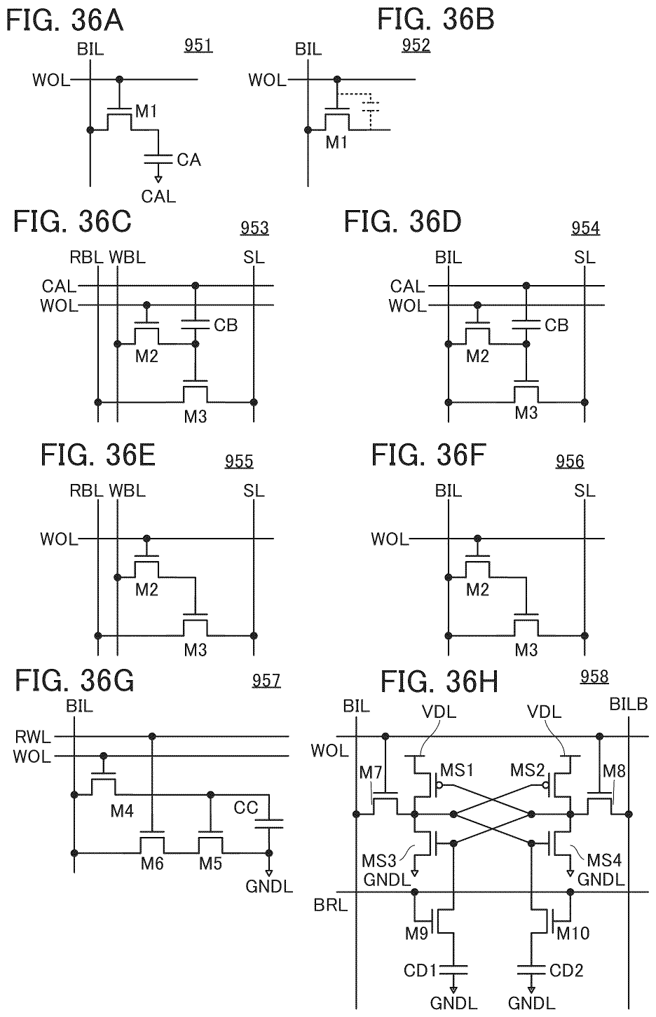

Structure examples of other memory cells each of which can be used as the memory cell 950 are described with reference to FIGS. 36A to 36H.

### [DOSRAM]

FIG. 36A illustrates a circuit configuration example of a memory cell for a dynamic random access memory (DRAM). In this specification and the like, a DRAM using an OS transistor is referred to as a dynamic oxide semiconductor random access memory (DOSRAM). A memory cell 951 includes a transistor M1 and a capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to a wiring BIL. The gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (referred to as a reference potential in some cases) is preferably applied to the wiring CAL.

Data writing and data reading are performed in such a manner that a high-level potential is applied to the wiring WOL to turn on the transistor M1 and establish electrical continuity between the wiring BIL and the first terminal of the capacitor CA (make a state where a current can flow therethrough).

The transistor M1, the capacitor CA, the wiring BIL, the wiring WOL, and the wiring CAL can correspond to the transistor 10, the capacitor 30, the wiring BL, the wiring WL, and the wiring PL, respectively, in FIG. 2B.

The memory cell that can be used as the memory cell 950 is not limited to the memory cell 951, and the circuit structure can be changed. For example, a structure of a memory cell 952 illustrated in FIG. 36B can be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. With such a structure, the structure of the memory cell can be greatly simplified.

Note that an OS transistor is preferably used as the transistor M1. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 951 and 952.

### [NOSRAM]

FIG. 36C illustrates a circuit structure example of a gain-cell memory cell including two transistors and one capacitor. A memory cell 953 includes a transistor M2, a transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to a wiring WBL. A gate of the transistor M2 is connected to the wiring WOL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing, data retention, and data reading, a low-level potential (sometimes referred to as a reference potential) is preferably applied to the wiring CAL.

Data writing is performed in such a manner that a high-level potential is applied to the wiring WOL to turn on the transistor M2 and establish electrical continuity between the wiring WBL and the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

As another example, one wiring BIL may be provided instead of the wiring WBL and the wiring RBL. A circuit structure example of the memory cell is illustrated in FIG. 36D. In a memory cell 954, one wiring BIL is provided instead of the wiring WBL and the wiring RBL in the memory cell 953, and the second terminal of the transistor M2 and the first terminal of the transistor M3 are electrically connected to the wiring BIL. In other words, one wiring BIL operates as the write bit line and the read bit line in the memory cell 954.

A memory cell 955 illustrated in FIG. 36E is an example in which the capacitor CB and the wiring CAL in the memory cell 953 are omitted. A memory cell 956 illustrated in FIG. 36F is an example in which the capacitor CB and the wiring CAL in the memory cell 954 are omitted. Such structures enable high integration of memory cells.

Note that an OS transistor is preferably used as at least the transistor M2. In particular, an OS transistor is preferably used as each of the transistors M2 and M3.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

When the OS transistor is used as the transistor M3, the memory cell can be configured with only n-type transistors.

FIG. 36G illustrates an example of a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is electrically connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed in such a manner that a high-level potential is applied to the wiring WOL to turn on the transistor M4 and establish electrical continuity between the wiring BIL and the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than the OS transistor depending on the crystal state of silicon used in a semiconductor layer, for example.

When OS transistors are used as the transistors M5 and M6, the memory cell can be configured with only n-type transistors.

### [OS-SRAM]

FIG. 36H illustrates an example of a static random access memory (SRAM) using an OS transistor. In this specification and the like, an SRAM using an OS transistor is referred to as an oxide semiconductor SRAM (OS-SRAM). A memory cell 958 illustrated in FIG. 36H is a memory cell of an SRAM capable of backup operation.

The memory cell 958 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1. A gate of the transistor M9 is connected to a wiring BRL. A second terminal of the transistor M10 is connected to a first terminal of the capacitor CD2. A gate of the transistor M10 is connected to the wiring BRL.

A second terminal of the capacitor CD1 is connected to the wiring GNDL. A second terminal of the capacitor CD2 is connected to the wiring GNDL.

The wirings BIL and BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. Since the transistor M8 is on, an inversion signal of the potential that has been applied to the wiring BIL (i.e., the signal that has been input to the wiring BIL) is output to the wiring BILB. Since the transistors M9 and M10 are on, the potential of the second terminal of the transistor M7 is retained in the first terminal of the capacitor CD2, and the potential of the second terminal of the transistor M8 is retained in the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading is performed by precharging the wirings BIL and BILB with a predetermined potential, and then applying a high-level potential to the wirings WOL and BRL, whereby the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, with the use of the transistors M7 to M10, written data can be retained for a long time, and thus the frequency of refresh operation for the memory cell can be decreased. Alternatively, refresh operation for the memory cell can be omitted.

Note that the transistors MS1 to MS4 may be Si transistors.

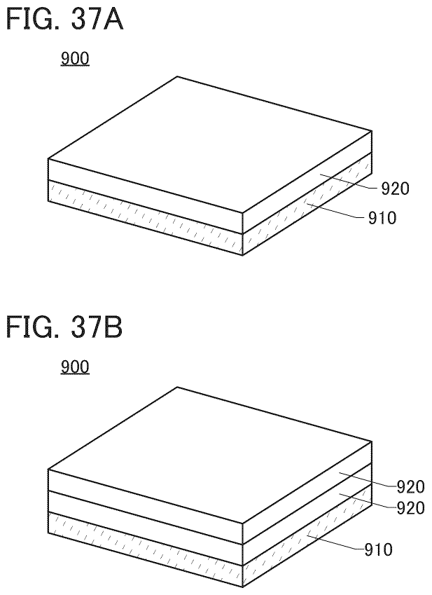

The driver circuit 910 and the memory array 920 included in the semiconductor device 900 may be provided on the same plane. Alternatively, as illustrated in FIG. 37A, the driver circuit 910 and the memory array 920 may be provided to overlap with each other. Providing the driver circuit 910 and the memory array 920 to overlap with each other can shorten a signal propagation distance. As illustrated in FIG. 37B, a plurality of memory cell arrays 920 may be stacked over the driver circuit 910.

Next, description is made on an example of an arithmetic processing device that can include the semiconductor device, such as the memory device described above.

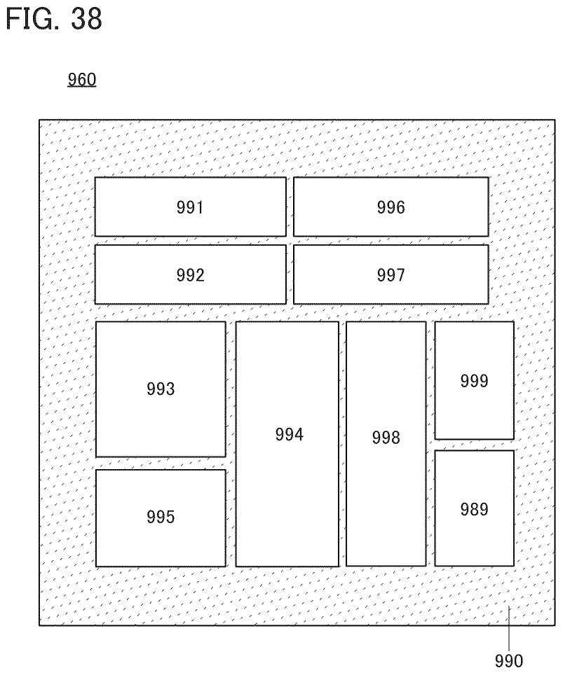

FIG. 38 is a block diagram of an arithmetic device 960. The arithmetic device 960 illustrated in FIG. 38 can be used for a CPU, for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 38 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 38 is only an example with a simplified structure, and the actual arithmetic device 960 has a variety of structures depending on the application. For example, what is called a multicore structure is preferably employed in which a plurality of cores each including the arithmetic device 960 in FIG. 38 operate in parallel. The larger number of cores can further enhance the arithmetic performance. The number of cores is preferably larger; for example, the number is preferably 2, further preferably 4, still further preferably 8, still further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 38, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply voltage is supplied to the memory cell in the register 996. When data retention by the capacitor is selected, the data is rewritten into the capacitor, and supply of the power supply voltage to the memory cell in the register 996 can be stopped.

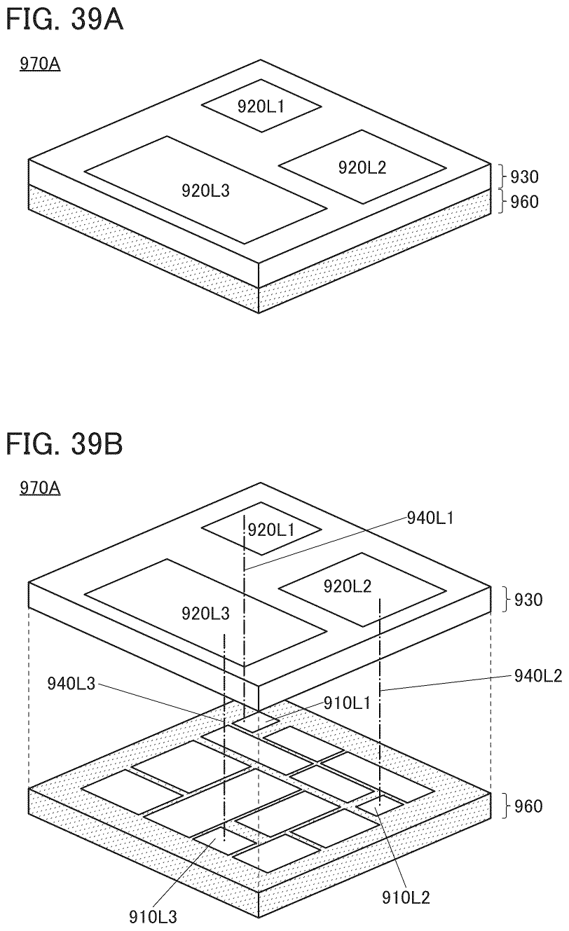

The memory array 920 and the arithmetic device 960 can be provided to overlap with each other. FIGS. 39A and 39B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 39B.

Providing the arithmetic device 960 and the layer 930 including the memory arrays to overlap with each other can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 39B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays can be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

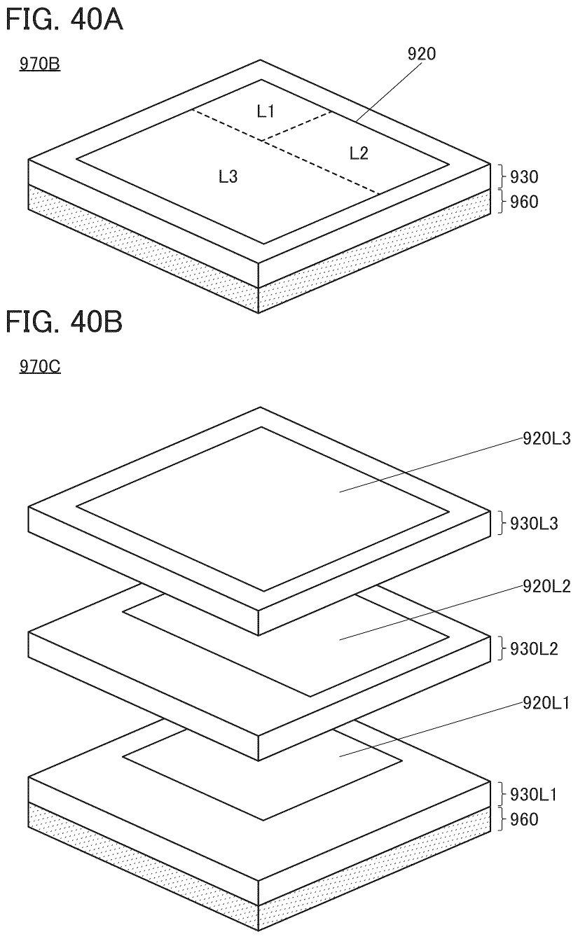

The layer 930 including one memory array 920 may be provided to overlap with the arithmetic device 960. FIG. 40A is a perspective view of a semiconductor device 970B.

In the semiconductor device 970B, one memory array 920 can be divided into a plurality of areas having different functions. FIG. 40A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 40B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

At least part of this embodiment can be implemented as appropriate in combination with any of the other embodiments described in this specification.

### Embodiment 3

In this embodiment, application examples of the semiconductor device of one embodiment of the present invention are described. The semiconductor device of one embodiment of the present invention can be used for an electronic component, an electronic device, a large computer, space equipment, and a data center (also referred to as DC), for example. An electronic component, an electronic device, a large computer, space equipment, and a data center each employing the semiconductor device of one embodiment of the present invention are effective in improving performance, for example, reducing power consumption.

### [Electronic Component]

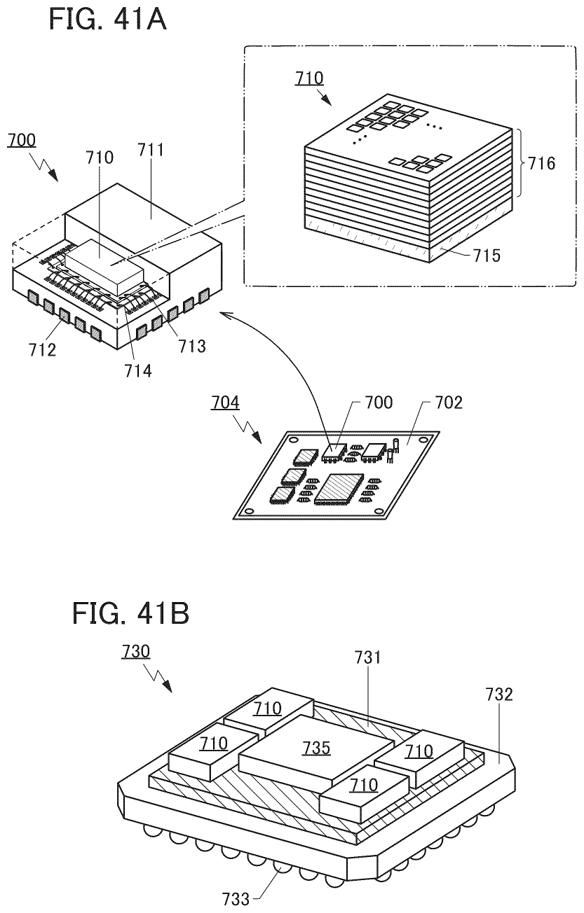

FIG. 41A is a perspective view of a substrate (a circuit board 704) provided with an electronic component 700. The electronic component 700 illustrated in FIG. 41A includes a semiconductor device 710 in a mold 711. FIG. 41A omits some components to show the inside of the electronic component 700. The electronic component 700 includes a land 712 outside the mold 711. The land 712 is connected to an electrode pad 713, and the electrode pad 713 is connected to the semiconductor device 710 through a wire 714. The electronic component 700 is mounted on a printed circuit board 702, for example. A plurality of such electronic components are combined and connected to each other on the printed circuit board 702, which forms the circuit board 704.

The semiconductor device 710 includes a driver circuit layer 715 and a memory layer 716. The memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) technique and a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form compared with the case where the memory layer 716 is formed with OS transistors. Therefore, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 41B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The electronic component 730 using the semiconductor device 710 as a high bandwidth memory (HBM) is illustrated as an example. The semiconductor device 735 can be used for an integrated circuit such as a CPU, a GPU, an NPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of connecting a plurality of integrated circuits with different terminal pitches. The plurality of wirings are provided in a single layer or multiple layers. In addition, the interposer 731 has a function of connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are connected with use of a silicon interposer, a TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 41B illustrates an example where the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Large Computer]

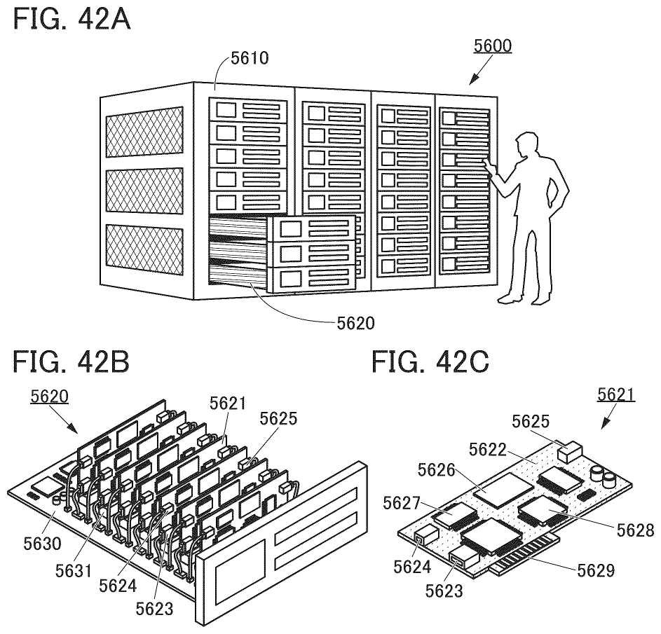

FIG. 42A is a perspective view of a large computer 5600. In the large computer 5600, a plurality of rack mount computers 5620 are stored in a rack 5610. Note that the large computer 5600 may be referred to as a supercomputer.

FIG. 42B is a perspective view of an example of the computer 5620. The computer 5620 includes a motherboard 5630. The motherboard 5630 is provided with a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

FIG. 42C illustrates an example of the PC card 5621. The PC card 5621 is a processing board provided with a CPU, a GPU, a memory device, and the like, for example. The PC card 5621 includes a board 5622 and components mounted on the board 5622, such as the connection terminal 5623, the connection terminal 5624, the connection terminal 5625, an electronic component 5626, an electronic component 5627, an electronic component 5628, and a connection terminal 5629. Note that FIG. 42C illustrates components other than the electronic component 5626, the electronic component 5627, and the electronic component 5628.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The electronic component 5626 includes a terminal (not illustrated) for inputting and outputting signals, and when the terminal is inserted in a socket (not illustrated) of the board 5622, the electronic component 5626 and the board 5622 can be connected to each other.

The electronic components 5627 and 5628 include a plurality of terminals; when the terminals are reflow-soldered, for example, to the wirings of the board 5622, the electronic components 5627 and 5628 can be mounted. Examples of the electronic component 5627 include an FPGA, a GPU, and a CPU. As the electronic component 5627, the electronic component 730 can be used, for example. Examples of the electronic component 5628 include a memory device. As the electronic component 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment.

The semiconductor device of one embodiment of the present invention includes an OS transistor. A change in electrical characteristics of the OS transistor due to radiation irradiation is small. That is, the OS transistor is highly resistant to radiation, and thus can be suitably used in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that although outer space refers to, for example, space at an altitude greater than or equal to 100 km, outer space described in this specification includes one or more of thermosphere, mesosphere, and stratosphere.

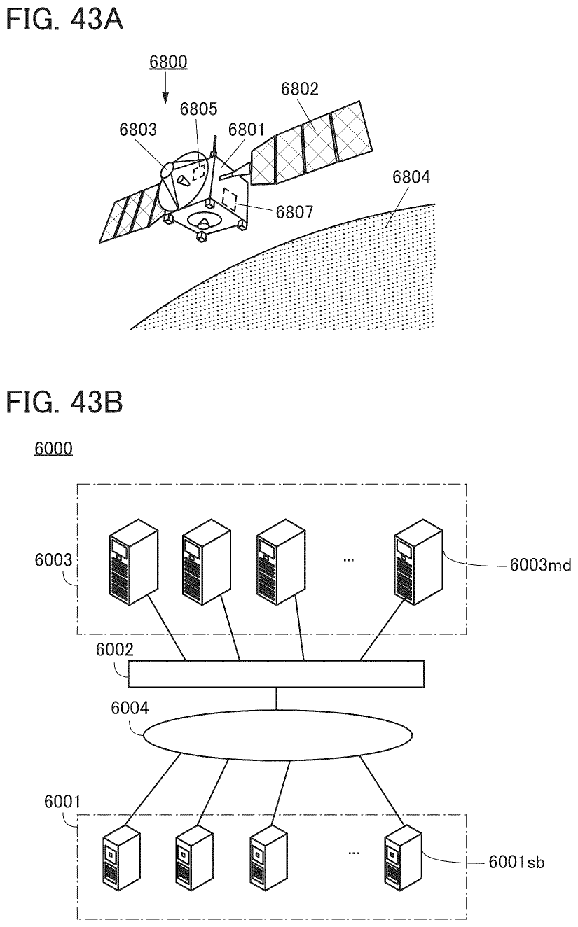

FIG. 43A illustrates an artificial satellite 6800 as an example of a space equipment. The artificial satellite 6800 includes a body 6801, a solar panel 6802, an antenna 6803, a secondary battery 6805, and a control device 6807. In FIG. 43A, a planet 6804 in outer space is illustrated as an example.

Although not illustrated in FIG. 43A, a battery management system (also referred to as BMS) or a battery control circuit may be provided in the secondary battery 6805. The battery management system or the battery control circuit preferably uses the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and high radiation tolerance as compared with a Si transistor.

### [Data Center]

The semiconductor device of one embodiment of the present invention can be suitably used for, for example, a storage system in a data center or the like. Long-term management of data, such as guarantee of data immutability, is required for the data center. The long-term management of data needs setting a storage and a server for retaining a huge amount of data, stable power supply for retaining data, cooling equipment for retaining data, an increase in building size, and the like.

With use of the semiconductor device of one embodiment of the present invention for a storage system in a data center, electric power used for retaining data can be reduced and a semiconductor device for retaining data can be downsized. Accordingly, downsizing of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 43B illustrates a storage system that can be used in a data center. A storage system 6000 illustrated in FIG. 43B includes a plurality of servers 6001sb as a host 6001. The storage system 6000 includes a plurality of memory devices 6003md as a storage 6003. In the illustrated example, the host 6001 and the storage 6003 are connected to each other through a storage area network 6004 and a storage control circuit 6002.

The host 6001 corresponds to a computer that accesses data stored in the storage 6003. The host 6001 may be connected to another host 6001 through a network.

The data access speed, i.e., the time taken for storing and outputting data, of the storage 6003 is shortened by using a flash memory, but is still considerably longer than the data access speed of a DRAM that can be used as a cache memory in a storage. In the storage system, in order to solve the problem of low access speed of the storage 6003, a cache memory is normally provided in the storage to shorten the time taken for data storage and output.

The above-described cache memory is used in the storage control circuit 6002 and the storage 6003. The data transmitted between the host 6001 and the storage 6003 is stored in the cache memories in the storage control circuit 6002 and the storage 6003 and then output to the host 6001 or the storage 6003.

With a structure in which an OS transistor is used as a transistor for storing data in the cache memory to retain a potential based on data, the frequency of refreshing can be decreased, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

At least part of this embodiment can be implemented as appropriate in combination with any of the other embodiments described in this specification.

This application is based on Japanese Patent Application Serial No. 2024-111316 filed with Japan Patent Office on Jul. 10, 2024, the entire contents of which are hereby incorporated by reference.

What is claimed is:

1. A semiconductor device comprising:
a first transistor;
a first insulating layer; and
a second insulating layer,
wherein the first transistor comprises a first conductive layer, a second conductive layer, a first semiconductor layer, a third insulating layer, and a third conductive layer,
wherein the first insulating layer is over the first conductive layer and comprises a slit reaching the first conductive layer,
wherein the second conductive layer is over the first insulating layer,
wherein the first insulating layer comprises a first side surface and a second side surface facing the first side surface in the slit,
wherein the first semiconductor layer comprises a first portion in contact with the second conductive layer, a second portion along the first side surface, and a third portion in contact with a first top surface of the first conductive layer,
wherein the first top surface overlaps with the slit in a plan view,
wherein the third conductive layer comprises a portion facing the second portion with the third insulating layer therebetween, and
wherein the second insulating layer comprises a portion facing the second portion with the third insulating layer and the third conductive layer therebetween and a portion overlapping with the first top surface with the third portion therebetween.

2. The semiconductor device according to claim 1, further comprising:
a second transistor; and
a fourth insulating layer,
wherein the second transistor comprises a fourth conductive layer, a fifth conductive layer, a second semiconductor layer, a fifth insulating layer, and a sixth conductive layer,
wherein the first insulating layer is over the fourth conductive layer so that the second side surface overlaps with a first region of a second top surface of the fourth conductive layer,
wherein the fifth conductive layer is over the first insulating layer,
wherein the second semiconductor layer comprises a fourth portion in contact with the fifth conductive layer, a fifth portion along the second side surface, and a sixth portion in contact with a second region of the second top surface of the fourth conductive layer,
wherein the second region of the second top surface overlaps with the slit in the plan view,
wherein the sixth conductive layer comprises a portion facing the fifth portion with the fifth insulating layer therebetween, and
wherein the fourth insulating layer comprises a portion facing the fifth portion with the fifth insulating layer and the sixth conductive layer therebetween and a portion overlapping with the second region of the second top surface with the second semiconductor layer therebetween.

3. The semiconductor device according to claim 1, wherein the third conductive layer and the second insulating layer extend in a first direction in the plan view.

4. The semiconductor device according to claim 1, wherein the first semiconductor layer comprises indium oxide.

5. The semiconductor device according to claim 1, further comprising:
a capacitor;
a sixth insulating layer; and
a seventh conductive layer,
wherein the capacitor comprises an eighth conductive layer, a ninth conductive layer, and a seventh insulating layer,
wherein the sixth insulating layer is over the seventh conductive layer and comprises an opening portion reaching the seventh conductive layer,
wherein the eighth conductive layer is in contact with a side surface of the sixth insulating layer and a top surface of the seventh conductive layer in the opening portion,
wherein the seventh insulating layer is over the eighth conductive layer,
wherein the ninth conductive layer is over the seventh insulating layer, and
wherein the first conductive layer is in contact with a top surface of the ninth conductive layer.

6. The semiconductor device according to claim 2,
wherein the slit extends in a first direction in the plan view,
wherein the first side surface and the second side surface are along the first direction, and
wherein the third conductive layer, the sixth conductive layer, the second insulating layer, and the fourth insulating layer extend in the first direction.

7. The semiconductor device according to claim 2, further comprising:
an eighth insulating layer; and
a ninth insulating layer,
wherein a third side surface of the first conductive layer faces a fourth side surface of the fourth conductive layer,
wherein the eighth insulating layer comprises a seventh portion covering the third side surface, an eighth portion covering the fourth side surface, a ninth portion covering a side surface of the second insulating layer, and a tenth portion covering a side surface of the fourth insulating layer, and
wherein the ninth insulating layer comprises a portion between the seventh portion and the eighth portion and a portion between the ninth portion and the tenth portion.

8. The semiconductor device according to claim 7,
wherein the second insulating layer and the fourth insulating layer each comprise one or more of silicon nitride and silicon nitride oxide,
wherein the eighth insulating layer comprises one or more of silicon nitride, silicon nitride oxide, silicon oxynitride, aluminum oxide, aluminum oxynitride, aluminum nitride, hafnium oxide, and hafnium aluminate, and
wherein the ninth insulating layer comprises one or more of silicon oxide, silicon oxynitride, silicon oxide comprising fluorine, silicon oxide comprising carbon, and silicon oxide comprising carbon and nitrogen.

9. A method for manufacturing a semiconductor device, comprising:
forming a first conductive layer;
forming a first insulating layer over the first conductive layer;
forming a second conductive layer over the first insulating layer;
by removing part of the second conductive layer and part of the first insulating layer with use of a first mask, forming a slit reaching the first conductive layer in the first insulating layer, thereby forming a first side surface and a second side surface of the first insulating layer that face each other within the slit in a cross-sectional view and dividing the second conductive layer with the slit therebetween in a plan view;
forming a first semiconductor layer covering a top surface of the first conductive layer and the first side surface and the second side surface of the first insulating layer in the slit;
forming a second insulating layer over the first semiconductor layer;
forming a third conductive layer over the second insulating layer;
by removing part of the third conductive layer by anisotropic etching, forming a fourth conductive layer along the first side surface and forming a fifth conductive layer along the second side surface;
forming a third insulating layer covering the first conductive layer, the second insulating layer, the fourth conductive layer, and the fifth conductive layer;
by removing part of the third insulating layer by anisotropic etching, forming a fourth insulating layer along the first side surface with the fourth conductive layer therebetween and forming a fifth insulating layer along the second side surface with the fifth conductive layer therebetween;
forming an eighth insulating layer and a ninth insulating layer by dividing the second insulating layer in the slit;
forming a second semiconductor layer and a third semiconductor layer by dividing the first semiconductor layer in the slit; and
forming a sixth conductive layer and a tenth conductive layer by dividing the first conductive layer in the slit,
wherein the slit extends in a first direction in the plan view,
wherein the first side surface and the second side surface extend in the first direction,
wherein the second semiconductor layer comprises a portion covering the first side surface and a portion covering a top surface of the sixth conductive layer, and
wherein the third semiconductor layer comprises a portion covering the second side surface and a portion covering a top surface of the tenth conductive layer.

10. The method for manufacturing a semiconductor device, according to claim 9, wherein the second insulating layer, the first semiconductor layer, and the first conductive layer are each divided using the fourth insulating layer and the fifth insulating layer as masks.

11. The method for manufacturing a semiconductor device, according to claim 9, wherein the first semiconductor layer comprises indium oxide.

12. The method for manufacturing a semiconductor device, according to claim 9, wherein the third insulating layer comprises one or more of silicon nitride and silicon nitride oxide.
